(19) United States
(12) Patent Application Publication
(10) Pub. No.: US 2026/0290457 A1
(43) Pub. Date: Sep. 24, 2026

(54) SEMICONDUCTOR MEMORY DEVICE

(71) Applicant: Kioxia Corporation, Tokyo (JP)

(72) Inventors: Rieko FUNATSUKI, Yokohama (JP); Noboru SHIBATA, Kawasaki (JP); Mina HATAKEYAMA, Tsukuba (JP)

(73) Assignee: Kioxia Corporation, Tokyo (JP)

(21) Appl. No.: 19/412,083

(22) Filed: Dec. 8, 2025

(30) Foreign Application Priority Data
Mar. 24, 2025 (JP) 2025-048702

(51) Int. Cl. G11C 16/04; G11C 16/10; G11C 16/16; G11C 16/24; G11C 16/30

(52) U.S. Cl. CPC G11C 16/0483; G11C 16/102; G11C 16/16; G11C 16/24; G11C 16/30

(57) ABSTRACT

A semiconductor memory device includes a first source line, a local bit line, a first bit line overlapping the local bit line, a first-tier memory cell array including a plurality of first local strings, each of the first local strings including a first selection transistor, a plurality of first memory cells, and a second selection transistor arranged between the first source line and the local bit line and electrically connected in series, a second-tier memory cell array including a plurality of second local strings, each of the second local strings including a third selection transistor, a plurality of second memory cells, and a fourth selection transistor arranged between the local bit line and the first bit line and electrically connected in series, and a control circuit electrically connected to the first bit line and configured to control the first-tier memory cell array and the second-tier memory cell array.

### CROSS-REFERENCE TO RELATED APPLICATION(S)

This application is based upon and claims the benefit of priority from the prior Japanese Patent Application No. 2025-048702, filed on Mar. 24, 2025, the entire contents of which are incorporated herein by reference.

Embodiments described herein relate generally to a semiconductor memory device.

### BACKGROUND

A NAND flash memory is known as a semiconductor memory device (a NAND type non-volatile semiconductor memory device).

### BRIEF DESCRIPTION OF THE DRAWINGS

FIG. 1 is a block diagram showing a configuration of a semiconductor storage device according to a first embodiment.

FIG. 2 is a circuit diagram showing a circuit configuration of a memory cell array of the semiconductor storage device according to the first embodiment.

FIG. 3 is a circuit diagram showing a circuit configuration of a memory string set of the semiconductor storage device according to the first embodiment.

FIG. 4 is an end view schematically showing an end cross-sectional structure of the semiconductor storage device according to the first embodiment.

FIG. 5 is a layout diagram schematically showing the configuration of the semiconductor storage device according to the first embodiment.

FIG. 6 is a layout diagram schematically showing a configuration of a semiconductor storage device according to a comparative example.

FIG. 7A is an end view showing a cross-sectional end configuration of the semiconductor storage device along a line A1-A2 shown in FIG. 5.

FIG. 7B is an end view showing a cross-sectional end configuration of the semiconductor storage device along a line B1-B2 and a line C1-C2 shown in FIG. 5.

FIG. 8 is an end view showing an end cross-sectional structure of the memory string set according to the first embodiment.

FIG. 9 is an end view schematically showing an end cross-sectional structure of the semiconductor storage device according to the first embodiment.

FIG. 10 is a circuit diagram showing a circuit configuration of a memory string set of the semiconductor storage device shown in FIG. 9.

FIG. 11 is an end view showing an end cross-sectional structure of the memory string set of the semiconductor storage device shown in FIG. 9.

FIG. 12 is a threshold distribution diagram showing an example of a threshold distribution of a memory cell transistor according to the first embodiment.

FIG. 13 is a timing chart showing waveforms of various signals in a read operation in the semiconductor storage device according to the first embodiment.

FIG. 14 is a circuit diagram for explaining a memory string set in the read operation in the semiconductor storage device according to the first embodiment.

FIG. 15 is a timing chart showing waveforms of various signals in a write operation in the semiconductor storage device according to the first embodiment.

FIG. 16 is a circuit diagram for explaining a memory string set in the write operation in the semiconductor storage device according to the first embodiment.

FIG. 17 is a circuit diagram for explaining the memory string set in the write operation in the semiconductor storage device according to the first embodiment.

FIG. 18 is a timing chart showing waveforms of various signals in the writing operation in the semiconductor storage device according to the first embodiment.

FIG. 19 is a circuit diagram for explaining a memory string set in the write operation in the semiconductor storage device according to the first embodiment.

FIG. 20 is a timing chart showing waveforms of various signals in an erase operation in the semiconductor storage device according to the first embodiment.

FIG. 21 is a circuit diagram showing a memory string set in the erase operation in the semiconductor storage device according to the first embodiment.

FIG. 22 is a timing chart showing waveforms of various signals in a verify operation in the semiconductor storage device according to the first embodiment.

FIG. 23 is a circuit diagram showing a memory string set in the verify operation in the semiconductor storage device according to the first embodiment.

FIG. 24 is a circuit diagram showing a circuit configuration of a memory string set of a semiconductor storage device according to a second embodiment.

FIG. 25 is an end view showing an end cross-sectional structure of the memory string set of the semiconductor storage device according to the second embodiment.

FIG. 26 is a timing chart showing waveforms of various signals in a read operation in the semiconductor storage device according to the second embodiment.

FIG. 27 is a circuit diagram for explaining a memory string set in the read operation in the semiconductor storage device according to the second embodiment.

FIG. 28 is a timing chart showing waveforms of various signals in a writing operation in the semiconductor storage device according to the second embodiment.

FIG. 29 is a circuit diagram for explaining a memory string set in the write operation in the semiconductor storage device according to the second embodiment.

FIG. 30 is a timing chart showing waveforms of various signals in an erase operation in the semiconductor storage device according to the second embodiment.

FIG. 31 is a circuit diagram showing a memory string set in the erase operation in the semiconductor storage device according to the second embodiment.

FIG. 32 is a circuit diagram for explaining a memory string set in a verify operation in the semiconductor storage device according to the second embodiment.

FIG. 33 is a circuit diagram showing a circuit configuration of the memory string set of the semiconductor storage device according to the second embodiment.

FIG. 34 is a circuit diagram showing the circuit configuration of the memory string set of the semiconductor storage device according to the second embodiment.

FIG. 35 is a circuit diagram showing a circuit configuration of a memory string set of a semiconductor storage device according to a third embodiment.

FIG. 36 is a circuit diagram for explaining a memory string set in a read operation in the semiconductor storage device according to the third embodiment.

FIG. 37 is a circuit diagram for explaining a memory string set in a write operation in the semiconductor storage device according to the third embodiment.

FIG. 38 is a circuit diagram for explaining a memory string set in an erase operation in the semiconductor storage device according to the third embodiment.

FIG. 39 is a circuit diagram for explaining a memory string set in a verify operation in the semiconductor storage device according to the third embodiment.

FIG. 40 is an end view showing an end cross-sectional structure of the semiconductor storage device according to the third embodiment.

FIG. 41 is an enlarged view showing a layout of a memory cell array serving as pair of the semiconductor storage devices shown in FIG. 5 and is an enlarged view showing part of the layout of the memory cell array serving as the pair.

FIG. 42 is an end view showing an example of an end section structure obtained by removing a local bit line or the like in the cross-sectional structure shown in FIG. 8.

### DETAILED DESCRIPTION

One embodiment provides a semiconductor memory device capable of suppressing a decrease in performance during a read operation. Alternatively, one embodiment provides a semiconductor memory device capable of suppressing a decrease in reliability during a write operation and a read operation. Alternatively, one embodiment provides a semiconductor memory device capable of suppressing an increase in device size due to an increase in the number of memory cells and suppressing a decrease in reliability due to an increase in the number of memory cells.

A semiconductor memory device includes a first source line extending in a first direction and a second direction intersecting the first direction, a local bit line extending in the second direction, a first bit line extending in the second direction and overlapping the local bit line when viewed from a third direction intersecting the first and second directions, a first-tier memory cell array including a plurality of first local strings arranged in the third direction, each of the plurality of first local strings including a first selection transistor, a plurality of first memory cells, and a second selection transistor arranged between the first source line and the local bit line and electrically connected in series, a second-tier memory cell array including a plurality of second local strings arranged in the third direction, each of the plurality of second local strings including a third selection transistor, a plurality of second memory cells, and a fourth selection transistor arranged between the local bit line and the first bit line and electrically connected in series, and a control circuit electrically connected to the first bit line and configured to control the first-tier memory cell array and the second-tier memory cell array.

A semiconductor memory device includes a plurality of memory cells each holding data, a plurality of word lines connected to the plurality of memory cells, a page including the plurality of memory cells connected to the same word line, a plurality of blocks having the plurality of pages, and first and second memory cell arrays including the plurality of blocks. The first memory cell array and the second memory cell array are arranged adjacent to each other, and the blocks of the first memory cell array and the blocks of the second memory cell array are arranged adjacent to each other or with dummy blocks having the same shape as the memory cells adjacent to each other.

Hereinafter, a semiconductor storage device in each embodiment will be specifically described with reference to the drawings. In addition, in the following description, components having the same function and configuration are given common reference numerals. Further, in the case of distinguishing a plurality of components having common reference signs, the plurality of components are distinguished by attaching a subscript to the common reference signs. In addition, in the case where the plurality of components is not required to be distinguished, the plurality of components is denoted by common reference signs only, and a subscript is not attached.

In the embodiments described below, in the case where the terms “same” and “match” are used, “same” and “match” may include errors within the design.

For example, in the specification, drawings, and claims of the present application, the semiconductor storage device according to an embodiment is a non-volatile storage device. Specifically, the semiconductor storage device according to an embodiment is a three-dimensional NAND flash memory.

### 1. First Embodiment

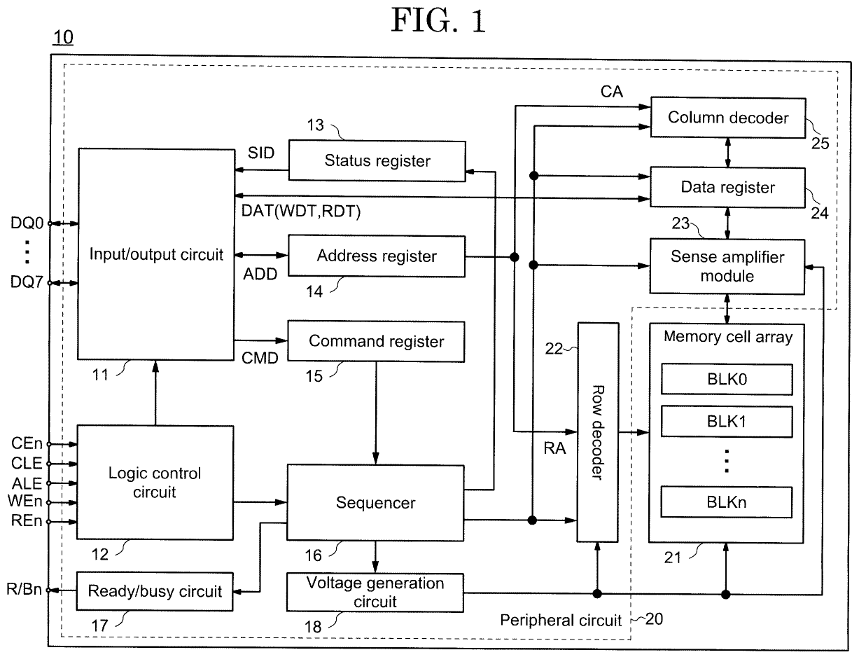

Referring to FIG. 1 to FIG. 23, a semiconductor storage device 10 according to a first embodiment will be described.

### 1-1. Overall Configuration of Semiconductor Storage Device 10

FIG. 1 is a block diagram of the semiconductor storage device 10. As shown in FIG. 1, the semiconductor storage device 10 includes an input/output circuit 11, a logic control circuit 12, a status register 13, an address register 14, a command register 15, a sequencer 16, a ready/busy circuit 17, a voltage generation circuit 18, a memory cell array 21, a row decoder 22, a sense amplifier module 23, a data register 24, and a column decoder 25.

The input/output circuit 11 controls the input/output of a signal DQ to/from an external device (not shown) such as a memory controller for controlling the semiconductor storage device 10. The signal DQ is, for example, an 8-bit signal of DQ 0 to DQ 7. The input/output circuit 11 includes an input circuit and an output circuit (not shown).

The input circuit transmits data DAT such as write data WDT received from the external device to the data register 24, transmits an address ADD to the address register 14, and transmits a command CMD to the command register 15.

The output circuit transmits status information SID received from the status register 13, data DAT such as read data RDT received from the data register 24, and the address ADD received from the address register 14 to the external device.

The logic control circuit 12 receives, for example, a chip enable signal CEn, a command latch enable signal CLE, an address latch enable signal ALE, a write enable signal WEn, and a read enable signal REn from the external device. The logic control circuit 12 controls the input/output circuit 11 and the sequencer 16 in response to the received signal.

The status register 13, for example, temporarily holds the status information SID in the write operation, the read operation, and the erase operation of the data, and notifies the external device whether or not the operation has ended normally via the input/output circuit 11. For example, in a write operation of data, a program loop including a program operation and a verify operation is executed multiple times. The verify operation may be omitted in each program loop. In addition, the read operation and the erase operation may include the verify operation.

The address register 14 temporarily holds the address ADD received from the external device through the input/output circuit 11. The address register 14 transfers a row address RA to the row decoder 22 and a column address CA to the column decoder 25.

The command register 15 temporarily stores the command CMD received from the external device via the input/output circuit 11 and transfers it to the sequencer 16.

The sequencer 16 controls operations of the semiconductor storage device 10. For example, the sequencer 16 controls the status register 13, the ready/busy circuit 17, the voltage generation circuit 18, the row decoder 22, the sense amplifier module 23, the data register 24, and the column decoder 25 according to the command CMD transferred from the command register 15, and executes the write operation, the read operation, the erase operation, and the like. The sequencer 16 in the semiconductor storage device 10 may be referred to as a “control circuit (controller).”

The ready/busy circuit 17 transmits a ready/busy signal R/Bn to the external device according to the operation status of the sequencer 16.

The voltage generation circuit 18 generates a voltage necessary for the write operation, the read operation, and the erase operation in response to control of the sequencer 16. For example, the voltage generation circuit 18 supplies the generated voltage to the memory cell array 21, the row decoder 22, and the sense amplifier module 23 and the like. The row decoder 22 and the sense amplifier module 23 apply the voltage supplied from the voltage generation circuit 18 to memory cells (memory cell transistors MT) in the memory cell array 21.

The memory cell array 21 includes a plurality of blocks BLK (blocks BLK 0, BLK 1, . . . , BLK n). The number n is an integer greater than or equal to 2. The blocks BLK are a collection of memory cells associated with bit lines and word lines. For example, the block BLK is an erase unit. For example, the memory cell is a charge-retaining transistor, which stores data in a non-volatile manner by the charge it holds. By including such a memory cell, the semiconductor storage device 10 functions as, for example, a NAND type non-volatile memory.

The row decoder 22 decodes the row address RA. The row decoder 22 selects one of the plurality of blocks BLK based on a result of the decoding process. The row decoder 22 applies a voltage required for the write operation, the read operation, and the erase operation to the blocks BLK.

For example, when the read operation is performed, the sense amplifier module 23 senses (detects) data read from the memory cell array 21. The sense amplifier module 23 transmits the sensed and read read data RDT to the data register 24. Further, for example, when the write operation is performed, the sense amplifier module 23 transmits the write data WDT to the memory cell array 21.

The data register 24 includes a plurality of latch circuits. The latch circuit retains write data WDT and read data RDT. For example, the data register 24 temporarily holds the write data WDT received from the input/output circuit 11 and transmits the write data WDT to the sense amplifier module 23 during the write operation. Further, for example, when the read operation is performed, the data register 24 temporarily holds the read data RDT received from the sense amplifier module 23, and transmits the read data RDT to the input/output circuit 11.

For example, the column decoder 25 decodes the column address CA during the write operation, the read operation, and the erase operation and selects the latch circuit in the data register 24 according to a result of the decoding process.

Circuit groups arranged around a periphery of the memory cell array 21 may be referred to as a peripheral circuit 20. The peripheral circuit 20 includes at least the input/output circuit 11, the row decoder 22, and the sense amplifier module 23. The status register 13, the address register 14, the command register 15, and the sequencer 16 may be included in the peripheral circuit 20. Further, the logic control circuit 12, the ready/busy circuit 17, and the voltage generation circuit 18 may be included in the peripheral circuit 20.

In this way, the semiconductor storage device 10 includes the memory cell array 21 including the plurality of memory cells and the peripheral circuit 20 for driving the plurality of memory cells.

### 1-2. Configuration of Memory Cell Array 21

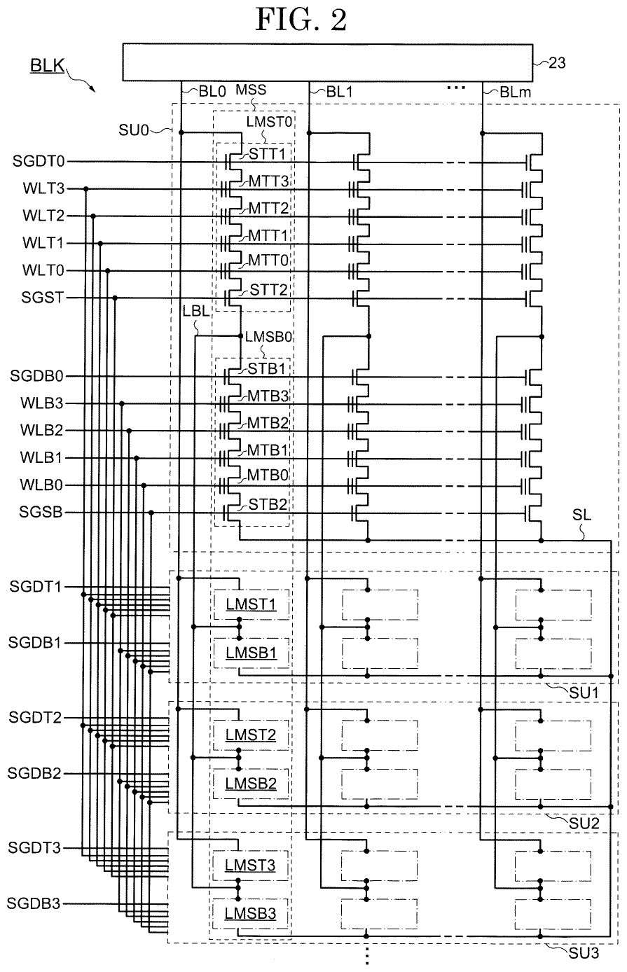

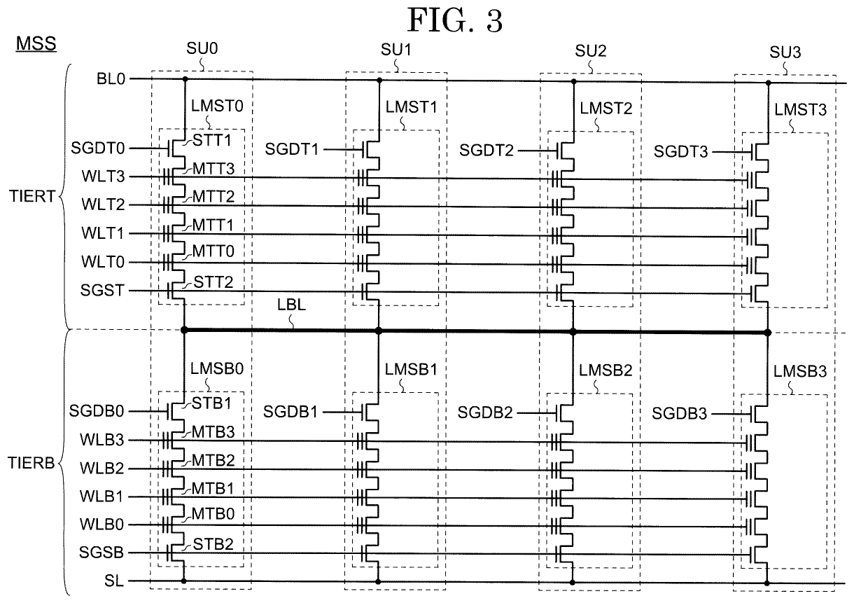

Referring to FIG. 2 and FIG. 3, a circuit configuration of the memory cell array 21 will be described. FIG. 2 is a circuit diagram showing the circuit configuration of the memory cell array 21 of the semiconductor storage device 10. FIG. 3 is a circuit diagram showing a circuit configuration of a memory string set MSS of the semiconductor storage device 10. FIG. 2 shows the block BLK of one of the plurality of blocks BLK included in the memory cell array 21, and FIG. 3 shows a memory cell string set MSS of one of a plurality of memory string sets MSS included in the block BLK shown in FIG. 2.

As described in the section “1-1. Overall Configuration of Semiconductor Storage Device 10”, the memory cell array 21 includes the plurality of blocks BLK. As shown in FIG. 2, each of the plurality of blocks BLK includes the plurality of memory string sets MSS associated with a set of a bit line BL 0 and a local bit line LBL corresponding to the bit line BL 0 to a set of a bit line BL m and a local bit line LBL corresponding to the bit line BL m. The number m is an integer greater than or equal to 1.

Each of the plurality of memory string sets MSS includes a plurality of sets of local memory strings LMST and LMSB. For example, FIG. 2 and FIG. 3 show cases in which the plurality of memory string sets MSS includes four sets of local memory strings LMST and LMSB. The four sets of local memory strings LMST and LMSB shown in FIG. 2 and FIG. 3 are local memory strings LMST 0 and LMSB 0, local memory strings LMST 1 and LMSB 1, local memory strings LMST 2 and LMSB 2, and local memory strings LMST 3 and LMSB 3.

Further, each of the plurality of blocks BLK is also classified into the number of string units SU corresponding to the number of local memory strings LMST and LMSB included in each of the memory string sets MSS. For example, the blocks BLK shown in FIG. 2 include four string units SU 0, SU 1, SU 2 and SU 3 corresponding to four sets of local memory strings LMST and LMSB, respectively. The string unit SU 0 includes local memory strings LMST 0 and LMSB 0. Each of the string units SU 1, the string unit SU 2 and SU 3 includes the same configuration as the string unit SU 0 and is similarly configured.

As shown in FIG. 2 and FIG. 3, the local memory strings LMST 0, LMST 1, LMST 2, and LMST 3 are included in the same memory string set MSS. A first end of each of the local memory strings LMST 0, LMST 1, LMST 2, and LMST 3 is commonly connected to a corresponding bit line BL (for example, BL 0). A second end of each of the local memory strings LMST 0, LMST 1, LMST 2, and LMST 3 and a first end of each of the local memory strings LMSB 0, LMSB 1, LMSB 2, and LMSB 3 are commonly connected to a corresponding local bit line LBL. A second end of each of the local memory strings LMSB 0, LMSB 1, LMSB 2, and LMSB 3 is commonly connected to a source line SL.

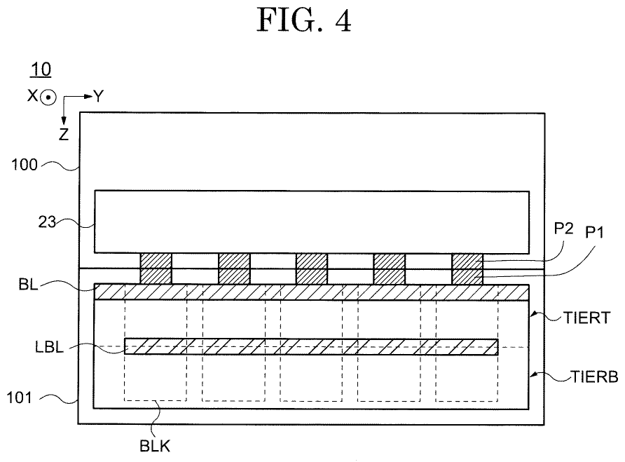

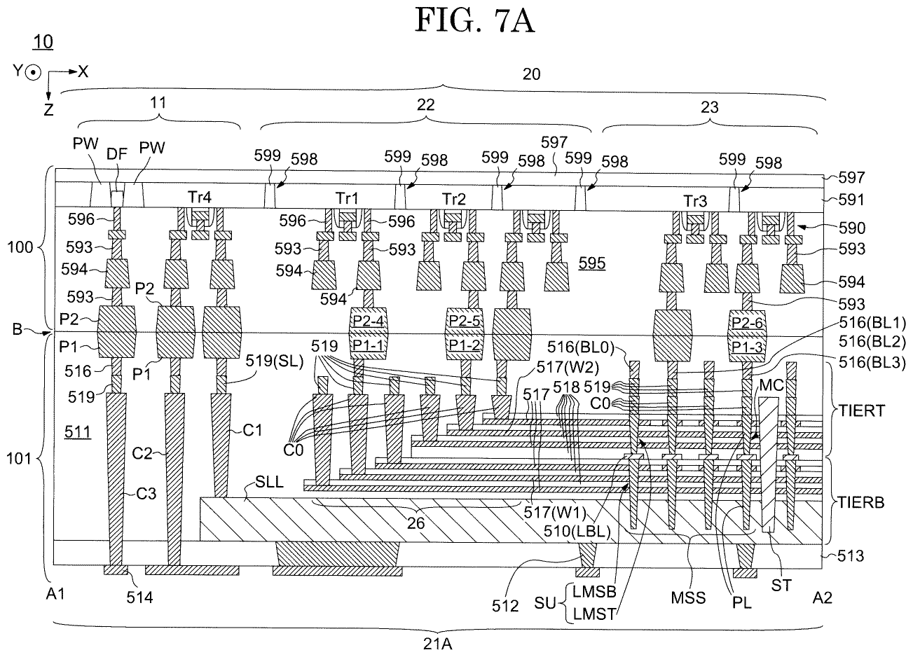

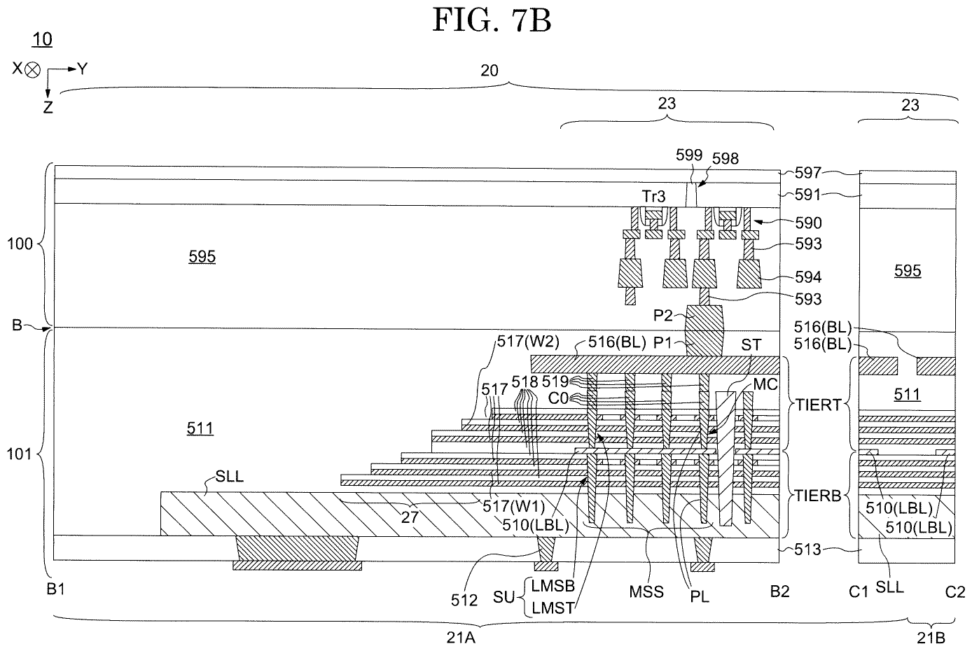

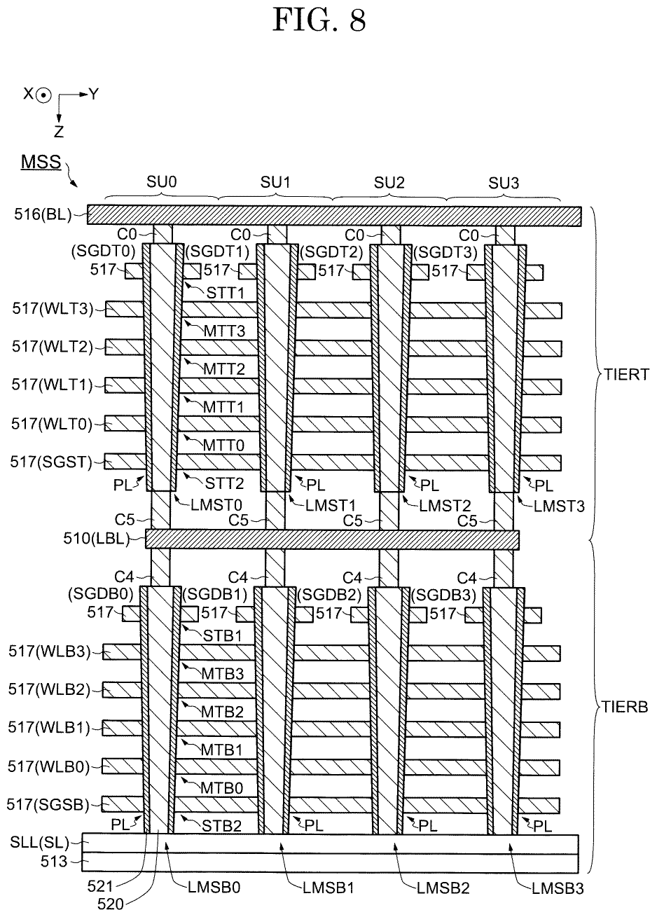

For example, as shown in FIG. 3, a tier TIERB is made up of the source line SL, the local memory strings LMSB 0, LMSB 1, LMSB 2, and LMSB 3 included in the same memory string set MSS, and a portion of the local bit line LBL. Further, for example, a tier TIERT may include the bit line BL 0 contained in the same memory string set MSS, the local memory strings LMST 0, LMST 1, LMST 2, and LMST 3, and a portion of the local bit line LBL. As shown in the end cross-sectional construction of the semiconductor storage device 10 of FIG. 4, FIG. 7A, FIG. 7B, and FIG. 8, a tier TIERT is stacked on the tier TIERB along a direction Z and the tier TIERT is electrically connected to the tier TIERB via the local bit line LBL. The tier TIERB and the tier TIERT in the semiconductor storage device 10 may be referred to as a sub block SUB BLK B and a sub block SUB BLK T.

In addition, the respective first ends of the local memory strings LMST 0, LMST 1, LMST 2, and LMST 3 are connected to the peripheral circuit 20, such as the sense amplifier module 23, via the respective bit lines BL. Furthermore, although not shown, the respective second ends of the local memory strings LMSB 0, LMSB 1, LMSB 2, and LMSB 3 are connected to the peripheral circuit 20 via the common source line SL. In addition, although not shown, the sense amplifier module 23 includes a plurality of sense amplifier units including a plurality of latch circuits, and each bit line BL is electrically connected to the sense amplifier unit corresponding to the respective bit line BL. Therefore, each bit line is individually supplied with a signal (voltage) from the sense amplifier unit corresponding to the respective bit line BL, and each bit line can individually transmit a signal (voltage) to the sense amplifier unit corresponding to the respective bit line BL.

The local bit line LBL is not electrically connected to the peripheral circuit 20, such as the bit line BL and source line SL, and is not driven by the peripheral circuit 20. That is, the local bit line LBL is a closed wiring in the memory string set MSS between the bit line BL and the source line SL. In other words, the local bit line LBL is connected to the peripheral circuit 20 via the bit line BL or source line SL that is connected to a corresponding local memory string. The applied voltage to the local bit line LBL of the selected block BLK is determined based on the bit line BL and the source line SL.

For example, a local memory string LMSB includes a drain select transistor STB 1, memory cell transistors MTB (MTB 0, MTB 1, MTB 2, and MTB 3) and a source select transistor STB 2 connected in series between the local bit line LBL and the source line SL.

For example, a local memory string LMST includes a drain select transistor STT 1, memory cell transistors MTT (MTT 0, MTT 1, MTT 2, and MTT 3) and a source select transistor STT 2 connected in series between the bit line BL and the local bit line LBL.

The drain select transistors STT 1 and STB 1 and the source select transistors STT 2 and STB 2 may be simply referred to as select transistors STT 1, STB 1, STT 2, STB 2.

A first end of the select transistor STB 1 is connected to the local bit line LBL as the first end of the local memory string LMSB. A second end of the select transistor STB 1 is connected to first ends of the memory cell transistors MTB (MTB 0, MTB 1, MTB 2, and MTB 3). Second ends of the memory cell transistors MTB (MTB 0, MTB 1, MTB 2, and MTB 3) are connected to the source line SL as the second end of the local memory string LMSB.

A first end of the select transistor STT 1 is connected to a corresponding bit line BL as the first end of the local memory string LMST, and a second end of the select transistor STT 1 is connected to first ends of the memory cell transistors MTT (MTT 0, MTT 1, MTT 2, and MTT 3). Second ends of the memory cell transistors MTT (MTT 0, MTT 1, MTT 2, and MTT 3) are connected to the local bit line LBL as the second end of the local memory string LMST.

That is, the first end of the select transistor STB 1 (the first end of the local memory string LMSB) is connected to the local bit line LBL along with the second end of the memory cell transistors MTT (MTT 0, MTT 1, MTT 2, and MTT 3) (the second end of the local memory string LMST).

Gate electrodes of all of the plurality of memory cell transistors MTB 0 to MTB of the string units SU 0 to SU 3 included in the same block BLK are commonly connected to word lines WLB 0 to WLB 3 (WLB 0, WLB 1, WLB 2, and WLB 3). Gate electrodes of all the plurality of memory cell transistors MTT 0 to MTT 3 of the string units SU 0 to SU 3 are commonly connected to word lines WLT 0 to WLT 3 (WLT 0, WLT 1, WLT 2, and WLT 3). Each gate electrode of the plurality of drain select transistors STB 1 in the string units SU 0 to SU 3 is commonly connected to select gate lines SGDB 0 to SGDB 3 (SGDB 0, SGDB 1, SGDB 2, and SGDB 3). Each gate electrode of the plurality of drain select transistors STT1 in the string units SU 0 to SU 3 is commonly connected to select gate lines SGDT 0 to SGDT 3 (SGDT 0, SGDT 1, SGDT 2, and SGDT 3). Gate electrodes of the plurality of source select transistors STB 2 in the string units SU 0 to SU 3 are commonly connected to a select gate line SGSB. Gate electrodes of the plurality of source select transistors STT2 in the string units SU 0 to SU 3 are commonly connected to a select gate line SGST.

In the case where word lines WL are distinguished, the word lines WL are marked with individual subscripts, as in WLT 0, or WLT 1. Similar to the word lines WL, in the case where the select gate lines SGD and SGS are distinguished, the select gate lines SGD and SGS are marked with individual subscripts as in SGDT 0, SGDT 1, SGDB 0, SGSB 1, a SGST 0, a SGST 1, a SGSB 0, or a SGSB 1. Each transistor (for example, MT or ST), each local memory string LMS, and each string unit SU are also marked with individual subscripts when distinguished as well as the word lines WL or the select gate lines SGD and SGS.

For example, the memory cell transistors MT (MTT 0 to MTT 3, MTB 0 to MTB 3) are field-effect transistors (FET: Field Effect Transistor) that include a charge storage layer in a gate insulating layer. A threshold voltage of the memory cell transistor MT varies according to a charge quantity held in the charge storage layer. By providing one or more threshold voltages, the memory cell transistor MT can store one or more bits of data.

For example, the select transistors STB 1, STB 2, STT 1, and STT 2 are field-effect transistors.

First ends of the word lines (WLB 0 to WLB 3, WLT 0 to WLT 3) and the select gate lines (SGDB 0 to SGDB 3, SGDT 0 to SGDT 3, SGSB, and SGST) are each connected to the peripheral circuit 20, such as the row decoder 22.

For example, the bit line BL may be shared by the plurality of memory string sets MSS, each of which is contained in a different block BLK, and the source line SL may be shared among the plurality of blocks BLK.

The circuit configuration of the memory cell array 21 included in the semiconductor storage device 10 is not limited to the configuration described in the section “1-2. Configuration of Memory Cell Array”. For example, the number of memory cell transistors MT included in the local memory string LMS may be one to four, and may be five or more. The number of select transistors STT 1 and STT 2 may be two or more. Further, the number of string units SU included in the respective blocks BLK may be one to four, and may be five or more. The number of memory cell transistors MT included in each local memory string LMS, the number of select transistors STT 1 and STT 2, and the number of string units SU included in each block BLK may be designed to any number as appropriate depending on the specifications, applications, and the like of the semiconductor storage device 10.

### 1-3. Schematic Layout and End Cross-sectional Structure of Semiconductor Storage Device 10

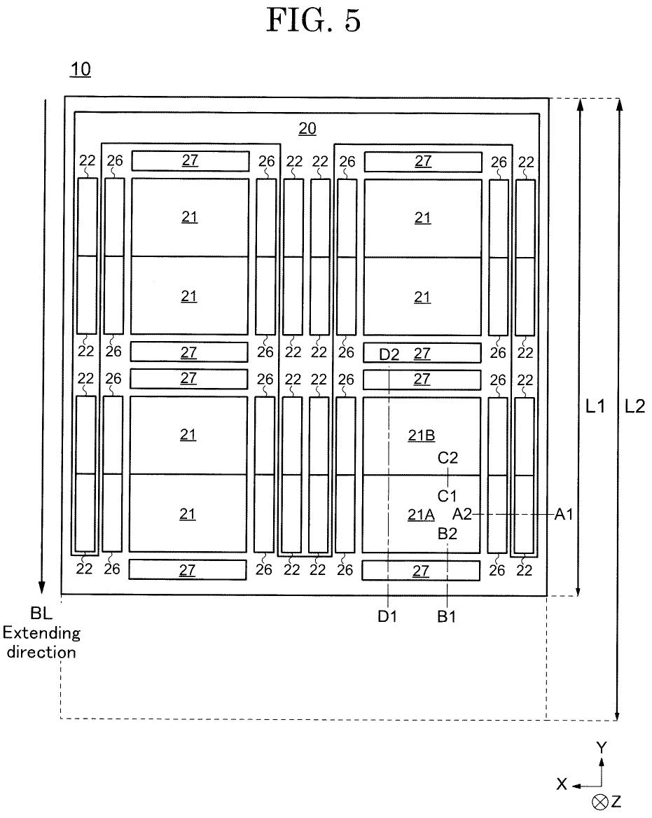

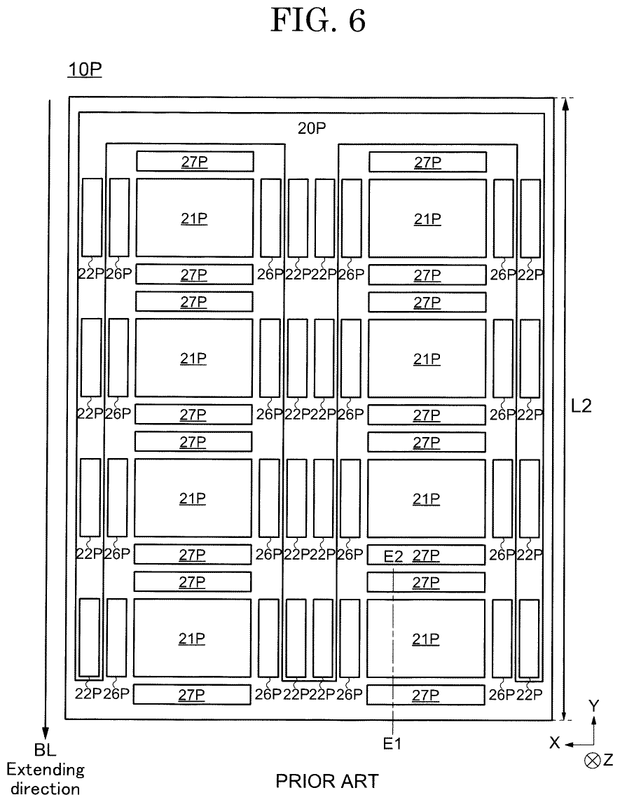

Referring to FIG. 4 to FIG. 8, a schematic layout and an end cross-sectional structure of the semiconductor storage device 10 will be described. FIG. 4 is an end view schematically showing an end cross-sectional structure of the semiconductor storage device 10. FIG. 5 is a layout diagram schematically showing the configuration of the semiconductor storage device 10. FIG. 6 is a layout diagram schematically showing a configuration of a semiconductor storage device according to a comparative example. FIG. 7A is an end view showing a cross-sectional end view of the semiconductor storage device 10 along a line A1-A2 and a line B1-B2 shown in FIG. 5. FIG. 7B is an end view showing a cross-sectional end view of the semiconductor storage device 10 along the line B1-B2 and a line C1-C2 shown in FIG. 5. FIG. 8 is an end view showing an end cross-sectional view of a memory string set MSS of the semiconductor storage device 10. Although the details will be explained later, for example, a main surface of a semiconductor layer 591 of the peripheral circuit 20 shown in FIG. 7A and FIG. 7B extends in a direction X and a direction Y. For example, the direction Z in the semiconductor storage device 10 is a direction perpendicular to the directions X and Y, and the direction in which an arrow of the direction Z is directed in the semiconductor storage device 10 may be expressed as above or upper, and an opposite direction may be expressed as under or lower. In addition, the direction X may be referred to as a “first direction”, the direction Y may be referred to as a “second direction”, and the direction Z may be referred to as a “third direction”. FIG. 4 to FIG. 8 are diagrams schematically showing the configuration of the semiconductor storage device 10 and show an example, and the configuration of the semiconductor storage device 10 is not limited to that shown in FIG. 4 to FIG. 8. In addition, for example, in order to promote understanding of the semiconductor storage device 10, there is a case where the direction X and the direction Y are interchanged to show the drawings easily.

First, referring to FIG. 4, FIG. 5, FIG. 7A, FIG. 7B, and FIG. 8, a construction of the semiconductor storage device 10 will be described. For example, as shown in FIG. 4, the semiconductor storage device 10 includes an IC chip 101 and an IC chip 100 that differs from the IC chip 101. The IC chip 101 includes the tier TIERB and tier TIERT described in the section “1-2. Configuration of Memory Cell Array 21.” As described in the section “1-2. Configuration of Memory Cell Array 21”, the tier TIERB and tier TIERT include the plurality of BLK, the tier TIERB includes a portion of the local bit line LBL, and the tier TIERT includes a portion of the local bit line LBL and bit line BL. For example, the IC chip 100 includes the sense amplifier module 23 and part of the peripheral circuit 20.

The IC chip 101 and the IC chip 100 are stacked in this order from below along the direction Z. That is, the tier TIERB, the tier TIERT and the sense amplifier module 23 are stacked in this order from the bottom along the direction Z. Further, the IC chip 101 also includes a plurality of connection electrodes P 1 which are electrically connected to the bit line BL, and the IC chip 100 includes a plurality of connection electrodes P 2 which are electrically connected to the sense amplifier module 23. Each of the plurality of connection electrodes P 2 is electrically connected to the corresponding connection electrode P 1 of the plurality of connection electrodes P 1. “Connection electrode” may be expressed as “lamination electrode”.

For example, as shown in FIG. 5, in the semiconductor storage device 10, the memory cell arrays 21 are arranged in a matrix form in the direction X and the direction Y. The semiconductor memory device 10 has a configuration in which four sets of memory parts are arranged in a matrix form in the direction X and the direction Y, with a set of memory parts including two memory cell arrays 21 arranged adjacently along the direction Y, two step parts 26 arranged along one end side and the other end side of the two memory cell arrays 21 along the direction X and arranged adjacently along the direction Y, two row decoders 22 arranged on the opposite side to the side where the two memory cell arrays 21 are arranged along the direction X with respect to the two step parts 26, and two dummy step parts 27 arranged on one end side and the other end side of the two memory cell arrays 21 along a line D1-D2 parallel to the direction Y. Further, for example, the peripheral circuit 20 includes sixteen row decoders 22 included in the four sets of memory parts. Further, as shown in FIG. 6 and FIG. 7A, in the semiconductor storage device 10, the memory cell arrays 21 or the peripheral circuits 20 are also stacked in the direction Z. For example, the bit line BL extends along the direction Y and a length along the direction Y of the semiconductor storage device 10 is a length L1.

For example, as shown in FIG. 7A and FIG. 7B, the semiconductor storage device 10 includes a plurality of wirings 517 stacked in a stepped manner, as will be described more fully hereinafter. Of the plurality of wirings 517, the number of wirings 517 corresponds to a plurality of word lines WL (WLB 0 to WLB 3, WLT 0 to WLT 3). For example, as shown in FIG. 7A, the step part 26 includes the plurality of word lines WL that extend along the direction X and the direction Y stacked in a stepped manner along the direction Z, and a plurality of vias C 0, a plurality of wirings 519, a plurality of wirings 516, and the like. The step part 26 can lead out the plurality of word lines WL to the periphery of the memory cell array 21 along the direction X or the direction Y using the plurality of vias C 0, the plurality of wirings 519, the plurality of wirings 516, and the like. Further, the step part 26 can route the plurality of word lines WL in the direction Y and the direction X using the plurality of vias C 0, the plurality of wirings 519, the plurality of wirings 516, and the like, and can also be electrically connected to the row decoder 22. On the other hand, for example, as shown in FIG. 7B, although the dummy step part 27 includes the plurality of word lines WL which extend along the direction X and the direction Y and are stacked in a stepped manner along the direction Z, the plurality of word lines WL in the dummy step part 27 are not drawn to the periphery of the memory cell array 21 along the direction X or the direction Y. Since a configuration and a function of each element other than the above shown in the end cross-sectional structure of the semiconductor storage device 10 shown in FIG. 7B are the same as the configuration and the function of each corresponding element in the end cross-sectional structure of the semiconductor storage device 10 shown in FIG. 7A, in the following description, the semiconductor storage device 10 will be described referring to the end cross-sectional structure of the semiconductor storage device 10 shown in FIG. 7A, and the end cross-sectional structure of the semiconductor storage device 10 shown in FIG. 7B will be described as required.

Referring now to FIG. 6, a semiconductor storage device 10P of a comparative example (PRIOR ART) will be described. For example, in the semiconductor storage device 10P, memory cell arrays 21P are arranged in a matrix in the direction X and the direction Y. The semiconductor storage device 10P of the comparative example has a configuration in which eight sets of memory parts are arranged in a matrix form in the direction X and the direction Y, with a memory cell array 21P, step parts 26P arranged at one end side and the other end side of the memory cell array 21P along the direction X, row decoders 22P arranged at the opposite side from the side where the memory cell array 21P is arranged along the direction X with respect to the step parts 26P, and two dummy step parts 27P arranged at one end side and the other end side of the memory cell array 21 along a line E1-E2 parallel to the direction Y as one set. Further, for example, a peripheral circuit 20P includes sixteen row decoders 22P included in eight sets of memory sections. Further, although not shown, similar to the semiconductor storage device 10, in the semiconductor storage device 10P of the comparative example, the memory cell arrays 21P or the peripheral circuit 20P is stacked in the direction Z. For example, the bit line BL extends along the direction Y and a length along the direction Y of the semiconductor memory device 10P is a length L2. Although not shown, since the semiconductor storage device 10P does not include a wiring corresponding to a local bit line in the semiconductor storage device 10, two pillars (see FIG. 7A) connected to the tiers TIERB and TIERT in the semiconductor storage device 10 through the local bit line form one pillar.

For example, in recent years, speed performance of the semiconductor storage device 10P has deteriorated as the number of stacked layers in the direction Z in the semiconductor storage device 10P increases. For example, by increasing the number of memory cell arrays 21P arranged in the direction Y and decreasing the length of the bit lines per one memory cell array 21P, degradation in the speed performance due to an increase in the number of stacked layers in the direction Z in the semiconductor storage device 10P is suppressed. On the other hand, since the number of memory cell arrays 21P is increasing, an increase in the area due to the dummy step part 27 in the semiconductor storage device 10P is a problem.

On the other hand, as shown in FIG. 5, the semiconductor storage device 10 does not include the dummy step part 27 between the neighboring memory cell arrays 21, and the length L1 of the semiconductor storage device 10 is shorter than the length L2. Further, since the stacked structure of the memory cell arrays 21 along the direction Z of the semiconductor storage device 10 has a configuration in which the tier TIERB and the tier TIERT are connected using the local bit line LBL and a stacked structure closed within one IC chip 101, the semiconductor storage device 10 does not include a separately required configuration for connecting the memory cell array 21 along the direction Z, and the bit line BL can be suppressed from being longer than necessary. Consequently, the semiconductor storage device 10 can maintain the same speed performance as the semiconductor storage device 10P and suppress the area increase.

Next, referring to FIG. 7A, the end section of the semiconductor storage device 10 will be described. For example, in order to promote understanding of the end cross-sectional structure of the semiconductor storage device 10, stack numbers of the plurality of wirings 517 and the plurality of insulating layers 518, vias, wirings, and the like that connect the wirings 517 to each other are omitted from the end cross-sectional structure of the semiconductor storage device 10 shown in FIG. 7A. The end cross-sectional structure of the semiconductor storage device 10 shown in FIG. 7A is an example, and the end cross-sectional structure of the semiconductor storage device 10 shown in FIG. 7A is not limited to the example shown in FIG. 7A.

As shown in FIG. 7A and FIG. 7B, the IC chip 100 includes the peripheral circuit 20 and the IC chip 101 includes memory cell arrays 21A and 21B. The main surface of the semiconductor layer 591 of the peripheral circuit 20 extends in the direction X and the direction Y. The IC chip 101 and the IC chip 100 are bonded to each other at a bonding surface B. That is, the memory cell arrays 21A and 21B and the peripheral circuit 20 are bonded to each other at the bonding surface B. The connecting electrode P 1 is arranged on the bonding surface B of the IC chip 101 (the memory cell arrays 21A and 21B). The connection electrode P 2 is arranged on the bonding surface B of the IC chip 100 (peripheral circuit 20). Circuits arranged in the memory cell arrays 21A and 21B are electrically connected to the circuit arranged in the peripheral circuit 20 through the connection electrodes P 1 and P 2. Further, as shown in the end cross-sectional structure of the semiconductor storage device 10 along the line C1-C2 of FIG. 7B, the bit line BL included in the memory cell array 21A is spaced apart from the bit line BL included in the memory cell array 21B along the direction Y, and the bit line LBL included in the memory cell array 21A is spaced apart from the bit line LBL included in the memory cell array 21B along the direction Y. Furthermore, a distance between the bit line BL included in the memory cell array 21A and the bit line BL included in the memory cell array 21B is less than a distance between the bit line LBL included in the memory cell array 21A and the bit line LBL included in the memory cell array 21B. The bit line BL included in the memory cell array 21A is not connected with the bit line BL included in the memory cell array 21B, and the memory cell array 21A and the memory cell array 21B can operate independently of each other.

In the case where the connection electrodes P 1 are distinguished in the semiconductor storage device 10, the connection electrodes P 1 have individual subscripts such as connection electrodes P 1-1, P 1-2, and P 1-3. In the case where the connection electrodes P1 are not distinguished, the connection electrodes P 1 are referred to as the connection electrodes P 1. Similar to the connection electrodes P 1, in the case where the connection electrodes P 2 in the semiconductor storage device 10 are distinguished, the connection electrodes P 2 have individual subscripts such as connection electrodes P 2-4, P 2-5, and P 2-6. In the case where the connection electrodes P 2 are not distinguished, the connection electrodes P 2 are referred to as the connection electrodes P 2.

As shown in FIG. 7A, the connection electrode P 1-1 is bonded to the connection electrode P 2-4. The connection electrode P 1-2 is bonded to the connection electrode P 2-5. The connection electrode P 1-3 is bonded to the connection electrode P 2-6. A connection electrode P 1-4 is bonded to a connection electrode P 2-7.

The peripheral circuit 20 includes the semiconductor layer 591, a processing circuit 592, a via 593, a wiring 594, an insulating layer 595, a contact 596, an insulating layer 597, and the connection electrode P2.

For example, a silicon layer is used as the semiconductor layer 591. For example, a thickness of the semiconductor layer 591 is less than a thickness of a silicon wafer typically used as a substrate.

The semiconductor layer 591 is provided with a trench 598. An insulating layer 599 is provided inside the trench 598. A lower surface of the semiconductor layer 591 is covered by the insulating layer 597. Since the trench 598 reaches the insulating layer 597, a lower surface of the insulating layer 599 is in contact with the insulating layer 597. For example, silicon oxide or silicon nitride is used as the insulating layers 597 and 599. For example, since the trench 598 is formed from above along the direction Z, a sidewall of the trench 598 is tapered with a slope facing upward. In other words, a width of the trench 598 along the direction Y in an end face view increases as it approaches the memory cell array 21. In other words, a distance between an opposing sidewall in the trench 598 in the end face view gradually increases from the bottom upwards.

The insulating layer 597 is in contact with the insulating layer 599 at a lower end of the insulating layer 599 (at an end far from the memory cell array 21). Similar to the insulating layer 597, an insulating layer 590 is in contact with the semiconductor layer 591 at the lower surface of the semiconductor layer 591 (a surface far from the memory cell array 21).

The processing circuit 592 includes a transistor Tr with the semiconductor layer 591 as a channel. For example, the processing circuit 592 includes the input/output circuit 11, the row decoder 22, and the sense amplifier module 23. For example, the row decoder 22 includes a first transistor Tr 1 and a second transistor Tr 2. The sense amplifier module 23 includes a third transistor Tr 3. The input/output circuit 11 includes a fourth transistor Tr 4. If the transistor is not distinguished, the transistor is simply referred to as the transistor Tr. Although not shown, the processing circuit 592 includes a capacitor and a resistive element.

The row decoder 22, the sense amplifier module 23, and the input/output circuit 11 are controlled by the logic control circuit 12 and the sequencer 16. One of the logic control circuit 12 or the sequencer 16 may be referred to as a “control circuit,” and the logic control circuit 12 and the sequencer 16 may be collectively referred to as a “control circuit.”

The row decoder 22, the sense amplifier module 23, and the input/output circuit 11 include the insulating layer 597, the trench 598, and the insulating layer 599. The trench 598 is arranged between adjacent transistors. Specifically, the trench 598 is arranged between the first transistor Tr 1 and the second transistor Tr 2. The input/output circuit 11 is connected to the row decoder 22 and the sense amplifier module 23, and transmits and receives signals to and from the external device.

The contact 596 is an electrode that extends in the direction z and is arranged in an opening of the insulating layer 595. The contact 596 is in contact with the semiconductor layer 591 and is electrically connected to a source terminal and a drain terminal of the transistor Tr.

The via 593 is a wiring arranged in the opening of the insulating layer 595 and extending in the direction Z. The via 593 electrically connects the contact 596 and the wiring 594. Although the wiring 594 shown in FIG. 7A is one layer, the wiring 594 is arranged with a plurality of layers along the direction Z through the insulating layer 595. A plurality of wirings 594 adjacent along the direction Z is connected by the vias 593. Similar to the plurality of wirings 594, adjacent wirings 594 and the connection electrodes P 2 along the direction Z are also connected by the vias 593.

An N+ diffused area DF sandwiched between P-wells PW on both sides is provided at the end of the peripheral circuit 20. The N+ diffusion area DF is connected to the connection electrode P 1 of the memory cell array 21 via the vias 593, the wirings 594, the contact 596, and the connection electrodes P 2 arranged in the semiconductor layer 591.

The memory cell array 21 includes the memory string set MSS, a slit ST, a source layer SLL, insulating layers 511, 513, and 518, a contact C 1, vias C 0, C 2, and C 3, an electrode 512, and wirings 514, 516, 517, and 519. For example, although not shown, a plurality of slits ST is provided, each of the plurality of slits ST is formed in a plate shape extending along the direction Z, and has a function of dividing a plurality of wirings 517, a plurality of insulating layers 518, and the wiring 510 for each block BLK. For example, the slit ST is an insulating layer having an insulating property similar to the insulating layer 518.

For example, the tier TIERT includes the wiring 516 serving as a bit line BL, a wiring 510 serving as a local bit line LBL, a plurality of pillars PL, the plurality of wirings 519, the plurality of vias C 0, the plurality of wirings 517 and the plurality of insulating layers 518. Further, for example, the tier TIERB includes the wiring 510 that functions as the local bit line LBL, the source layer SLL that functions as a source line SL, the plurality of pillars PL, the plurality of vias C 0, the plurality of wirings 517 and the plurality of insulating layers 518. The tier TIERB may include the plurality of wirings 516 and the plurality of wirings 519 that are electrically connected to the plurality of wirings 517. In addition, since the wiring 510 is divided for each block BLK, the local bit line LBL is divided into a plurality for each block BLK and are separated from each other.

The memory string set MSS includes the pillar PL, the plurality of wirings 517, and the plurality of insulating layers 518. The pillar PL extends along the direction Z. The plurality of pillars PL is provided in the direction Z. Further, the plurality of pillars PL is arranged along the direction Y. Two pillars PL shown in FIG. 7A are stacked along the direction Z. The pillar PL arranged on the wiring 516 side that functions as the bit line BL along the direction Z is included in the tier TIERT, and the pillar PL arranged on the source layer SLL side that functions as the source line SL along the direction Z is included in the tier TIERB.

The pillar PL included in each of the tier TIERT and tier TIERB includes a core layer, a semiconductor layer, insulating layers, and a charge storage layer. The core layer is a core of the pillar PL and is an insulator. The semiconductor layer is arranged around the core layer, the insulating layer is arranged around the semiconductor layer, the charge storage layer is arranged around the insulating layer, the insulating layer is arranged around the charge storage layer, and the wiring 517 is arranged around the insulating layer. The wirings 517 and the insulating layers 518 are alternately stacked along the direction Z. The plurality of wirings 517 is arranged so as to surround the outer insulating layers of the pillar PL, respectively. A portion where one of the plurality of wirings 517 faces the pillar PL is the memory cell MC, and the memory cell MC includes the memory cell transistor MT. Further, a portion where another one of the plurality of wirings 517 faces the pillar PL is a cell including a select transistor. That is, some of the plurality of wirings 517 function as the gate electrodes of the memory cell transistor MT, and the plurality of wirings 517 other than the plurality of wirings 517 that function as the gate electrodes of the memory cell transistor MT functions as gate electrodes of the select transistor.

The wiring 510 serving as the local bit line LBL is arranged between the plurality of wirings 517 and the plurality of insulating layers 518 included in the tier TIERT and the plurality of wirings 517 and the plurality of insulating layers 518 included in the tier TIERB. Further, the wiring 510 functioning as the local bit line LBL is arranged between and in contact with the insulating layer 518 farthest from the wiring 516 functioning as the bit line BL along the direction Z among the plurality of insulating layers 518 included in the tier TIERT and the insulating layer 518 farthest from the source layer SLL functioning as the source line SL along the direction Z among the plurality of insulating layers 518 included in the tier TIERB. Further, the pillar PL included in the tier TIERT is electrically connected to the pillar PL included in the tier TIERB via the wiring 510 that functions as the local bit line LBL.

Further, the plurality of wirings 517 extends along the directions X and Y. The wirings 517 serve as the word lines WL (WLB 0 to WLB 3 and WLT 0 to WLT 3) and select gate line SGDB 0 to SGDB 3 and SGDT 0 to SGDT 3. An end portion along the direction Y of the plurality of wirings 517 is arranged with the step part 26. By the step shape in the step part 26, each of the plurality of wirings 517 is sequentially exposed from the lower wiring 517, and is connected to the wiring 519 via the via C 0.

Further, the semiconductor layer of the pillar pl is connected to the wirings 516 and the source layer SLL. For example, the wirings 516 may serve as the bit line BL (for example, BL 0, BL 1, BL 2, and BL 3). The wiring 516 may be connected to the wiring 519 which functions as the bit line BL. For example, although the bit line BL shown in FIG. 7A extends along the direction X, the bit line BL may extend in the direction Y. The wiring 519 is connected to the connection electrode P 1 via the wiring 516. That is, the bit line BL is connected to the connection electrode P 1.

The electrode 512, the insulating layer 513, and the wiring 514 are arranged below the source layer SLL. The wiring 514 is arranged at a position corresponding to the N+ diffusion area DF of the peripheral circuit 20. The wiring 514 is connected to the connection electrode P2 of the peripheral circuit 20 via the via C 3, the wiring 519, the wiring 516, and the connection electrode P 1. The semiconductor layer 591 and the source layer SLL are electrically connected via the via C 1, the wirings 519, the wirings 516, and the connection electrode P 1. Although not shown, the wiring 514 is surrounded by an insulating layer, and a surface opposite to a surface in contact with the insulating layer 511 may be exposed from the insulating layer.

Of the plurality of wirings 517, the wiring 517 which is connected to the connection electrode P 1-1 via the via C 0 may be referred to as a “first word line W 1” in the step part 26. Similar to the wiring 517 connected to the connection electrode P 1-1 via the via C 0, the wiring 517 connected to the connection electrode P 1-2 via the via C 0 may be referred to as a “second word line W 2”. The memory cell MC (memory cell transistor MTT) using the first word line W1 as a gate electrode may be referred to as a “first memory cell (first memory cell transistor MTT).” The memory cell MC (memory cell transistor MTT) having the second word line W2 as a gate electrode may be referred to as a “second memory cell (second memory cell transistor MTT).”

In this instance, the plurality of first memory cells is arranged in series between the wiring 510 functioning as the local bit line LBL and the source layer SLL functioning as the source line SL and electrically connected to the wiring 510 and the source layer SLL. The plurality of second memory cells is arranged in series between the wiring 516, which functions as the bit line BL, and the wiring 510, which functions as the local bit line LBL, and is electrically connected to the wiring 516 and the wiring 510. Therefore, a plurality of first memory cells and second memory cells are both electrically connected to a common bit line BL. The first transistor Tr 1 is connected to the first word line W 1 via the connection electrode P 1-1 and the connection electrode P 2-4. The second transistor Tr 2 is connected to the second word line W 2 via the connection electrode P 1-2 and the connection electrode P 2-5. The third transistor Tr 3 is connected to the bit line BL via the connection electrode P 1-3 and the connection electrode P 2-6.

Referring to FIG. 8, the end cross-sectional construction of the memory string set MSS is described in more detail. In addition, the end cross-sectional construction of the memory string set MSS is briefly described with reference to FIG. 7A, so that the description of the content related to the memory string set MSS described briefly with reference to FIG. 7A may be omitted in the description with reference to FIG. 8. As shown in FIG. 8, the memory string set MSS includes the tier TIERB and the tier TIERT. To facilitate understanding of the end cross-sectional construction of the memory string set MSS, insulating layers such as insulating layers 518 and 511 shown in FIG. 7A have been omitted in the memory string set MSS shown in FIG. 8.

The tier TIERB contains the local memory strings LMSB 0 to LMSB 3. Each of the local memory strings LMSB 0 to LMSB 3 includes and is formed with the insulating layer 513, the sourcing layer SLL, the plurality of wirings 517, the plurality of vias C 4, and the wiring 510. The insulating layer 513, the source layer SLL, the plurality of wirings 517, the via C 4, and the wiring 510 are stacked in this order from top to bottom along the direction Z. For example, the insulating layer 513 is a semiconductor substrate.

The source layer SLL acts as the source line SL. The plurality of wirings 517 function as select gate lines SGSB, the word lines WLB 0 to WLB 3, and select gate line SGDB in order from the source layer SLL to the wirings 510 along the direction Z. The wiring 510 serves as the local bit line LBL.

For example, the source layer SLL, the plurality of wirings 517 serving as the select gate lines SGSB and the word lines WLB 0 to WLB 3, and the wirings 510 are formed in a plate manner extending along parallel planes along the directions X and Y and are commonly arranged in the local memory strings LMSB 0 to LMSB 3. For example, the plurality of wirings 517 serving as the select gate lines SGDB serve as the select gate lines SGDB 0 to SGDB 3 corresponding to each of the local memory strings LMSB 0 to LMSB 3. The plurality of wirings 517 serving as select gate lines SGDB 0 to SGDB 3 extends along the direction X and are spaced apart from each other along the direction Y and arranged independently. That is, the plurality of wirings 517 serving as respective select gate lines SGDB 0 to SGDB 3 is arranged in the same layer and corresponds to respective local memory strings LMSB 0 to LMSB 3.

The memory pillars PL corresponding to each of the local memory strings LMSB 0 to LMSB 3 are arranged between the source layer SLL and the wirings 510. The memory pillar PL is arranged to extend along an axis Z. The memory pillar PL extends through the plurality of wirings 517. A bottom of the source layer SLL side of the memory pillar PL along the direction Z contacts the source layer SLL. In the memory pillar PL included in the local memory string LMSB shown in FIG. 8, the semiconductor layers described with reference to FIG. 7A are denoted as semiconductor layers 520, the insulating layers and charge storage layers described with reference to FIG. 7A are denoted as charge storage layers 521 collectively, and the core layers described with reference to FIG. 7A are omitted in the diagram. For example, the semiconductor layer 520 in a transistor may be referred to as a channel.

Upper ends of the semiconductor layer 520 and the charge storage layer 521 (the wiring 510 side along the direction Z) are located above the wiring 517, which functions as the select gate line SGDB, and lower ends of the semiconductor layer 520 and the charge storage layer 521 (the source layer SLL side along the direction Z) contacts the source layer SLL. The charge storage layer 521 surrounds and covers a side surface of the semiconductor layer 520.

In the memory pillar PL included in the local memory string LMSB, portions intersecting the plurality of wirings 517 function as the select transistor STB 1, the memory cell transistors MTB 3 to MTB 0, and the select transistor STB 2, in order from the wiring 510 to the source layer SLL along the direction Z.

The columnar via C 4 is arranged on the upper surface (along the direction Z toward the wirings 510) of the semiconductor layers 520 in the memory pillar PL included in the local memory string LMSB. For example, a diameter of the via C 4 is less than a diameter of the semiconductor layers 520, and an upper end of the via C 4 contacts a corresponding wiring 510 (local bit line LBL). An under surface (the source layer SLL side along the direction Z) of the semiconductor layer 520 in the memory pillar PL included in the local memory string LMSB contacts the source layer SLL. Thus, the source layer SLL and the wirings 510 are connected to each other through the semiconductor layer 520 in the memory pillar PL.

The tier TIERT contains local memory strings LMST 0 to LMST 3. Each of the local memory strings LMST 0 to LMST 3 includes the wiring 510 corresponding to the local bit line LBL, the plurality of vias C 5, the plurality of wirings 517, the via C 0, and the wiring 516 corresponding to the bit line BL. The wiring 510, the plurality of vias C 5, the plurality of wirings 517, the via C 0, and the wiring 516 are laminated in this order from top to bottom along the direction Z. In addition, the wiring 510 corresponding to the local bit line LBL are shared by the tier TIERB and tier TIERT and are commonly arranged.

As noted above, the wirings 510 serve as the local bit line LBL. The plurality of wirings 517 functions as a select gate line SGDB, word lines WLT 0 to WLT 3, and the select gate line SGDT in order from the local bit line LBL to the wiring 516 along the direction Z. The wiring 516 serves as the local bit line LBL. The wiring 516 serves as the bit line BL.

For example, the plurality of wirings 517 that function as the select gate lines SGST and the word lines WLT 0 to WLT 3 are formed in a plate shape that extends along parallel planes along the direction X and the direction Y, and are commonly arranged in the local memory strings LMST 0 to LMST 3. Also, for example, the wirings 516 extend along the direction Y and are segmented along the direction X in the same units as the bit line BL and are commonly arranged in the local memory strings LMST 0 to LMST 3. For example, the plurality of wirings 517 serving as select gate lines SGDT serves as the select gate lines SGDT 0 to SGDT 3 corresponding to each of the local memory strings LMST 0 to MST 3. The plurality of wirings 517 serving as the select gate lines SGDT 0 to SGDT 3 extend along the direction X and are spaced apart from each other along the direction Y and arranged independently. That is, the plurality of wirings 517 serving as respective select gate lines SGDT 0 to SGDT 3 is arranged in the same layer and correspond to respective local memory strings LMST 0 to LMST 3.

The memory pillar PL is arranged between the wiring 510 and wiring 516. The memory pillar PL between the wiring 510 and wiring 516 is included in the local memory string LMST. The memory pillar PL is arranged to extend along the axis Z. The memory pillar PL extends through the plurality of wirings 517. Bottoms of the wirings 510 side of t he memory pillar PL along the direction Z touch the wirings 510. The memory pillar PL between the wiring 510 and the wiring 516 includes a configuration similar to the memory pillar PL between the source layer SLL and the wiring 510.

The upper ends of the semiconductor layer 520 and the charge storage layer 521 (the wiring 516 side along the direction Z) are located above the wiring 517, which functions as the select gate line SGDT, and the lower ends of the semiconductor layer 520 and the charge storage layer 521 (the wiring 510 side along the direction Z) contact the wiring 516. The charge storage layer 521 surrounds and covers the side surface of t he semiconductor layer 520.

In the memory pillar PL included in the local memory string LMST, portions intersecting the plurality of wirings 517 function as the select transistor STT 1, the memory cell transistors MTT 3 to MTT 0, and the select transistor STT 2 in order from the wiring 516 to the wiring 510 along the direction Z.

The columnar via C 0 is arranged on an upper surface (along the direction Z toward the wirings 516) of the semiconductor layers 520 in the memory pillar PL included in the local memory string LMST. For example, a diameter of the via C 0 is less than a diameter of the semiconductor layer 520, and an upper end of the via C 0 contacts the corresponding wiring 516 (bit line BL). The columnar via C 5 is arranged on a lower surface (the wirings 510 side along the direction Z) of the semiconductor layers 520 in the memory pillar PL included in the local memory string LMST. For example, a diameter of the via C 5 is less than a diameter of the semiconductor layers 520, and a lower end of the via C 5 contacts a corresponding wiring 510 (local bit line LBL). Therefore, the wiring 510 and the wiring 516 are connected to each other through the semiconductor layers 520 in the memory pillar PL.

### 1-4. Schematic Layout and End Section Structure of Semiconductor Memory 10A

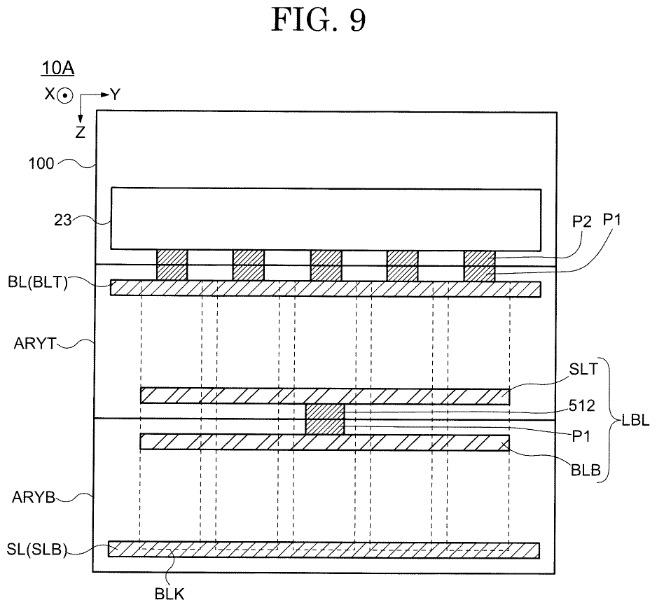

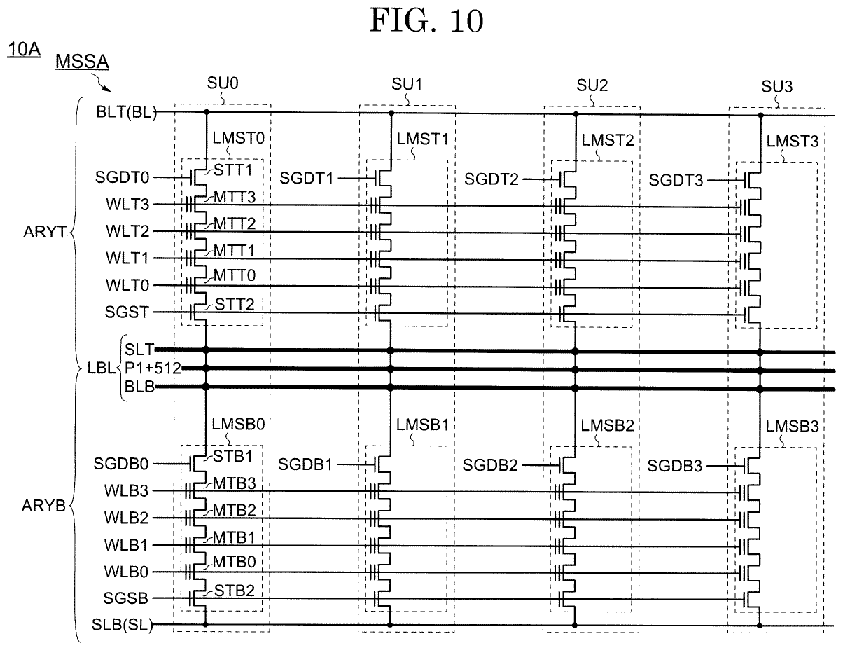

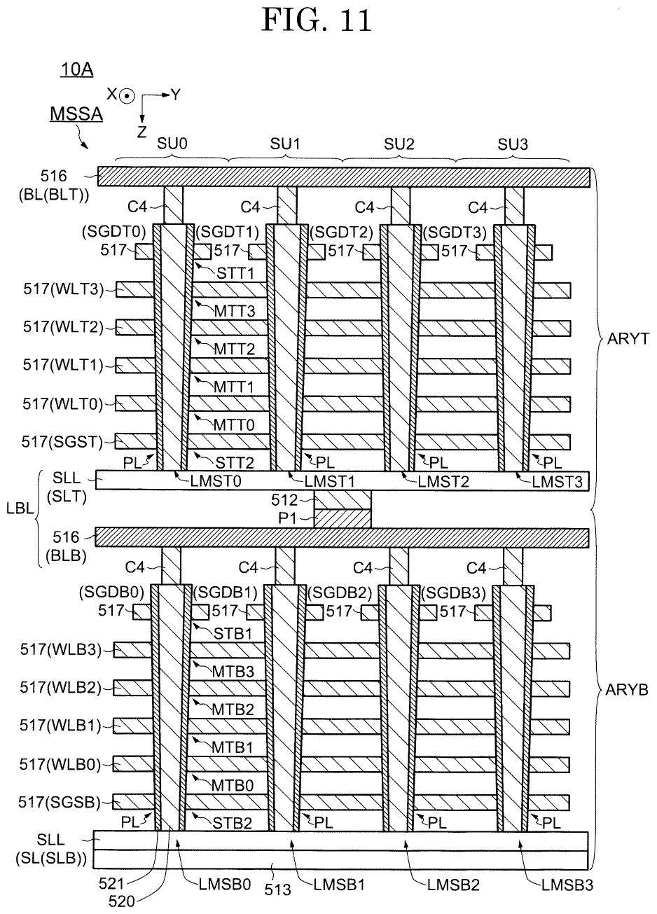

Referring to FIG. 9 to FIG. 11, a schematic layout and an end cross-sectional structure of a semiconductor storage device 10A will be described. FIG. 9 is an end view schematically showing the end cross-sectional structure of the semiconductor storage device 10A. FIG. 10 is a circuit diagram showing a circuit configuration of a memory string set MSSA of the semiconductor storage device 10A. FIG. 11 is an end view showing an end cross-sectional view of the memory string set MSSA of the semiconductor storage device 10A.

The semiconductor storage device 10A includes at least the following configurations 1 to 3 as compared to the semiconductor storage device 10.
(Configuration 1) A configuration in which the tier TIERB and the tier TIERT in one IC chip 101 of the semiconductor storage device 10 are replaced with an array ARYB and an array ARYT in the semiconductor storage device 10A.
(Configuration 2) The array ARYB and the array ARYT are IC chips which differ from each other. That is, the semiconductor storage device 10A has a configuration in which two IC chips are stacked.
(Configuration 3) The local bit line LBL in the semiconductor storage device 10 includes the wiring 510, whereas the local bit line LBL in the semiconductor storage device 10A includes at least the wiring 516 (dummy bit line BLB) and the connection electrode P 1 (first bonding electrode) included in the array ARYB, and the electrode 512 (second bonding electrode) and the source layer SLL (dummy source line SLT) included in the array ARYT.

Configurations other than the configurations 1 to 3 and configurations other than the related configurations of the configurations 1 to 3 in the semiconductor storage device 10A are the same as the configurations of the semiconductor storage device 10. In the description of the semiconductor storage device 10A, the description of the same or similar content as the semiconductor storage device 10 may be omitted, and the same or similar content as the semiconductor storage device 10 may be described as required.

The array ARYB may be referred to as a “first chip” and the array ARYT may be referred to as a “second chip.”

First, referring to FIG. 9 and FIG. 11, a structure of the semiconductor storage device 10A will be described. For example, as shown in FIG. 9, the semiconductor storage 10A includes the array ARYB, the array ARYT, and the IC chip 100.

The array ARYB and the array ARYT include a configuration similar to the stacked structure of the IC chip 101 shown in FIG. 7A, but without the configuration related to wirings 510. The configuration of the IC chip 100 in the semiconductor storage device 10A is similar to that of the IC chip 100 shown in FIG. 7A.

The array ARYB includes a configuration in which the wiring 510 serving as the local bit line LBL in the tier TIERB is replaced with the wiring 516 (dummy bit line BLB) serving as the local bit line LBL and the connection electrode P 1 electrically connected to the wiring 516. Other configurations of the array ARYB are similar to the tier TIERB.

The array ARYT includes the following configurations 4 and 5. (Configuration 4) A configuration in which the wiring 510 functioning as the local bit line LBL in the tier TIERT is replaced with the electrode 512 functioning as the local bit line LBL and the source layer SLL functioning as the dummy SLT in the array ARYT. (Configuration 5) A configuration in which the via C 0 in the tier TIERT is replaced with the via C 4 in the array ARYT.

Configurations other than the configuration 4 and the configuration 5 in the array ARYT, and configurations other than configurations related to the configuration 4 and the configuration 5 are the same as the tier TIERT.

The array ARYB, the array ARYT and the IC chip 100 are stacked in this order from below along the direction Z. That is, the array ARYB, the array ARYT and the IC chip 100 and the sense amplifier module 23 are stacked in this order from below along the direction Z. Further, the array ARYB is bonded to and electrically connected to the electrode 512 which is electrically connected to the dummy source line SLT of the array ARYT using the connection electrode P 1 which is electrically connected to the dummy bit line BLB. Further, the array ARYT also includes the plurality of connection electrodes P 1 electrically connected to the bit line BL (BLT). Each of the plurality of connection electrodes P 1 is electrically connected to the corresponding connection electrode P 2 of the plurality of connection electrodes P 2 included in the IC chip 100 and is electrically connected to the sense amplifier module 23 via the connection electrode P 2.

Next, referring to FIG. 10, an electric configuration (circuit configuration) of the memory string set MSSA included in the semiconductor storage device 10A will be described. For example, as shown in FIG. 10, the semiconductor storage 10A includes the memory string set MSSA. The configuration other than the configuration 1 to the configuration 3 in the memory string MSSA is the same as the configuration of the memory string set MSS of the semiconductor storage device 10. Incidentally, the electrical configuration in the memory string MSSA is similar to the electrical configuration of the memory string set MSS.

The semiconductor storage device 10A described above has the same advantages as the semiconductor storage device 10. Further, the semiconductor storage device 10A includes a configuration in which the connection electrode P 1 and the electrode 512 are bonded. For example, in the case where a width of the wiring of the two chips is narrow (a narrow pitch), misalignment at the time of bonding of the two chips is a problem. A width (area) of the connection electrode P 1 and the electrode 512 in the semiconductor storage device 10A is thicker (larger) than the dummy bit line BLB. Since the arrays ARYB and ARYT in the semiconductor storage device 10A are bonded to each other by the connection electrode P 1 and the electrode 512 having large areas, effects of the misalignment can be suppressed.

### 1-5. Threshold Distribution of Memory Cell Transistor MT

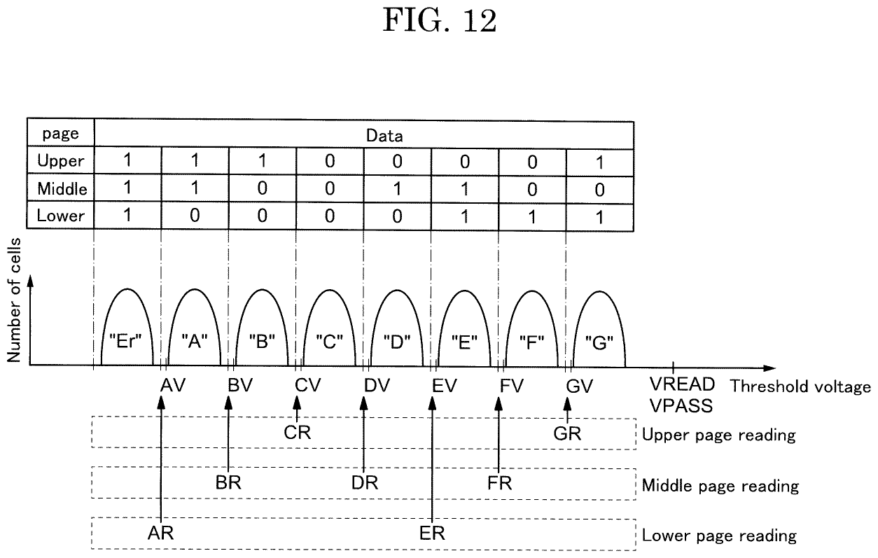

Referring to FIG. 12, a threshold distribution of the memory cell transistor MT will be described. FIG. 12 is a diagram showing a threshold distribution of memory cell transistors MT of the memory cell MC of the semiconductor storage devices 10 and 10A. In FIG. 12, although a Triple Level Cell (TLC) will be described as an example of the threshold distribution of the memory cell transistor MT,, in the memory cell transistor MT, a Quad Level Cell (QLC), a Multi Level Cell (MLC), a Single Level Cell (SLC), and the like may be used.

FIG. 12 shows an exemplary threshold distribution, data (Data) assignment, read voltage, and verify voltage of the memory cell transistor MT. A vertical axis of the threshold distribution shown in FIG. 12 corresponds to the number of memory cell transistors MT (Number of cells) and the horizontal axis corresponds to the threshold voltage Vth (Threshold Voltage) of the memory cell transistor MT.

As shown in FIG. 12, the plurality of memory cell transistors MT in the TLC manner form eight threshold distributions. The eight threshold distributions are sometimes referred to as write levels. The write level is expressed as “Er” level, “A” level, “B” level, “C” level, “D” level, “E” level, “F” level, and “G” level in order from the lowest threshold voltage. For example, different 3-bit data shown below are assigned to these write levels. This 3-bit data is referred to as the lower (Lower), middle (Middle), and upper (Upper) bits.

A set of Lower bits held by the memory cell transistor MT connected to the same word line WL is denoted as a Lower page (Page), a set of Middle bits is denoted as a Middle page, and a set of Upper bits is denoted as an Upper page. The write operation and the read operation of the data are performed on a page-by-page basis.
“Er” level: “111” data
“A” level: “110” data
“B” level: “100” data
“C” level: “000” data
“D” level: “010” data
“E” level: “011” data
“F” level: “001” data
“G” level: “101” data

In addition, the above items are represented in the order of Upper, Middle, Lower.

A verify voltage used in a respective verify operation is set between adjacent threshold distributions. Specifically, verify voltages AV, BV, CV, DV, EV, FV, and GV are set corresponding to each of the “A” level, the “B” level, the “C” level, the “D” level, the “E” level, the “F” level, and the “G” level.

For example, the verify voltage AV is set between a maximum threshold voltage at the “Er” level and a minimum threshold voltage at the “A” level. When the verify voltage AV is applied to the memory cell transistor MT, the memory cell transistor MT whose threshold voltage is included in the “Er” level is turned on, and the memory cell transistor MT whose threshold voltage is included in the threshold distribution which is equal to or greater than the “A” level is turned off.

Other verify voltages BV, CV, DV, EV, FV, and GV are also set in the same way as the verify voltage AV. The verify voltage BV is set between the “A” level and the “B” level. The verify voltage CV is set between the “B” level and the “C” level. The verify voltage DV is set between the “C” level and the “D” level. The verify voltage EV is set between the “D” level and the “E” level. The verify voltage FV is set between the “E” level and the “F” level. The verify voltage GV is set between the “F” level and the “G” level.

For example, the verify voltage AV may be set to 0.8 V, the verify voltage BV may be set to 1.6 V, the verify voltage CV may be set to 2.4 V, the verify voltage DV may be set to 3.1 V, the verify voltage EV may be set to 3.8 V, the verify voltage FV may be set to 4.6 V, and the verify voltage GV may be set to 5.6 V. However, these verify voltages AV to GV are not limited to the above voltage values. The verify voltages AV to GV may be appropriately set in stages, for example, in a range of 0.0 V to 7.0 V.

The read voltage (verify voltage) used in the respective read operation (or verify operation) is set between the adjacent threshold distributions. For example, a read voltage AR that determines whether the threshold voltage of the memory cell transistor MT is included in the “Er” level or included in the “A” level or more is set between the maximum threshold voltage at the “Er” level and the minimum threshold voltage at the “A” level.

Other read voltages BR, CR, DR, ER, FR, AND GR, as well as the read voltage AR, are set between neighboring levels. For example, the read voltage BR is set between the “A” level and “B” level, the read voltage ER is set between the “D” level and “E” level, and the read voltage GR is set between the “F” level and “G” level.

A voltage VREAD applied to a non-selected word line WL during reading is set to a voltage value that is higher than the largest threshold voltage of the highest threshold distribution (for example, “G” level). When the voltage VREAD is applied to a gate terminal of the memory cell transistor MT, the memory cell transistor MT is turned on regardless of the data stored by the memory cell transistor MT.

The verify voltages AV, BV, CV, DV, EV, FV, and GV are set to voltages higher than the read voltages AR, BR, CR, DR, ER, FR, and GR, respectively. That is, the verify voltages AV to GV are set near lower tails of the threshold distributions of the “A” level, “B” level, “C” level, “D” level, “E” level, “F” level, and “G” level, respectively.

### 1-6. Example of Operation in Semiconductor Storage Device

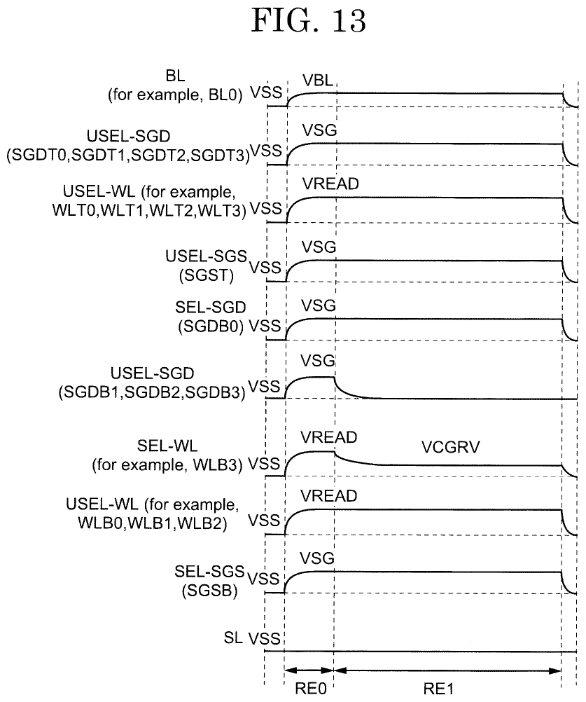

Referring to FIG. 13 to FIG. 23, operations in the semiconductor storage device 10 and the semiconductor storage device 10A will be described. The operations in the semiconductor storage device 10A are the same as those in the semiconductor storage device 10, and the operations in the semiconductor storage device 10 are described here, and the description of the operations of the semiconductor storage device 10A is omitted. In some cases, the operations in the semiconductor storage device 10A are described as required.

In the description herein and the drawings of the respective operations of the semiconductor storage device, there are cases where “selected” is added to the memory cell transistor MT to be operated and the components including (or corresponding to) the memory cell transistor MT to be operated, and “non-selected” is added to the memory cell transistors MT that are not the target of the operation and the components not including (or not corresponding to) the memory cell transistor MT to be operated, and they are distinguished from each other. For example, the select gate lines SGD and SGS connected to the selected select transistors STT1 and STT2 included in the local memory string (selected local memory string) containing the memory cell transistor (selected memory cell transistor) to be operated may be referred to as selected select gate lines SGD and SGS (or selected SGD and selected SGS). Also, for example, the select gate lines SGD and SGS connected to the select transistors STT1 and STT2 (non-selected transistors STT1 and STT2) included in the local memory string (non-selected local memory string) that does not include the select memory cell transistor may be referred to as non-selected gate lines SGD and SGS (or non-selected SGD and non-selected SGS). Further, string units including the selected memory cell transistor are written as selected string units, and those not including the selected memory cell transistor are written as non-selected string units, tiers including the selected memory cell transistor are written as selected tiers (for example, a selected tier TIERB, a selected tier TIERT), and those not including the selected memory cell transistor are written as non-selected tiers. Further, “SEL-” or “PROG-” in the timing chart indicating the respective operations of the semiconductor storage device 10 refers to a signal line (control signal line) connected to the selected select transistor and the selected memory cell transistor. “USEL-” or “Inhibit-” in the timing chart indicating the respective operations of the semiconductor storage device 10 refers to a signal line (control signal line) connected to the non-selected transistor and the non-selected memory cell transistor.

Each signal line is controlled by the sequencer 16 or the like. The sequencer 16 controls the row decoder 22, the sense amplifier module 23, the column decoder 25, the voltage generation circuit 18, and the like so as to supply a voltage to each signal line.

### 1-6-1. Example of Read Operation in Semiconductor Storage Device

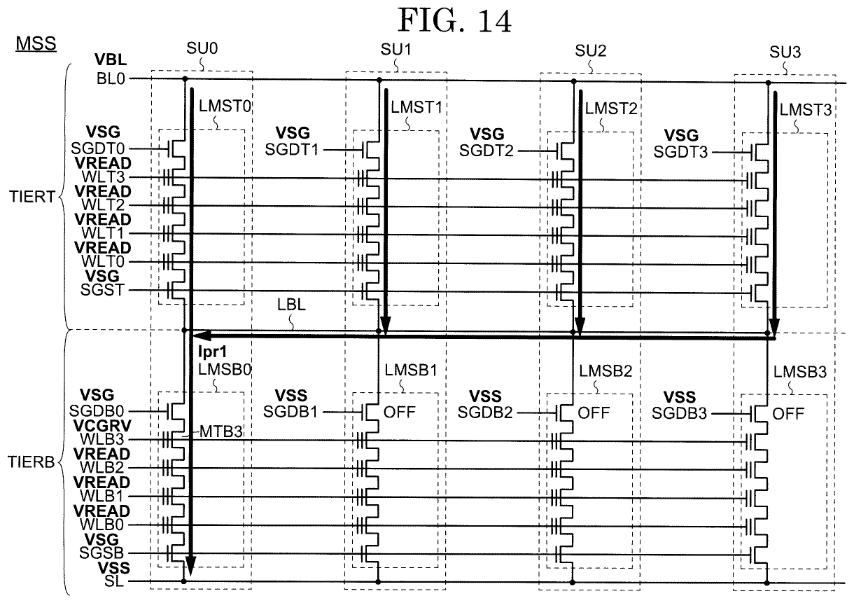

Referring to FIG. 13 and FIG. 14, the read operation of the data in the semiconductor storage device 10 will be described. FIG. 13 is a timing chart showing waveforms of various signals of the read operation in the semiconductor storage device 10. FIG. 14 is a circuit diagram for explaining the memory string set MSS in the read operation of the semiconductor storage device 10. In the circuit diagram shown in FIG. 14, reference signs of the transistors in the circuit diagram shown in FIG. 3 are omitted. In one example of a read operation of a semiconductor storage device, an example is shown in which the selected transistor is the memory cell transistor MTB 3.

As shown in FIG. 13, the read operation includes at least a period RE 0 and a period RE 1. The source line SL is supplied with a voltage VSS for all periods shown in FIG. 13.

As shown in FIG. 13, up to the period RE 0, the bit line BL (for example, BL 0), the select gate lines SGDT 0 to SGDT 3 (USEL-SGD), the word lines WLT 0 to WLT 3 (USEL-WL), the select gate line SGST (USEL-SGS), the select gate line SGDB 0 (SEL-SGD), the word line WLB 3 (SEL-WL), and the select gate line SGSB (SEL-SGS) are supplied with the voltage VSS and each signal line is in a standby state. In this case, the select transistor STT 1, the memory cell transistors MTT 0 to MTT 3, the select transistor STT 2, the select transistors SGDB 0 to SGDB 3, the memory cell transistor MTB 3, the memory cell transistors MTB 0 to MTB 2, and the select transistor STB 2 connected to the select gate lines SGDT 0 to SGDT 3 are in an off state.

In the period RE 0, the bit line BL is supplied with a voltage VBL. The word line WLT 0 to WLT 3, the selected word line WLB 3, and the word lines WLB 0 to WLB 2 are supplied with the voltage VREAD. The select gate lines SGDT 0 to SGDT 3, the select gate line SGST, the select gate lines SGDB 0 to SGDB 3, and the select gate line SGSB are supplied with a voltage VSG. Thus, the select transistor STT 1 connected to the select gate lines SGDT 0 to SGDT 3, the select transistor STB 2 connected to the select gate lines SGDB 0 to SGDB 3, the memory cell transistors MTT 0 to MTT 3 electrically connected to the respective signal lines, the select transistor STT 2, the memory cell transistor MTB 3, the memory cell transistors MTB 0 to MTB 2, and the select transistor STB 2 are in an on state.

Consequently, in the period RE 0, the local memory strings LMST 0 to LMST 3 of the non-selected tier TIERT and the local memory strings LMSB 0 to LMSB 3 of the selected tier TIERB are conductive in the memory string set MSS connected to the bit line BL. That is, in the period RE 0, all the local memory string LMS (LMST 0 to LMST 3 and LMSB 0 to LMSB 3) of the non-selected tier TIERT and the selected tier TIERB in the memory string set MSS are conductive.

In the period RE 1, the bit line BL is subsequently supplied with the voltage VBL. The word lines WLT 0 to WLT 3 and the word lines WLB 0 to WLB 2 are subsequently supplied with the voltage VREAD. The select gate lines SGDT 0 to SGDT 3, the select gate line SGST, the select gate line SGDB 0, and the select gate line SGSB are subsequently supplied with the voltage VSG. Thus, the select transistor STT 1, the memory cell transistors MTT 0 to MTT 3, the select transistor STT 2, the select transistor SGDB 0, and the select transistor STB 2 continue to remain in the on state. Further, in the period RE 1, the voltage VSS is supplied to the select gate lines SGDB 1 to SGDB 3, and a voltage VCGRV is supplied to the selected word line WLB 3. Thus, the select transistors SGDB 1 to SGDB 3 are in the off state and the memory cell transistor MTB 3 and the memory cell transistors MTB 0 to MTB 2 are in the on state.

For example, the voltage VREAD is greater (higher) than the voltage VSG, the voltage VSG is greater (higher) than the voltage VSS, and the voltage VCGRV is greater (higher) than the voltage VSS. For example, the voltage VSS is a voltage to be a reference (reference voltage), and may be 0 V corresponding to a voltage such as a ground voltage.

Consequently, in the period RE 1, in the memory string set MSS connected to the bit line BL, all of the local memory strings LMST 0 to LMST 3 of the non-selected tier TIERT are conductive, the local memory string LMSB 0 of the selected tier TIERB is conductive, and the local memory strings LMSB 1 to LMSB 3 of the selected tier TIERB are not conductive.

That is, in the period RE 1, the bit line BL 0 is electrically connected with the source line SL via the local memory strings LMST 0 to LMST 3 of the non-selected tier TIERT, the local bit line LBL, and the local memory string LMSB 0 of the selected tier TIERB. Thus, as shown by the thick solid line in FIG. 14, in the memory string set MSS of the read operation, current flows from the bit line BL 0 to the source line SL via the local memory strings LMST 0 to LMST 3 of the non-selected tier TIERT, the local bit line LBL, and the local memory string LMSB 0 of the selected tier TIERB. For example, the current value at this time is a current value Ipr 1. The sense amplifier module 23 electrically connected to the bit line BL 0 senses the current Ipr 1, and the semiconductor storage device 10 can read the data.

In a period after the period RE 1, the same voltage as the period until the period RE 0 is supplied to each signal line, and each transistor is in the off state.

As described above, the semiconductor storage device 10 executes the read operation.

For example, since the semiconductor storage device 10P in the comparative example does not include the local bit line LBL, it includes one memory string (that is, the string unit SU includes one memory string) in which the memory strings corresponding to the local memory string LMST and the local memory string LMSB in the semiconductor storage device 10 are combined. Therefore, in the semiconductor storage device 10P, if the number of stacked layers increases, a resistance value of the memory string in the semiconductor storage device 10P increases, so that the current value flowing through the memory string in the read operation in the semiconductor storage device 10P decreases, and thus it becomes difficult to sense data stored in respective memory cell transistors using the sense amplifier module. That is, if the number of stacked layers in the semiconductor storage device 10P is increased, performance of the read operation in the semiconductor storage device 10P is lowered.

Meanwhile, as described above, the semiconductor storage device 10 includes the local bit line LBL, and select transistors SGD and SGS. Consequently, while the tier TIERT is electrically connected to all of the transistors in the non-selected “USEL-” signal line and is a non-selected tier, since all of the local memory strings LMST 0 to LMST 3 in the non-selected tier TIERT are conductive, the tier TIERT can be made less resistive than the case where one local memory string LMST is conductive, and approximately four times more current can be drawn to the local memory string LMSB 0 including the selected memory cell transistor MTB 3 in the selected tier TIERB than the case where one local memory string LMST is conductive. For example, the semiconductor storage device 10 differs from the semiconductor storage device 10P in the comparative example in at least (1) arrangement of the memory cell array 21 and (2) introduction of the local bit line LBL. The semiconductor storage device 10 can reduce the resistance value between the bit line BL and the source line SL more than the semiconductor storage device 10P in the comparative example by (2). Further, as in the semiconductor storage device 10P in the comparative example, even in the case where the arrangement of the memory cell array 21 includes the dummy step (the arrangement before deleting the dummy step), (2) is possible, and it is possible to reduce the resistance value between the bit line BL and the source line SL. Therefore, it is possible to suppress a decrease in the current flowing through the memory string in the read operation, and prevent the data stored in each memory cell transistor using the sense amplifier module from becoming difficult to sense. That is, the semiconductor storage device 10 can suppress a decrease in the performance of the read operation in the semiconductor storage device 10 even if the number of stacked layers increases.

### 1-6-2. Example of Write Operation in Semiconductor Storage Device

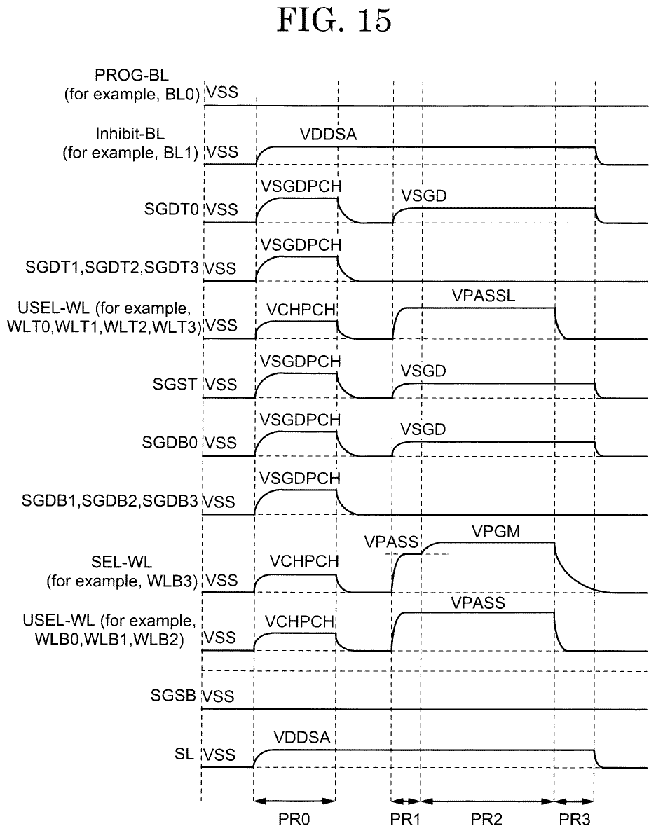

Referring to FIG. 15 to FIG. 19, the program operation in the semiconductor storage device 10 and the semiconductor storage device 10A will be described. The program operation in the semiconductor storage device 10A is the same as that in the semiconductor storage device 10, and the program operation in the semiconductor storage device 10 is described here, and the description of the operation of the semiconductor storage device 10A is omitted. In some cases, the program operation in the semiconductor storage device 10A will be described as required.

### 1-6-2-1. First Example of Program Operation of Semiconductor Storage Device

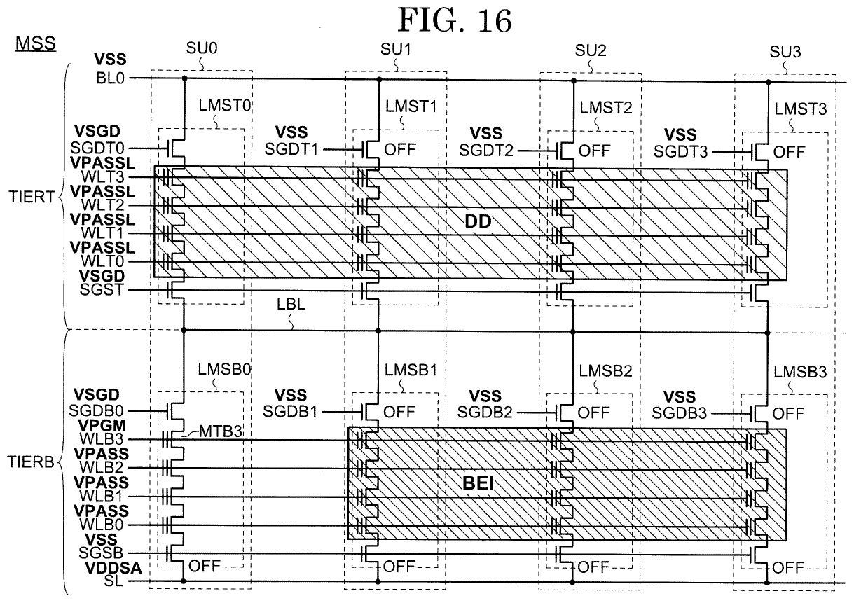

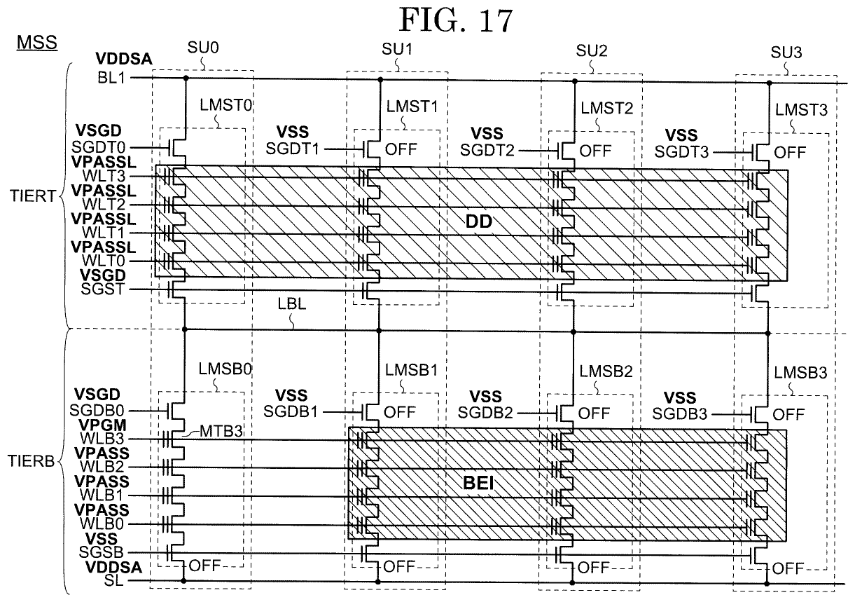

Referring to FIG. 15 to FIG. 17, a first example of the program operation in the semiconductor storage device 10 will be described. The first example is the case where the tier TIERB is a selected tier. FIG. 15 is a timing chart showing waveforms of various signals of the program operation in the semiconductor storage device 10. FIG. 16 and FIG. 17 are circuit diagrams for explaining the memory string set MSS in the program operation of the semiconductor storage device 10. In a first example of a program operation of a semiconductor storage device, an example is shown in which the selected transistor is the memory cell transistor MTB 3. In the circuit diagram shown in FIG. 16 and FIG. 17, the reference signs of the transistor in the circuit diagram shown in FIG. 3 are omitted.

As shown in FIG. 15, the program operation includes at least the period PR 0, the period PR 1, a period PR 2, and a period PR 3. A write bit line BL (PROG-BL, BL 0) and the select gate line SGSB are supplied with the voltage VSS for all periods shown in FIG. 15.

As shown in FIG. 15, up to the period PR 1, the write bit line BL (BL 0, PROG-BL), a non-write bit line Inhibit-BL (BL 1, Inhibit-BL), the select gate line SGDT 0 (UEL-SGD), the select gate lines SGDT 1 to SGDT 3 (USEL-SGD), the word lines WLT 0 to WLT 3 (USEL-WL), the select gate line SGST (USEL-SGS), the select gate line SGDB 0 (SEL-SGD), the word line WLB 3 (SEL-WL), the word lines WLB 0 to WLB 2 (USEL-WL), and the source line SL are supplied with the voltage VSS and each signal line is in the standby state. In this case, the select transistor STT 1, the memory cell transistors MTT 0 to MTT 3, the select transistor STT 2, the select transistors SGDB 1 to SGDB 3, the memory cell transistor MTB 3, the memory cell transistors MTB 0 to MTB 2, and the select transistor STB 2 are in the off state. Therefore, the local memory strings LMST 0 to LMST 3 of the non-selected tier TIERT and the local memory strings LMSB 0 to LMSB 3 of the selected tier TIERB are not conductive.

For example, in the period PR 0, a non-write bit line BL 1 is supplied with a voltage VDDSA, the source line SL is supplied with the voltage VSS, the select gate line SGDT 0, the select gate lines SGDT 1 to SGDT 3, the select gate line SGST, and the select gate line SGDB 0 are supplied with a voltage VSGDPCH, and the word lines WLT 0 to WLT 3, the word line WLB 3, and the word lines WLB 0 to WLB 2 are supplied with a voltage VSCHPCH. In this case, the select transistor STT 1, the memory cell transistors MTT 0 to MTT 3, the select transistor STT 2, the select transistors SGDB 0 to SGDB 3, the memory cell transistor MTB 3, and the memory cell transistors MTB 0 to MTB 2 are in the on state and the select transistor STB 2 is in the off state. Thus, the local memory strings LMST 0 to LMST 3 of the non-selected tier TIERT are conductive and the local memory strings LMSB 0 to LMSB 3 of the selected tier TIERB are conductive. Consequently, for example, current flows from the bit line BL towards the local memory strings LMSB 0 to LMSB 3 of the selected tier TIERB via the local memory strings LMST 0 to LMST 3 of the non-selected tier TIERT, and channels of the transistors are precharged to the voltage VDDSA or the voltage VSS depending on the voltage VDDSA or the voltage VSS of the bit line BL.

In addition, in the period PR 0 shown in FIG. 15, although an example in which a write bit line PROG-BL and the select gate line SGSB are supplied with the voltage VSS is shown, the voltage supplied to the write bit line PROG-BL and the select gate line SGSB in the period PR 0 in the semiconductor storage device 10 is not limited to the example shown in FIG. 15. For example, the write bit line PROG-BL may be supplied with the voltage VDDSA. Further, for example, in the period PR0 in the semiconductor storage device 10, the source line SL may be supplied with the voltage VDDSA, the select gate lines SGDT 0 to SGDT 3 may be supplied with the voltage VSS, and the select gate line SGSB may be supplied with the voltage VSGDPCH. In this case, the select transistor STT 1 is in the off state, and the memory cell transistors MTT 0 to MTT 3, the select transistor STT 2, the select transistors SGDB 0 to SGDB 3, the memory cell transistor MTB 3, the memory cell transistors MTB 0 to MTB 2, and the select transistor STB 2 are in the on state. Therefore, the local memory strings LMST 0 to LMST 3 of the non-selected tier TIERT and the local memory strings LMSB 0 to LMSB 3 of the selected tier TIERB are conductive. Consequently, for example, the voltage VDDSA is supplied from the source line SL to the local memory strings LMST 0 to LMST 3 of the non-selected tier TIERT via the local memory strings LMSB 0 to LMSB 3 of the selected tier TIERB, and channels of the transistors are precharged to the voltage VDDSA.

In addition, in a period between the period PR 1 and the period PR 2, the non-write bit line BL 1 and the source line SL remain in a state in which the voltage VDDSA is supplied, and the signal lines other than the non-write bit line BL 1 and the source line SL are supplied with the voltage VSS. In this case, the select transistor STT 1, the memory cell transistors MTT 0 to MTT 3, the select transistor STT 2, the select transistors SGDB 0 to SGDB 3, the memory cell transistor MTB 3, the memory cell transistors MTB 0 to MTB 2, and the select transistor STB 2 are in the off state. Therefore, the local memory strings LMST 0 to LMST 3 of the non-selected tier TIERT and the local memory strings LMSB 0 to LMSB 3 of the selected tier TIERB are not conductive.

For example, in the period PR 1, the non-write bit line BL 1 and the source line SL remain in a state in which the voltage VDDSA is supplied, the select gate line SGDT 0, the select gate line SGDB 0, and the select gate line SGST are supplied with a voltage VSGD, and the select gate lines SGDT 1 to SGDT 3, the select gate lines SGDB 1 to SGDB 3, and the select gate line SGSB are supplied with the voltage VSS. Further, the word lines WLT 0 to WLT 3 are supplied with a voltage VPASSL, and the word line WLB 3 and word lines WLB 0 to WLB 2 are supplied with a voltage VPASS. In this case, the select transistor STT 1 connected to the select gate line SGDT 0, the memory cell transistors MTT 0 to MTT 3, the select transistor STT 2, the select transistor STB 1 described in the select gate line SGDB 0, the memory cell transistor MTB 3, and the memory cell transistors MTB 0 to MTB 2 are in the on state. The select transistor STT 1 connected to each of the select gate lines SGDT 1 to SGDT 3, the select transistor STB 1 connected to each of the select gate lines SGDB 1 to SGDB 3, and the select transistor STB 2 are in the off state.

Consequently, in the period PR 1, only the local memory string LMST 0 of the non-selected tier TIERT is conductive, and the local memory strings LMST 1 to LMST 3 of the non-selected tier TIERT as well as the local memory strings LMSTB 0 to LMSTB 3 of the selected tier TIERB are non-conductive. In the period PR 1, since the respective memory cell transistors MTB 0 to MTB 3 in local memory strings LMSTB 1 to LMSTB 3 are in the on state, and the select transistors SGDB 1 to SGDB 3 and the select transistor STB 2 are in the off state, the channels of the respective memory cell transistors MTB 0 to MTB 3 in the local memory strings LMSTB 1 to LMSTB 3 are in a floating state and a boosted state.

Further, for example, in the period PR 1, the select gate lines SGDT 1 to SGDT 3 may be supplied with the voltage VSGD in the same manner as the select gate line SGDT 0. Thus, since the select transistor STT 1 connected to each of the select gate lines SGDT 1 to SGDT 3 is in the on state, and all of the channels of the non-selected tier TIERT can be conductive, the resistance value can be reduced. In this case, a voltage VSGD 2 smaller than the voltage VDDSA and greater than the voltage VSGD may be supplied to the select gate lines SGDT 0 to SGDT 3, the select gate line SGST, and the select gate line SGDB 0.

For example, in the period PR 2, the non-write bit line BL 1 and source line SL remain in a state in which the voltage VDDSA is supplied, the select gate line SGDT 0 and the select gate line SGDB 0, and the select gate line SGST remain in a state in which the voltage VSGD is supplied, and the select gate line SGSB 0 remains in a state in which the voltage VSS is supplied. Further, the word lines WLT 0 to WLT 3 also remain in a state in which the voltage VPASSL is supplied, and the word lines WLB 0 to WLB 2 remain in a state in which the voltage VPASS is supplied. The word line WLB 3 is supplied with a voltage VPGM. In this case, the select transistor STT 1 connected to the select gate line SGDT 0, the memory cell transistors MTT 0 to MTT 3, the select transistor STT2, the select transistor STB 2 connected to the select gate line SGDB 0, the memory cell transistor MTB 3, and the memory cell transistors MTB 0 to MTB 2 remain in the on state, and the select transistors STT 1 respectively connected to the select transistors SGDT 1 to SGDT 3, the select transistors STB 1 respectively connected to the select gate lines SGDB 1 to SGDB 3, and the select transistor STB 2 remain in the off state.

For example, the voltage VPGM is larger (higher) than the voltage VPASS, the voltage VPASS is larger (higher) than the voltage VPASSL, the voltage VPASSL is larger (higher) than the voltage VCHPCH, the voltage VSGDPCH is the same as the voltage VCHPCH, the voltage VSGDPCH is larger (higher) than the voltage VSGD, the voltage VDDSA is larger (higher) than the voltage VSGD, and the voltage VSGD is larger than the voltage VSS.

In the period PR 2, as in the period PR 1, only the local memory string LMST 0 of the non-selected tier TIERT is conductive, and the local memory strings LMST 1 to LMST 3 of the non-selected tier TIERT and the local memory strings LMSTB 0 to LMSTB 3 of the selected tier TIERB are non-conductive. In the period PR 2, the respective memory cell transistors MTB 0 to MTB 3 in the local memory strings LMSTB 1 to LMSTB 3 are in the on state and the select transistors SGDB 1 to SGDB 3 and the select transistor STB 2 are in the off state, similar to the period PR 1. Therefore, the memory cell transistor MTB 3 connected to the word line WLB 3 which is the selected word line is selected, and the threshold voltage is increased or the threshold voltage is maintained on the basis of the voltage supplied to the bit line BL 0. Also, the channels of the respective memory cell transistors MTB 0 to MTB 3 in the local memory strings LMSTB 1 to LMSTB 3 maintain the floating state and the boosted state.

For example, in the period PR 3, the non-write bit line BL1 and source line SL remain in a state in which the voltage VDDSA is supplied, the select gate line SGDT 0, the select gate line SGDB 0, and the select gate line SGST remain in a state in which the voltage VSGD is supplied, and the select gate lines SGDB 1 to SGDB 3 and the select gate line SGSB remain in a state in which the voltage VSS is supplied. In addition, the word lines WLT 0 to WLT 3 and the word lines WLB 0 to WLB 3 are discharged from the voltage VPASS or the voltage VPASSL. In this case, the select transistor STT 1 connected to the select gate line SGDT 0, the select transistor STT 2, and the select transistor STB 1 connected to the select gate line SGDB 0 remain in the on state, and the select transistor STT 1 connected to each of the select gate lines SGDT 1 to SGDT 3, the select transistor STB 1 connected to each of the select gate lines SGDB 1 to SGDB 3, and the select transistor STB 2 remain in the off state. The memory cell transistors MTT 0 to MTT 3, the memory cell transistor MTB 3, and the memory cell transistors MTB 0 to MTB 2 are in the off state.

Consequently, in the period PR 3, the same as in the period PR 2, only the local memory string LMST0 of the non-selected tier TIERT is conductive, and the local memory strings LMST 1 to LMST 3 of the non-selected tier TIERT and the local memory strings LMSTB 0 to LMSTB 3 of the selected tier TIERB are non-conductive.

In a period after the period PR 3, the same voltage as the period until the period PR 0 is supplied to each signal line, and each transistor is in the off state.

As described above, the semiconductor storage device 10 executes the program operation. Further, for example, the semiconductor storage device 10 executes the verify operation after the program operation. Description of the verify operation is omitted.

For example, since the semiconductor storage device 10P in the comparative example does not include a local bit line LBL, the semiconductor storage device 10P includes one memory string unit (that is, the string unit SU includes one memory string) in which memory strings corresponding to the local memory string LMST and the local memory string LMSB in the semiconductor storage device 10 are collected together. Therefore, in the string unit in the semiconductor storage device 10P, as the number of stacked layers increases, the number of word lines to which the voltage VPASS is supplied increases for one selected word line to which the voltage VPGM is supplied during the program operation. Therefore, the efficiency of the boost (boost efficiency) applied to each channel of the plurality of memory cell transistors other than the selected memory cell transistor in the selected string unit decreases (the boost is less likely to be applied). In addition, boost is less likely to be applied (the efficiency of boost (boost efficiency) is reduced) to the respective channels of the plurality of non-selected memory cell transistors in the non-selected string unit. For example, in the selected string unit, in the case where the voltage VPASS supplied to each memory cell transistor other than the selected memory cell transistor is large (high), since the threshold voltage of each memory cell transistor is easily changed, the voltage VPASS is required to be small (low). However, if boost is less likely to be applied to each memory cell transistor other than the selected memory cell transistor, the voltage of each memory cell transistor other than the selected memory cell transistor is decreased, so that the voltage VPASS needs to be made larger (higher) in order to make the voltage of the channel larger (higher). Consequently, by the voltage VPASS, the threshold voltage of each memory cell transistor other than the selected memory cell transistor is easily changed, that is, each memory cell transistor other than the selected memory cell transistor is susceptible to disturbance due to a program operation. Also, in non-selected string units, as the boost efficiency decreases, potential differences between the voltage VPGM and the voltage supplied to the channel or the voltage VPASS and the voltage supplied to the channel become large. As a result, in the memory cell transistors in the non-selected string unit, due to a program operation, the threshold voltage of each memory cell transistor is easily changed, that is, the memory cell transistors are more susceptible to disturbances caused by program operations.

Meanwhile, as described above, the semiconductor storage device 10 includes the local bit line LBL and the select transistors SGD and SGS. Also, the voltage supplied to the memory cell transistors MTT 0 to MTT 3 of the non-selective tier TIERT is the voltage VPASSL that is less than the voltage VPASS. Consequently, the memory cell transistors MTT 0 to MTT 3 of the non-selective tier TIERT in the semiconductor storage device 10 corresponding to a region DD indicated by the diagonal line in FIG. 16 is less susceptible to disturbance than the memory cell transistor supplied with the voltage VPASS in the semiconductor storage device 10P. Further, in the memory cell transistors MTB 0 to MTB 3 in the non-selected local memory strings LMSB 1 to LMSB 3 of the selected tier TIERB in the semiconductor storage device 10 corresponding to a region BEI indicated by the diagonal line in FIG. 16, the number of stacked layers is suppressed by the local bit line LBL and the select transistors SGD and SGS. Therefore, in the selective tier TIERB in the semiconductor storage device 10, the number of memory cell transistors supplying the voltage VPASS can be reduced more than in the semiconductor storage device 10P. Thus, the semiconductor storage device 10 can improve the boost efficiency of the memory cell transistors MTB 0 to MTB 3 in the non-selected local memory strings LMSB 1 to LMSB 3.

Further, as shown in FIG. 17, each memory cell transistor electrically connected to the non-write bit line BL 1 is in the same status as each memory transistor electrically connected to the write bit line BL0 shown in FIG. 16 except that the voltage VDDSA is supplied to the non-write bit line BL 1. For example, the memory string set MSS electrically connected to the non-write bit line BL 1 is a memory string set adjacent along the direction X of the memory string set MSS electrically connected to the non-write bit line BL in FIG. 8. As shown in FIG. 15 or FIG. 17, in the period PR 2, the word line WL in the tier TIERT electrically connected to the non-write bit line BL 1 is at the voltage VPASSL which is a low voltage, and therefore the memory cell MC in the tier TIERT is not written. In addition, the channels in the tier TIERT may be boosted and the memory cell MC may be non-written. On the other hand, a select gate transistor STB 1 in the local memory string LMSB 0 in the tier TIERB electrically connected to the non-write bit line BL 1 is electrically connected to the select gate line SGDB 0 and is supplied with the voltage VSGD. The voltage VSGD is smaller (lower) than the voltage VDDSA supplied to the non-write bit line BL 1. Thus, the select gate transistor STB 1 is in the off state and the local memory string LMSB 0 is non-conductive. Consequently, in the period PR 2, the channels of memory cell transistors MTB 0 to 3 in the local memory string LMSB 0 electrically connected to the non-write bit line BL 1 are in the boosted state. Also, since the selected gate transistors SGDB 1 to 3 in the local memory strings LMSB 1 to 3 are in the off state, the channels of the memory cell LMSB 1 in the local memory strings LMSB 1 to 3 are in the boosted state. Since the semiconductor storage device 10 (sequencer 16) can supply a voltage corresponding to each bit line BL from the sense amplifier module 23 electrically connected to each bit line BL, the semiconductor storage device 10 can supply the voltage VSS to the write bit line BL 1 and supply the voltage VDDSA to the non-write bit line. Therefore, for example, the semiconductor storage device 10 (the sequencer 16) can write and divide data 0 and data 1 according to the bit line BL.

Further, in the section “1-6-2-1. First Example of Program Operation of Semiconductor Storage Device”, for example, the select gate lines SGST may be configured to be divided for each local memory string LMST 0 to LMST 3 as well as the select gate lines SGDT 0 to SGDT 3 and electrically connected to the respective select transistors STT2 in the local memory strings LMST 0 to LMST 3 as the select gate lines SGST 0 to SGST 3. On the other hand, the select gate lines SGSB may also be configured to be separate for each local memory string LMSB 0 to LMSB 3 and electrically connected to respective select transistors STB 2 in the local memory strings LMSB 0 to LMSB 3 as the select gate lines SGSB 0 to SGSB 3.

### 1-6-2-2. Second Example of Program Operation in Semiconductor Storage Device

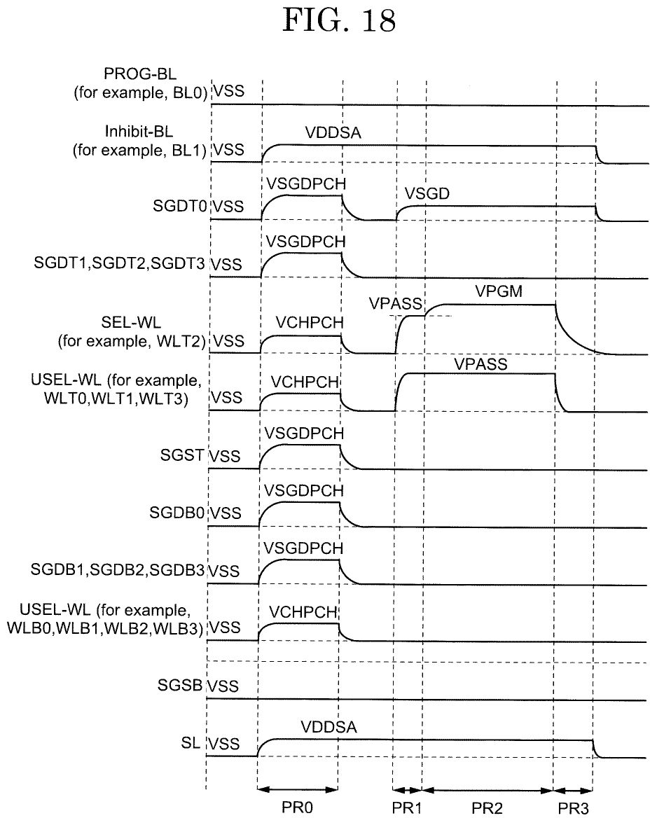

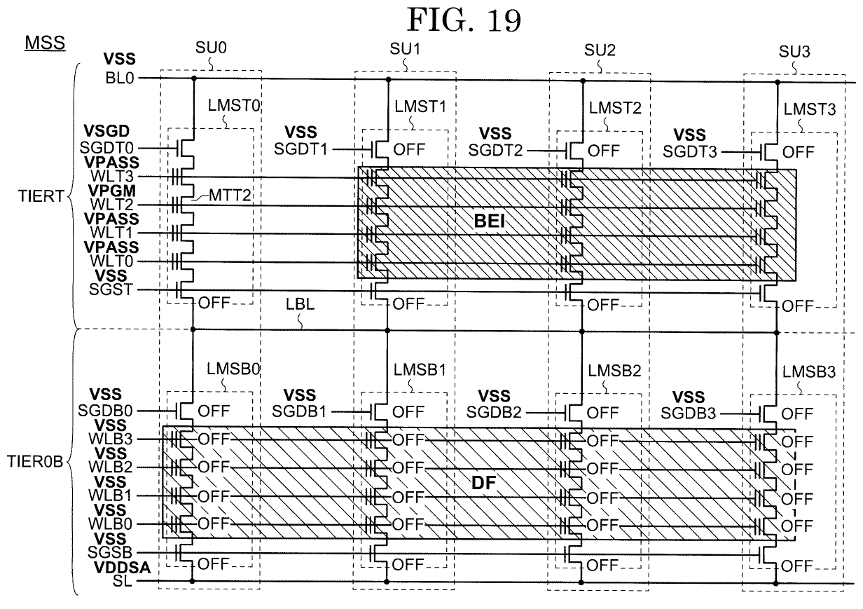

Referring to FIG. 18 and FIG. 19, a second example of the program operation in the semiconductor storage device 10 will be described. The second example is the case where the tier TIERT is a selected tier. FIG. 18 is a timing chart showing waveforms of various signals of the program operation in the semiconductor storage device 10. FIG. 19 is a circuit diagram for explaining the memory string set MSS in the program operation of the semiconductor storage device 10. In the second example of the program operation of the semiconductor storage device 10, an example is shown in which the selected transistor is the memory cell transistor MTT 2. In the circuit diagram shown in FIG. 19, the reference sign of the transistor in the circuit diagram shown in FIG. 3 is omitted.

The timing chart shown in FIG. 18 differs from the timing chart shown in FIG. 15 in a configuration 6 to a configuration 10 shown below.
(Configuration 6) The selected word line WL (SEL-WL) in FIG. 18 is changed from the word line WLB 3 in FIG. 15 to the word line WLT 2, and the word line WLT2 in FIG. 18 is supplied with a signal (voltage) which is supplied to the word line WLB 3 in FIG. 15.
(Configuration 7) The word lines WLT 0, 1, and 3, which are the non-selected word lines WL (USEL-WL) in FIG. 18, are supplied with the voltage VPASS.
(Configuration 8) The select gate lines SGST and SGDB 0 in FIG. 18 are supplied with the voltage VSS in the period PR 1 to the period PR 3, and are supplied with the signal (voltage) in FIG. 15 in the other period.
(Configuration 9) The word lines WLB 0 to WLB 2, which are the non-selected word line WL (USEL-WL) in FIG. 18, are supplied with the voltage VSS in the period PR 1 to the period PR 3, and are supplied with the signal (voltage) in FIG. 15 in the other period.
(Configuration 10) The word line WLB 3 in FIG. 15 is changed from the selected word line WL (SEL-WL) in FIG. 15 to the non-selected word line (USEL-WL) in FIG. 18, and the word line WLB3 which is the non-selected word line (USEL-WL) in FIG. 18 is supplied with the same signal (voltage) as the word lines WLB 0 to WLB 2 which are the non-selected word lines WL (USEL-WL) in FIG. 18.

Configurations other than the configuration 6 to configuration 10 in the timing chart shown in FIG. 18, and configurations other than configurations related to the configuration 6 to configuration 10 are the same as the configurations in the timing chart shown in FIG. 15. Therefore, in the description of the timing chart in the section “1-6-2-2. Second Example of Program Operation of Semiconductor Storage Device”, the description of the same or similar configurations and functions as in the timing chart shown in the section “1-6-2-1. First Example of Program Operation of Semiconductor Storage Device” are omitted and will be described as necessary.

States of each select gate transistor and each memory cell transistor of the selected tier TIERT shown in FIG. 19 differ from the states of each select gate transistor and each memory cell transistor of the selected tier TIERB shown in FIG. 16 in the following configurations 11 and 12.
(Configuration 11) The select transistors STB 1 and STB 2, the memory cell transistors MTB 0, MTB 1, MTB 2, and MTB3 shown in FIG. 16 are replaced with the select transistors STT 1 and STT 2, the memory cell transistors MTT 0, MTT 1, MTT 3, and MTT 2 shown in FIG. 19.
(Configuration 12) The transistors of the non-selected tier TIERB are all in the off state.

Configurations other than the configuration 11 and the configuration 12 in the memory cell string set MSS shown in FIG. 19 and configurations other than configurations related to the configuration 11 and the configuration 12 are the same as the memory cell string set MSS shown in FIG. 16. Therefore, in the description of the memory cell string set MSS in the section “1-6-2-2. Second Example of Program Operation of Semiconductor Storage Device,” the description of the configurations and functions identical to or similar to the configurations and functions in the memory cell string set MSS shown in the section “1-6-2-1. First Example of Program Operation of Semiconductor Storage Device” is omitted and described as needed.

The memory cell transistors MTT 0 to MTT 3 in the unselected local memory strings LMST 1 to LMST 3 of the selected tier TIERT in the semiconductor memory device 10, which corresponds to the region BEI shown by diagonal lines in FIG. 19, have the number of stacks reduced by the local bit line LBL and the select transistors SGD and SGS, similar to the memory cell transistors MTB 0 to MTB 3 in the unselected local memory strings LMSB 1 to LMSB 3 of the selected tier TIERB in the semiconductor memory device 10, which corresponds to the region BEI shown by diagonal lines in FIG. 16. Therefore, in the selected tier TIERT in the semiconductor storage device 10, the number of memory cell transistors supplying the voltage VPASS can be reduced more than in the semiconductor storage device 10P. Thus, the semiconductor storage device 10 can improve the boost efficiency of the memory cell transistors MTT 0 to MTT 3 in the non-selected local memory strings LMST 1 to LMST 3.

Further, since the gates, the local bit line LBL, and the source lines SL of all the transistors in the non-selected tier TIERB in the semiconductor storage device 10 corresponding to a region DF indicated by diagonal lines in FIG. 19 are supplied with VSS, there is no path through which a current flows in all the transistors, and all the transistors are in the off state. Therefore, the memory cell transistors MTB 0 to MTB 3 in the non-selective tier TIERB are not affected by disturbance (disturbance free).

### 1-6-3. Example of Erase in Semiconductor Storage Device

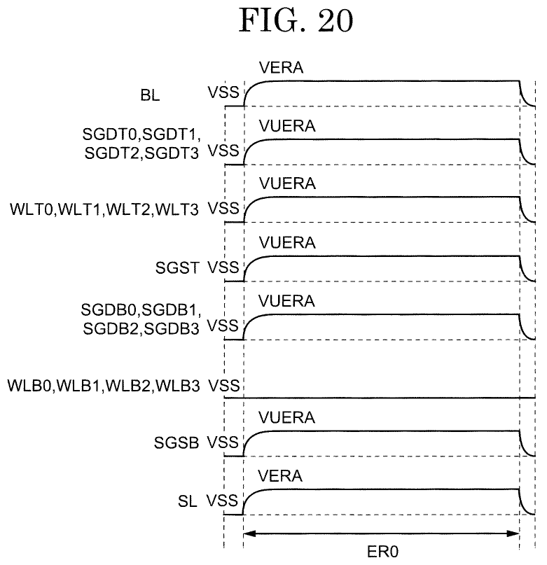

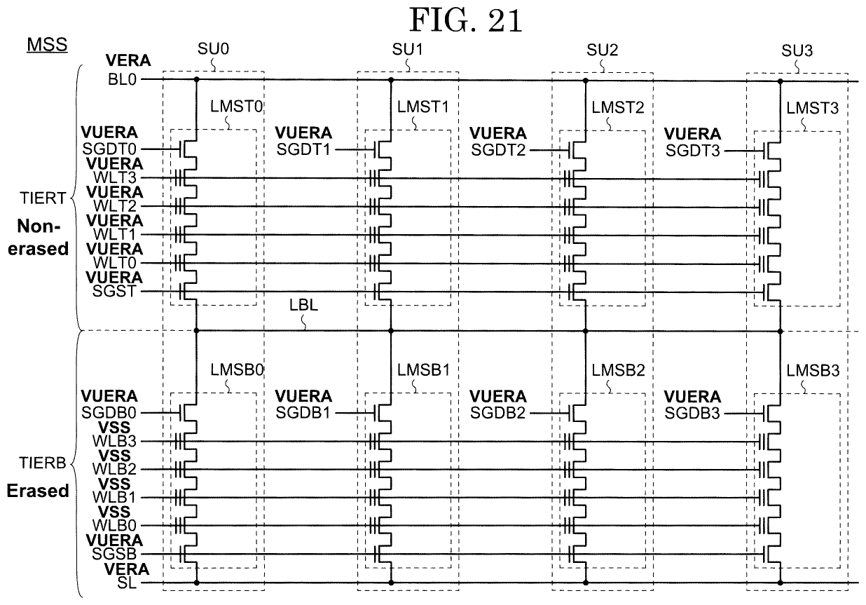

Referring to FIG. 20 and FIG. 21, the erase operation of data in the semiconductor storage device 10 will be described. FIG. 20 is a timing chart showing waveforms of various signals of the erase operation in the semiconductor storage device 10. FIG. 21 is a schematic diagram showing the memory string set MSS in an erase operation of the semiconductor storage device 10. In the circuit diagram shown in FIG. 21, the reference signs of transistors in the circuit diagram shown in FIG. 3 are omitted. In one example of the erase operation of the semiconductor storage device, an example is shown for erase data of respective memory cell transistors MTB 0 to MTB 3 of local memory strings LMSB 0 to LMSB 3 included in the tier TIERB. That is, the tier TIERB is the selected tier including the memory cell transistor to be erased, the tier TIERB is referred to as the selected tier TIERB, the tier TIERT is the tier not to be erased, and is referred to as the non-selected tier TIERT.

As shown in FIG. 20, the erase operation includes at least a period ER 0. The word lines WLB 0 to WLB 2 (SEL-WL) are supplied with the voltage VSS for all periods shown in FIG. 20.

As shown in FIG. 20, up to the period ER 0, all bit lines BL (BL 0, BL 1, and the like), the select gate lines SGDT 0 to SGDT 3 (USEL-SGD), the word lines WLT 0 to WLT 3 (USEL-WL), select gate line SGST (USEL-SGS), select gate lines SGDB 0 to SGDB 3 (SEL-SGD), word lines WLB 0 to WLB 3 (SEL-WL), select gate line SGSB (SEL-SGS), and the source line SL are supplied with the voltage VSS and each signal line is in the standby state. In this case, the select transistor STT 1 connected to the select gate lines SGDT 0 to SGDT 3, the memory cell transistors MTT 0 to MTT 3, the select transistor STT 2, the select transistor STB 1 connected to the select gate lines SGDB 0 to SGDB 3, the memory cell transistors MTB 0 to MTB 3, and the select transistor STB 2 are in the off state.

In the period ER 0, all the bit lines BL and source lines SL are supplied with a voltage VERA, and a voltage VUERA is supplied to the select gate lines SGDT 0 to SGDT 3, the word lines WLT 0 to WLT 3, the select gate line SGST, the select gate lines SGDB 0 to SGDB 3, and the select gate line SGSB. The voltage VERA is larger (higher) than the voltage VUERA. For example, the voltage VERA may be 20 V and the voltage VUERA may be 15 V.

A potential difference between the voltage VERA and the voltage VUERA is a so-called GIDL (Gate Induced Drain Leak Current) voltage required to produce a current. In the period ER 0, a gate terminal of the select transistor STB 2 in the selected tier TIERB is connected to the select gate line SGSB and is supplied with the voltage VUERA, and the source line SL is supplied with the voltage VERA. Therefore, a GIBL current and a hole are generated at a gate end of the select transistor STB 2 in the selected tier TIERB due to a potential difference between the gate terminal of the select transistor STB2 and a vicinity of the source line SL in the selected tier TIERB. The generated holes flow to the respective channels of the memory cell transistors MTB 0 to MTB 3 in the selective tier TIERB. Also, the memory cell transistors MTB 0 to MTB 3 in the selective tier TIERB are connected to the word lines WLB 0 to WLB 2 and are supplied with the voltage VSS. Consequently, electrons of the respective charge storage layers of the memory cell transistors MTB 0 to MTB 3 in the selected tier TIERB are withdrawn and the data of the memory cell transistors MTB 0 to MTB 3 in the selected tier TIERB is erased.

On the other hand, in the non-selective tier TIERT, the GIBL current and a hole are generated at a gate end of the select transistor STT 1 in the non-selective tier TIERT due to a potential difference between a gate terminal of the select transistor STT 1 and a vicinity of the bit line BL 0. The generated holes flow to the respective channels of the memory cell transistors MTT 0 to MTT 3 in the non-selective tier TIERT. The memory cell transistors MTT 0 to MTT 3 in the non-selective tier TIERT are connected to the word lines WLT 0 to WLT 2 to provide the voltage VUERA. Consequently, coupling of the gate terminals of the memory cell transistors MTT 0 to MTT 3 in the non-selective tier TIERT with the channel increases the voltage supplied to the channel and does not pull out the electrons in the respective charge storage layers. Therefore, the data of the memory cell transistors MTT 0 to MTT 3 in the non-selected tier TIERT is not erased (the non-selected tier TIERT is not erased).

In the period ER 0, the voltage supplied to the select gate lines SGDB 0 to SGDB 3 of the selected tier TIERB and the select gate line SGSB, the voltage supplied to the select gate lines SGDT 0 to SGDT 3 of the non-selected tier TIERT and the select gate line SGST are shown to be the voltage VUERA, but may not be the voltage VUERA. For example, the voltage supplied to the select gate lines SGDB 0 to SGDB 3 and the select gate line SGSB of the selected tier TIERB, and the voltage supplied to the select gate lines SGDT 0 to SGDT 3 of the non-selected tier TIERT and the select gate line SGST may be different voltages (voltages differing from each other). Further, for example, the non-selected tier TIERT may be supplied with a voltage that does not generate a hole.

In a period after the period ER 0, the same voltage as the period up to the period ER 0 is supplied to each signal line, and each transistor is in the off state.

As described above, the semiconductor storage device 10 can perform the erase operation for each tier TIER (sub block SUBBLK).

The erase operation of data in the semiconductor storage device 10 is not limited to the form described in the section “1-6-3. Example of Erase in Semiconductor Storage Device”. For example, the semiconductor storage device 10 may perform an erase operation that simultaneously erases the tier TIERT and the tier TIERB.

### 1-6-4. Example of Erase Verify Operation in Semiconductor Storage Device

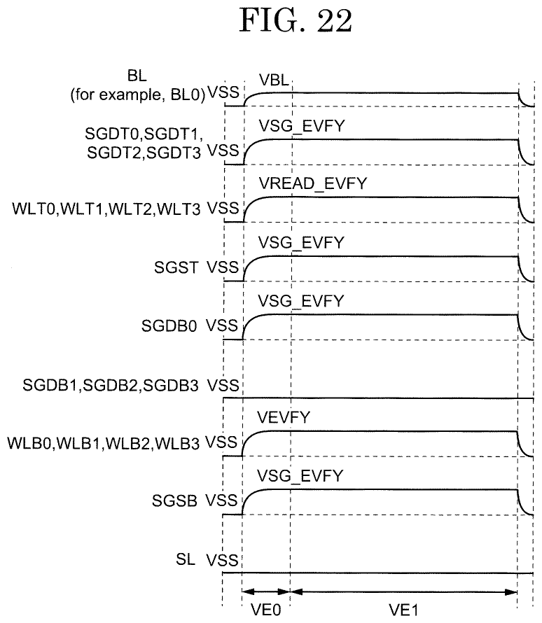

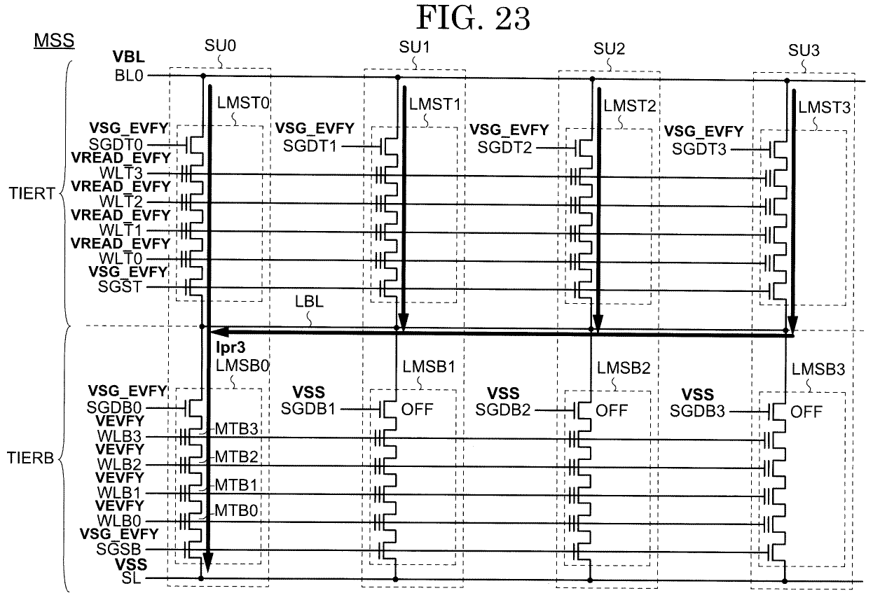

Referring to FIG. 22 and FIG. 23, an erase verify operation of data (erase verify operation) in the semiconductor storage device 10 will be described. FIG. 22 is a timing chart showing waveforms of various signals of an erase verify operation in the semiconductor storage device 10. FIG. 23 is a circuit diagram for explaining the memory string set MSS in the erase verify operation of the semiconductor storage device 10. In the circuit diagram shown in FIG. 23, the reference signs of the transistors in the circuit diagram shown in FIG. 3 are omitted. In the example of the erase verify operation of the semiconductor storage device, an example is shown in which the local memory string unit LMSB 0 is subject to the erase verify operation and the selected transistor (memory cell transistors MTB 0 to MTB 3) is verified. That is, the tier TIERB is the selected tier including the memory cell transistor to be subject to the erase verify operation, the tier TIERB is referred to the selected tier TIERB, the tier TIERT is not subject to the erase verify operation, and is referred to the non-selected tier TIERT.

The erase verify operation is an operation for confirming that the threshold voltages of all selected memory cell transistors MT (selected memory cell transistor) are less than the “Er” level. That is, the erase verify operation is an operation for confirming that all selected memory cell transistors MT are turned into the on state in a state where data is erased by the erase operation, and that a current flows in the memory string. For example, a voltage below the “Er” level may be the verify voltage AV described in the section “1-5. Threshold Distribution of Memory Cell Transistor MT”. In the description of “1-6-4. Example of Erase Verify Operation in Semiconductor Storage Device”, the voltage below the “Er” level is a voltage VEVFY. In this case, all the word lines WL included in the non-selected tier TIER are supplied with a voltage VREAD_EVFY, and the memory cell transistor MT connected to the word line WL is turned into the on state. On the other hand, all word lines WL included in the selected tier TIER are arranged with the voltage VEVFY, and the memory cell transistors MT connected to the word line WL are turned into the on state if the threshold of the memory cell is less than VEVFY. In the case where at least one memory cell transistor MT is included, since the memory cell transistor MT is in the off state, no current flows through the memory string.

For example, the voltage VREAD_EVFY is greater (higher) than a voltage VSG_EVFY, and the voltage VSG_EVFY is greater (higher) than the voltage VSS. The voltage VREAD_EVFY may be different from the voltage VREAD, the voltage VSG_EVFY may be different from the voltage VREAD_EVFY.

As shown in FIG. 22, the erase verify operation includes at least a period VE 0 and a period VE 1. The select gate lines SGDB 1 to SGDB 3 and the source line SL are supplied with the voltage VSS for all periods shown in FIG. 22. Thus, the select transistor STB 1 electrically connected to each of the select gate lines SGDB 1 to SGDB 3 is in the off state for all periods shown in FIG. 22.

As shown in FIG. 22, up to the period VE 0, the bit line BL (for example, BL 0), the select gate lines SGDT 0 to SGDT 3 (USEL-SGD), the word lines WLT 0 to WLT 3 (USEL-WL), the select gate line SGST (USEL-SGS, the word line SGDB 0 (SEL-SGD), and the select gate line SGSB (SEL-SGS) are supplied with the voltage VSS, and the signal lines are in the standby state. In this case, the select transistor STT 2, the memory cell transistors MTT 0 to MTT 3, the select transistor STT 2, the memory cell transistor MTB 3, the memory cell transistors MTB 0 to MTB 2, and the select transistor STB 2 connected to the select gate lines SGDB 0 to SGDB 3 are in the off state.

In the period VE 0, the voltage VBL is supplied to the bit line BL, the voltage VSG_EVFY is supplied to the select gate lines SGDT 0 to SGDT 3, the select gate line SGST, and the select gate line SGSB, the voltage VREAD_EVFY is supplied to the word lines WLT 0 to WLT 3, and the voltage VEVFY is supplied to the word lines WLB 0 to WLB 3. Thus, the select transistor STT 1 connected to the select gate lines SGDT 0 to SGDT 3, the select transistor STB 1 connected to the select gate line SGDB 0, the memory cell transistors MTT 0 to MTT 3 electrically connected to the respective signal lines, the select transistor STT2, the memory cell transistors MTB 0 to MTB 3 in the local memory string LMSB 0, and the select transistor STB 2 are turned into the on state.

Consequently, in the period VE 0, in the memory string set MSS connected to the bit line BL, the local memory strings LMST 0 to LMST 3 of the non-selected tier TIERT, and the local memory string LMSB 0 of the selected tier TIERB are conductive and the local memory strings LMSB 1 LMSB 3 of the selected tier TIERB are non-conductive (are non-conductive).

That is, in the period VE 0, the bit line BL is electrically connected to the source line SL via the local memory strings LMST 0 to LMST 3 of the non-selected tier TIERT, the local bit line LBL, and the local memory string LMSB 0 of the selected tier TIERB. Thus, all memory cell transistors MTT 0 to MTT 3 in the local memory strings LMST 0 to LMST 3 of the non-selected tier TIERT and memory cell transistors MTB 0 to MTB 3 in the local memory string LMSB 0 of the selected tier TIERB are precharged to the voltage VBL via the local memory strings LMST 0 to LMST 3 of the non-selected tier TIERT and the local bit line LBL, and the local memory string LMSB 0 of the selected tier TIERB.

In the period VE 1, the bit line BL is subsequently supplied with the voltage VBL and the select gate lines SGDT 0 to SGDT 3, the select gate line SGST, and the select gate line SGSB are subsequently supplied with the voltage VSG_EVFY, and the word lines WLT 0 to WLT 3, as well as the word lines WLB 0 to WLB 3, are subsequently supplied with the voltage VREAD_EVFY. Thus, the select transistor STT 1 connected to the select gate lines SGDT 0 to SGDT 3, the select transistor STB 1 connected to the select gate line SGDB 0, the memory cell transistors MTT 0 to MTT 3 electrically connected to the respective signal lines, the select transistor STT 2, the memory cell transistors MTB 0 to MTB 3 in the local memory string LMSB 0, and the select transistor STB 2 are turned into the on state.

Consequently, in the period VE 1, in the memory string set MSS connected to the bit line BL 0, the local memory strings LMST 0 to LMST 3 of the non-selected tier TIERT, the local memory string LMSB 0 of the selected tier TIERB are conductive and the local memory strings LMSB 1 to LMSB 3 of the selected tier TIERB are non-conductive (are non-conductive).

That is, in the period VE 1, the bit line BL 0 is electrically connected to the source line SL via the local memory strings LMST 0 to LMST 3 of the non-selected tier TIERT, the local bit line LBL, and the local memory string LMSB 0 of the selected tier TIERB. Thus, as shown by the thick solid line in FIG. 23, in the memory string set MSS of the erase verify operation, current flows from the bit line BL 0 to the source line SL via the local memory strings LMST 0 to LMST 3 of the non-selected tier TIERT, the local bit line LBL, and the local memory string LMSB 0 of the selected tier TIERB. For example, the current value at this time is a current value Ipr 3. The sense amplifier module 23 electrically connected to the bit line BL 0 senses the current Ipr 3 and the semiconductor storage device 10 can verify that the data of the memory cell transistors MTB 0 to MTB 3 in the local memory string LMSB 0 of the selected tier TIERB has been erased.

In the case where it is confirmed that no current flows from the bit line BL 0 to the source line SL, the semiconductor storage device 10 repeatedly performs the erase operation and the erase verify operation until a current flows from the bit line BL 0 to the source line SL.

In a period after the period VE 1, the same voltage as the period until the period VE 0 is supplied to each signal line, and each transistor is in the off state.

The operations in the period VE 0 and the period VE 1 are performed on each memory cell transistor MTB 0 to MTB 3 of the local memory strings LMSB 1 to LMSB 3 of the selected tier TIERB. The semiconductor storage device 10 confirms that the current flows, and the semiconductor storage device 10 sets that all the data of the selected tier TIERB is erased and the selected tier TIERB is erased.

Further, in the section “1-6-4. Example of Erase Verify Operation in Semiconductor Storage Device”, similar to “1-6-2-1. First Example of Program Operation in Semiconductor Storage Device”, for example, the select gate line SGST may be configured to be divided for each local memory string LMST 0 to LMST 3, as well as the select gate lines SGDT 0 to SGDT 3, and electrically connected to each respective select transistor STT 2 in the local memory strings LMST 0 to LMST 3 as the select gate lines SGST 0 to SGST 3. Also, in this case, the select gate line SGSB may be configured to be divided for each local memory string LMSB 0 to LMSB 3 and electrically connected to the respective select transistor STB 2 in the local memory strings LMSB 0 to LMSB 3 as the select gate lines SGSB 0 to SGSB 3.

### 2. Second Embodiment

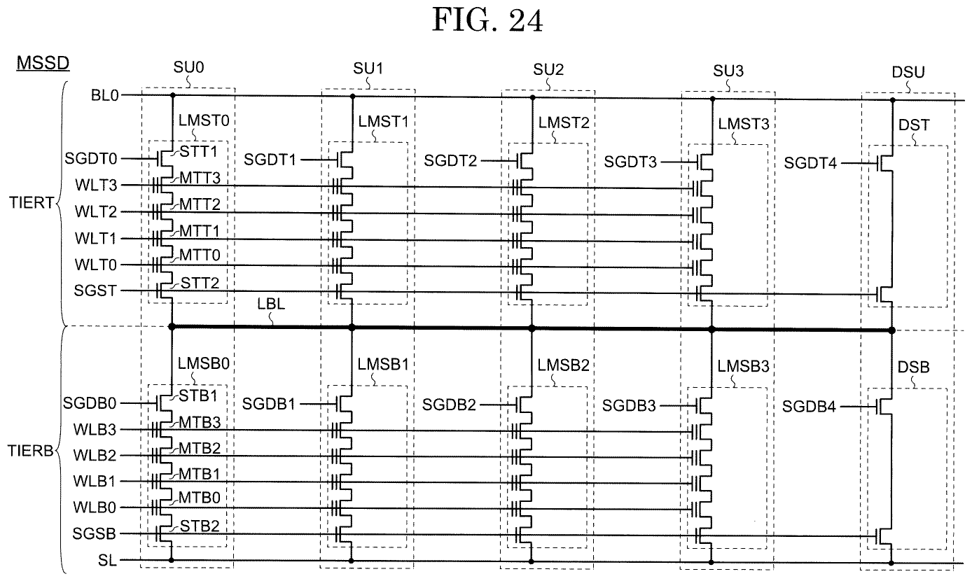

Referring to FIG. 24 to FIG. 34, a semiconductor storage device 10B according to a second embodiment will be described.

### 2-1. Overall Configuration of Semiconductor Memory Device 10B

The semiconductor storage device 10B includes at least a configuration 13 shown below as compared to the semiconductor storage device 10. (Configuration 13) A configuration includes a dummy string unit DSU.

Configurations other than the configuration 13 in the semiconductor storage device 10B and configurations other than configurations related to the configuration 13 are the same as the configurations of the semiconductor storage device 10 or the semiconductor storage device 10A. In the description of the semiconductor storage device 10B, the description of the same or similar content as the semiconductor storage device 10 or the semiconductor storage device 10A may be omitted, and the same or similar content as the semiconductor storage device 10 or the semiconductor storage device 10A may be described as required.

### 2-2. Circuit Configuration of Memory String Set MSSD of Semiconductor Memory Device 10B

Referring to FIG. 24, a memory string set MSSD of a semiconductor storage device 10B will be described. FIG. 24 is a circuit diagram showing a circuit configuration of the memory string set MSSD of the semiconductor storage device 10B.

As shown in FIG. 24, the memory string set MSSD includes the memory string set MSS and the dummy string unit DSU. The memory string set MSS of the semiconductor storage device 10B includes a configuration similar to the semiconductor storage device 10 or the semiconductor storage device 10A. Descriptions of configurations similar to those of the semiconductor storage device 10 or the semiconductor storage device 10A are omitted here.

The dummy string unit DSU includes dummy strings DST and DSB. The dummy string DST is included in the tier TIERT and the dummy string DSB is included in the tier TIERB. A first end of the dummy string DST is connected to a corresponding bit line BL (for example, BL 0). The first end of the dummy string DST is also connected to the peripheral circuit 20, such as the sense amplifier module 23, via the bit line BL. A second end of the dummy string DST and a first end of the dummy string DSB are commonly connected to corresponding local bit lines LBL. A second end of the dummy string DSB is connected to the source line SL.

For example, the dummy string DSB includes the drain select transistor STB 1 and the source select transistor STB 2 connected in series between the local bit line LBL and the source line SL. For example, the dummy string DST includes the drain select transistor STT1 and the source select transistor STT2 connected in series between the bit line BL and the local bit line LBL. That is, the dummy strings DSB and DST do not include a memory cell transistor between the drain select transistor and the source select transistor, and the first end of the drain select transistor STB 1 and a second end of the source select transistor STT 2 are connected to each other.

The first end of the select transistor STB 1 is connected to the local bit line LBL as the first end of the dummy string DSB. The second end of the select transistor STB 1 is connected to a first end of the select transistor STB 2. A second end of the select transistor STB 2 is connected to the source line SL as the second end of the dummy string DSB.

The first end of the select transistor STT 1 is connected to the corresponding bit line BL as the first end of the dummy string DST. The second end of the select transistor STT 1 is connected to a first end of the select transistor STT 2. The second end of the select transistor STT 2 is connected to the local bit line LBL as the second end of the dummy string DST.

That is, the first end of the select transistor STB 1 (the first end of the dummy string DSB) is connected to the local bit line LBL together with the second end of the select transistor STT 2 (the second end of the dummy string DST).

A gate electrode of the drain select transistor STB 1 of the dummy string DSB is connected to a select gate line SGDB 4. A gate electrode of the drain select transistor STT 1 of the dummy string DST is connected to a select gate line SGDT 4. A gate electrode of the source select transistor STB 2 of the dummy string DSB is commonly connected to the select gate line SGSB. The gate electrode of the source select transistor STT 2 in the dummy string DSB is connected to the select gate line SGST.

For example, in the dummy string unit DSU, the select transistors STB 1, STB 2, STT 1, and STT 2 are field-effect transistors. Also, each first end of the select gate lines (SGDB 4, SGDT 4, SGSB, SGST) in the dummy string unit DSU is connected to the peripheral circuit 20, such as the row decoder 22.

For example, the dummy string DST may include a memory cell transistor in which the “Er” level is preprogrammed between the source select transistor STT 2 and the drain select transistor STT 1. Similar to the dummy string DST, the dummy string DSB may also include a memory cell transistor in which the “Er” level is preprogrammed between the source select transistor STB 2 and the drain select transistor STB 1. Further, in these cases, the dummy string DST and the dummy string DSB may have the same configuration as the memory cell transistor and may have the same processing step or the like.

### 2-3. Schematic Layout and End Cross-sectional Structure of Semiconductor Memory 10B

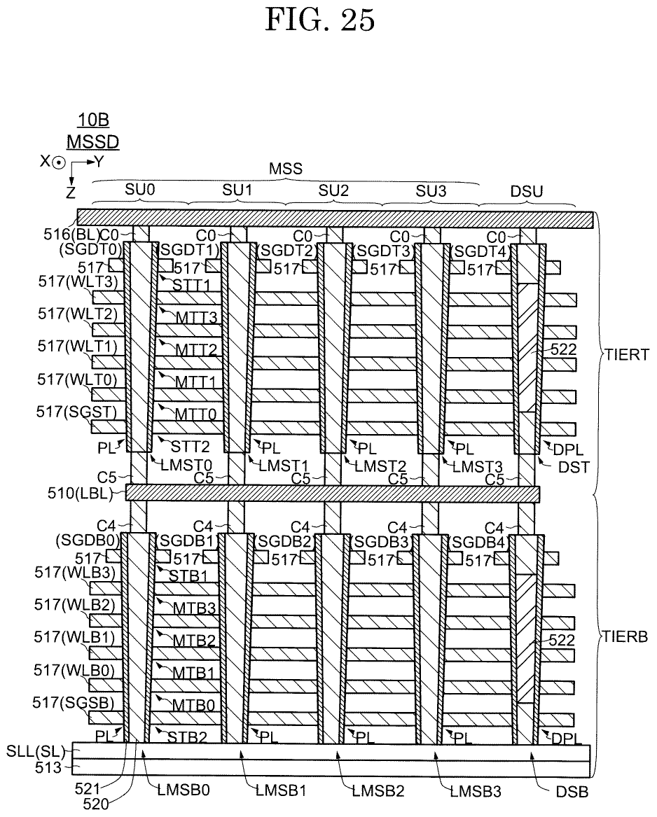

Referring to FIG. 25, a schematic end section of the semiconductor storage device 10B will be described. FIG. 25 is an end view showing an end cross-sectional view of the memory string set MSSD of the semiconductor storage device 10B.

The end cross-sectional configuration of the semiconductor storage device 10B is the same as that of the semiconductor storage device 10 or the semiconductor storage device 10A in configurations other than the dummy string unit DSU (in particular, the configuration of the memory string set MSS). Therefore, the description of the same configurations as those of the semiconductor storage device 10 or the semiconductor storage device 10A is omitted here.

The tier TIERB includes the dummy string DSB. The dummy string DSB includes and is formed using the insulating layer 513, the source layer SLL, the plurality of wirings 517, the via C 4, and the wirings 510, as well as the local memory string LMSB. The dummy string DSB also includes a dummy pillar DPL arranged between the source layer SLL and the wirings 510.

The plurality of wirings 517 is arranged in order from the source layer SLL toward the wirings 510 along the direction Z. The plurality of wirings 517 is formed in a plate shape extending along a plane parallel along the directions X and Y. Also, among the plurality of wirings 517, the wiring 517 on the local bit line LBL side functions as the select gate line SGDB 4, and the wiring 517 on the source layer SLL side functions as the select gate line SGSB. The select gate line SGDB 4 is arranged in the same layers as the select gate lines SGDB 0 to SGDB 3 corresponding to each of the local memory strings LMSB 0 to LMSB 3. The select gate line SGSB is shared with SGSB corresponding to each of the local memory strings LMSB 0 to LMSB 3. Further, the plurality of wirings 517 between the wiring 517 on the local bit line LBL side and the wiring 517 on the source layer SLL side functions as word lines WLB 0 to WLB 3 in the local memory strings LMSB 0 to LMSB 3, but does not function as word lines WLB 0 to WLB 3 in the dummy pillar DPL. The wiring 510 extends along the direction Y, is split in the same units as the bit line BL along the direction X, and serves as the local bit line LBL.

The dummy pillar DPL is arranged to extend along the axis Z. The dummy pillar DPL passes through the plurality of wirings 517. A bottom of the dummy pillar DPL on the source layer SLL side along the direction Z contacts the source layer SLL. The dummy pillar DPL includes the semiconductor layer 520 and the charge storage layer 521 as well as the memory pillar PL. The dummy pillar DPL also includes a configuration in which, from the source layer SLL to the wiring 510 along the Z direction, the semiconductor layer 520 on the source layer SLL side and the charge storage layer 521 covering the semiconductor layer 520, a metal layer 522 and the charge storage layer 521 covering the metal layer 522, and the semiconductor layer 520 on the wiring 510 side and the charge storage layer 521 covering the semiconductor layer 520 are stacked in this order. In addition, the charge storage layer 521 extends uniformly from the source layer SLL to the wiring 510 along the direction Z.

In the dummy pillar DPL, a portion where the semiconductor layer 520 and the charge storage layer 521 of the wiring 510 side intersect the wiring 517 along the direction Z functions as a select transistor STB 1, and a portion where the semiconductor layer 520 and the charge storage layer 521 of the source layer SLL side intersect the wiring 517 along the direction Z functions as a select transistor STB 2.

The columnar via C 4 is arranged on an upper surface of the semiconductor layer 520 in the dummy pillar DPL (the wiring 510 along the direction Z). An upper end of the via C 4 contacts one corresponding wiring 510 (local bit line LBL). The lower surface (the source layer SLL side along the direction Z) of the semiconductor layer 520 in the dummy pillar DPL contacts the source layer SLL. Therefore, the source layer SLL and the wirings 510 are connected to each other through the semiconductor layer 520 and the metal layer 522 in the memory pillar PL.

The tier TIERT contains the dummy string DST. The dummy string DST includes and is formed using the wirings 510, the via C 5, the wirings 517, the via C 0, and the wirings 516 corresponding to the local bit line LBL as well as the local memory string LMST. The dummy string DST also includes the dummy pillar DPL arranged between the wiring 510 and the wiring 516. As in the memory string set MSS, the wirings 510 corresponding to the local bit line LBL in the memory string set MSSD are shared by the tier TIERB and the tier TIERT, and are also commonly arranged.

The plurality of wirings 517 is arranged in order from the wiring 510 toward the wiring 516 along the direction Z. The plurality of wirings 517 is formed in a plate shape extending along a plane parallel along the directions X and Y. Also, among the plurality of wirings 517, the wiring 517 on the bit line BL side functions as the select gate line SGDT 4, and the wiring 517 on the local bit line LBL side functions as the select gate line SGST. The select gate line SGDT 4 is arranged in the same layers as the select gate lines SGDT 0 to SGDT 3 corresponding to each of the local memory strings LMST 0 to LMST 3. The select gate line SGST is shared with SGST corresponding to each of the local memory strings LMST 0 to LMST 3. Further, the plurality of wirings 517 between the wirings 517 on the bit line BL side and the wirings 517 on the local bit line LBL side functions as the word lines WLT 0 to WLT 3 in the local memory strings LMST to LMST 3, but does not function as the word lines WLT 0 to WLT 3 in the dummy pillar DPL. The wiring 510 serves as the local bit line LBL.

The dummy pillar DPL is arranged to extend along the axis Z. The dummy pillar DPL passes through the plurality of wirings 517. A bottom of the local bit line LBL side of the dummy pillar DPL along the direction Z contacts the local bit line LBL. The dummy pillar DPL includes the semiconductor layer 520 and the charge storage layer 521 as well as the memory pillar PL. Further, the dummy pillar DPL includes a configuration in which, from the wiring 510 to the wiring 516 along the Z direction, the semiconductor layer 520 on the wiring 510 side and the charge storage layer 521 covering the semiconductor layer 520, the metal layer 522 and the charge storage layer 521 covering the metal layer 522, and the semiconductor layer 520 on the wiring 516 side and the charge storage layer 521 covering the semiconductor layer 520 are stacked in this order. In addition, the charge storage layer 521 extends uniformly from the wiring 510 to the wiring 516 along the direction Z.

In the dummy pillar DPL, a portion where the semiconductor layer 520 and the charge storage layer 521 of the wiring 516 side along the direction Z intersect the wiring 517 functions as the select transistor STT 1, and a portion where the semiconductor layer 520 and the charge storage layer 521 of the wiring 510 side along the direction Z intersect the wiring 517 functions as the select transistor STT 2.

The columnar via C 0 is arranged on the upper surface of the semiconductor layer 520 in the dummy pillar DPL (the wiring 516 side along the direction Z). The upper end of the via C 0 contacts one corresponding wiring 516 (bit line BL). The columnar via C 5 is arranged on the lower surface of the semiconductor layer 520 in the dummy pillar DPL (the wiring 510 along the direction Z). The lower end of the via C5 contacts one corresponding wiring 510 (local bit line LBL). Therefore, the wiring 510 and the wiring 516 are connected to each other through the semiconductor layer 520 and the metal layer 522 in the memory pillar PL.

### 2-4. Example of Operation in Semiconductor Storage Device

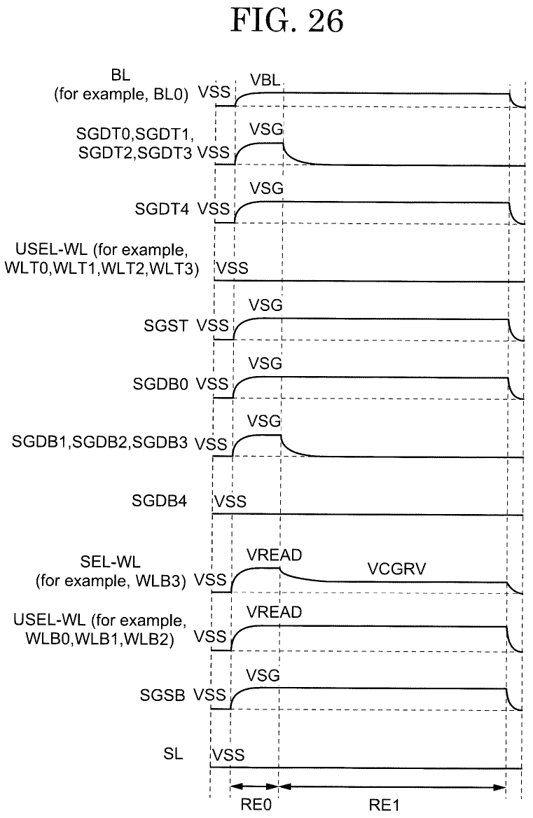

Referring to FIG. 26 to FIG. 32, an operation in the semiconductor storage device 10B will be described.

### 2-4-1. Example of Read Operation in Semiconductor Storage Device

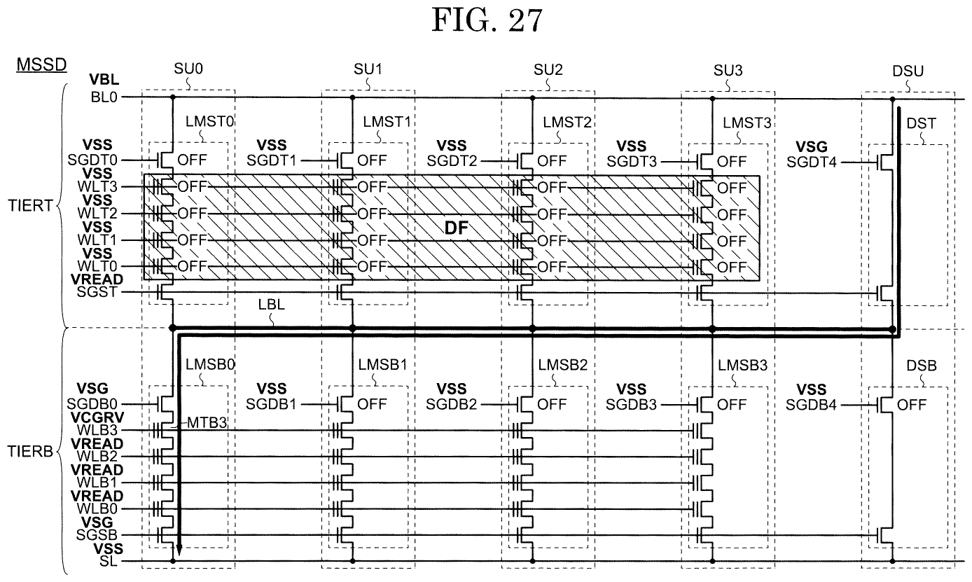

Referring to FIG. 26 and FIG. 27, a read operation of data in the semiconductor storage device 10B will be described. FIG. 26 is a timing chart showing waveforms of various types of read operations in the semiconductor storage device 10B. FIG. 27 is a circuit diagram showing the memory string set MSSD in the read operation of the semiconductor storage device 10B. In the circuit diagram shown in FIG. 27, the reference sign of the transistor in the circuit diagram shown in FIG. 3 is omitted. In one example of the read operation of the semiconductor storage device, an example is shown in which the selected transistor is the memory cell transistor MTB 3.

As shown in FIG. 26, the read operation includes at least the period RE 0 and a period RE 1. The word lines WLT 0 to WLT 3 (USEL-WL), the select gate line SGDB 4 and the source line SL are supplied with the voltage VSS for all periods shown in FIG. 26. Therefore, the memory cell transistors MTT 0 to MTT 3 connected to the word lines WLT 0 to WLT 3 and the select transistor STB 2 connected to the select gate line SGDB 4 are in the off state for all the periods shown in FIG. 26.

As shown in FIG. 26, until the period RE 0, the bit line BL (for example, BL 0), the select gate lines SGDT 0 to SGDT 3 (USEL-SGD), the select gate line SGST (USEL-SGS), the select gate line SGDB 0 (SEL-SGD), the select gate lines SGDB 1 to SGDB 3 (USEL-SGD), the word line WLB 3 (SEL-WL), the word lines WLB 0 to WLB 2 (USEL-WL), and the select gate line SGSB (SEL-SGS) are supplied with the voltage VSS and the signal lines are in the standby state. In this case, the select transistor STT 1 connected to the select gate lines SGDT 0 to SGDT 3, the memory cell transistors MTT 0 to MTT 3, the select transistor STT 2, the select transistor STB 1 connected to the select gate lines SGDB 0 to SGDB 3, the memory cell transistor MTB 3, the memory cell transistors MTB 0 to MTB 2, and the select transistor STB 2 are in the off state.

For example, in the period RE 0, the bit line BL is supplied with the voltage VBL, the select gate lines SGDT 0 to SGDT 3, the select gate line SGDT 4, the select gate line SGST, the select gate lines SGDB 0 to SGDB 3, and the select gate line SGSB are supplied with the voltage VSG, and the selected word line WLB 3 and word lines WLB 0 to WLB 2 are supplied with the voltage VREAD. Thus, the select transistor STT 1 connected to the select gate lines SGDT 0 to SGDT 4, the select transistor STB 1 connected to the select gate lines SGDB 0 to SGDB 4, the memory cell transistors MTT 0 to MTT 3 electrically connected to the respective signal lines, the select transistor STT 2, the memory cell transistor MTB 3, the memory cell transistors MTB 0 to MTB 2, and the select transistor STB 2 are turned into the on state.

Consequently, in the period RE 0, in the memory string set MSS connected to the bit line BL, the local memory strings LMST 0 to LMST 3 of the non-selected tier TIERT and the dummy string DSB are non-conductive, and the dummy string DST of the non-selected tier TIERT and the local memory strings LMSB 0 to LMSB 3 of the selected tier TIERT are conductive. Thus, all MTTB 0 to MTTB 3 of the local memory strings LMSB 0 to LMSB 3 of the selected tier TIERT are precharged to the voltage VBL.

In addition, for example, in the period RE 0, the select gate lines SGDT 0 to SGDT 3 may be supplied with the voltage VSS.

In the period RE 1, the bit line BL is subsequently supplied with the voltage VBL, and the select gate line SGDT 4, the select gate line SGST, the select gate line SGDB 0, and the select gate line SGSB are subsequently supplied with the voltage VSG, and the word lines WLB 0 to WLB 2 are subsequently supplied with the voltage VREAD. The select gate lines SGDT 0 to SGDT 3 and the select gate lines SGDB 1 to SGDB 3 are supplied with the voltage VSS. The word line WLT 3 is supplied with the voltage VCGRV. Thus, the select transistor STT 1 connected to the select gate line SGDT 4, the select transistor STB 1 connected to the select gate line SGDB 0, the memory cell transistors MTB 0 to MTB 3, and the select transistor STB 2 remain in the on state. The select transistor STT 1 connected to the select gate lines SGDT 0 to SGDT 3 and the select transistor STB 1 connected to the select gate lines SGDB 1 to SGDB 3 are turned into the off state. The memory cell transistor MTB 3 and the memory cell transistors MTB 0 to MTB 2 are in the on state.

Consequently, in the period RE 1, in the memory string set MSS connected to the selected bit line SEL-BL, the local memory strings LMST 0 to LMST 3 of the non-selected tier TIERT, the local memory strings LMSB 1 to LMSB 3 of the selected tier TIERB and the dummy string DSB do not conduct, and the dummy string DST of the non-selected tier TIERT and the local memory string LMSB 0 of the selected tier TIERT conduct.

That is, in the period RE 1, the bit line BL 0 (SEL-BL) is electrically connected with the source line SL via the dummy string DST of the non-selected tier TIERT, the local bit line LBL, and the local memory string LMSB0 of the selected tier TIERB. Thus, as indicated by the thick solid line in FIG. 27, in the memory string set MSSD in the read operation, via the dummy string DST of the non-selected tier TIERT, the local bit line LBL, and the local memory string LMSB 0 of the selected tier TIERB, the bit line BL 0 (SELs-BL) and the source line SL are conductive and the threshold value stored in the memory cell transistor MTB 3 is read. The sense amplifier module 23 electrically connected to the bit line BL 0 senses a current value corresponding to the threshold value, and the semiconductor storage device 10B can read the data.

In a period after the period RE 1, the same voltage as the period until the period RE 0 is supplied to each signal line, and each transistor is in the off state.

As described above, the semiconductor storage device 10B performs the read operation.

As described above, the semiconductor storage device 10B conducts the dummy string DST including the metal layers 522 in the non-selected tier TIERT so that a sufficient current for readout can flow to the local memory string LMSB 0 including the select memory cell transistor MTB 3 in the selected tier TIERB. In this case, since VSS is supplied to the gate of the transistor in the local memory strings LMST 0 to LMST 3 in the non-selected tier TIERT in the semiconductor storage device 10B corresponding to the region DF indicated by the diagonal line in FIG. 27, all the transistors in the non-selected tier TIERB are in the off state, and there is no path through which the current flows in the non-selected tier TIERB. Therefore, the memory cell transistors MTB 0 to MTB 3 in the non-selected tier TIERB is not affected by disturbance (disturbance free). Therefore, the semiconductor storage device 10B can suppress a reduction in the current flowing in the memory string in the read operation, and can suppress the data stored in the memory cell transistors using the sense amplifier module from becoming difficult to sense. That is, it is possible for the semiconductor storage device 10B to suppress a decrease in the performance of the read operation in the semiconductor storage device 10B even if the number of stacked layers is increased.

Further, in the section “2-4-1. Example of Read Operation in Semiconductor Storage Device”, similar to “1-6-2-1. First Example of Program Operation in Semiconductor Storage Device”, for example, the select gate line SGST may be configured to be divided for each local memory string LMST 0 to LMST 3 and electrically connected to each select transistor STT 2 in the local memory strings LMST 0 to LMST 3 as the select gate lines SGST 0 to SGST 3, similar to the select gate lines SGDT 0 to SGDT 3. Also, in this case, the select gate line SGSB may be configured to be separated by local memory strings LMSB 0 to LMSB 3 and electrically connected as the select gate lines SGSB 0 to SGSB 3 to a respective select transistor STB 2 in the local memory strings LMSB 0 to LMSB 3.

### 2-4-2. Example of Program Operation in Semiconductor Storage Device

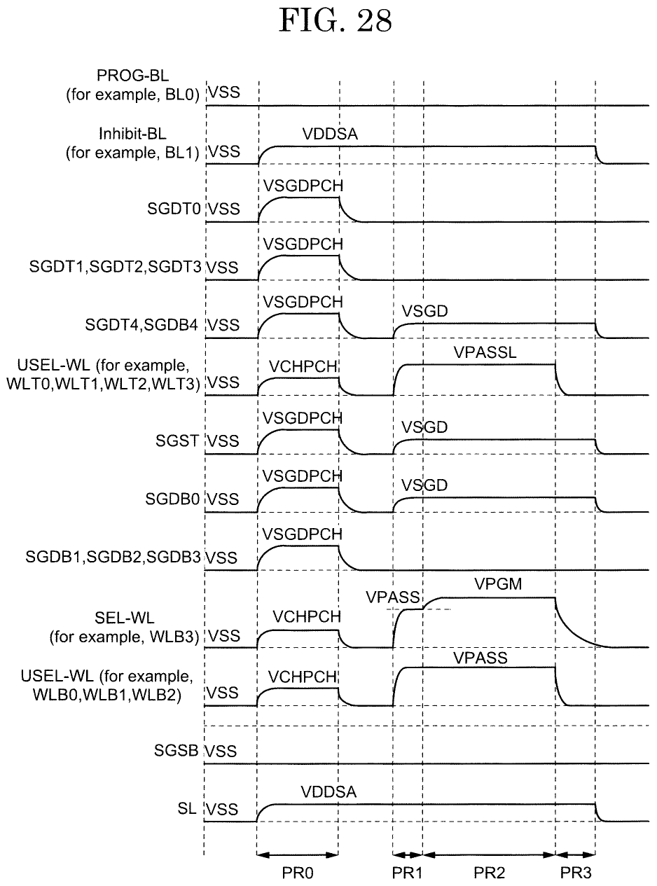

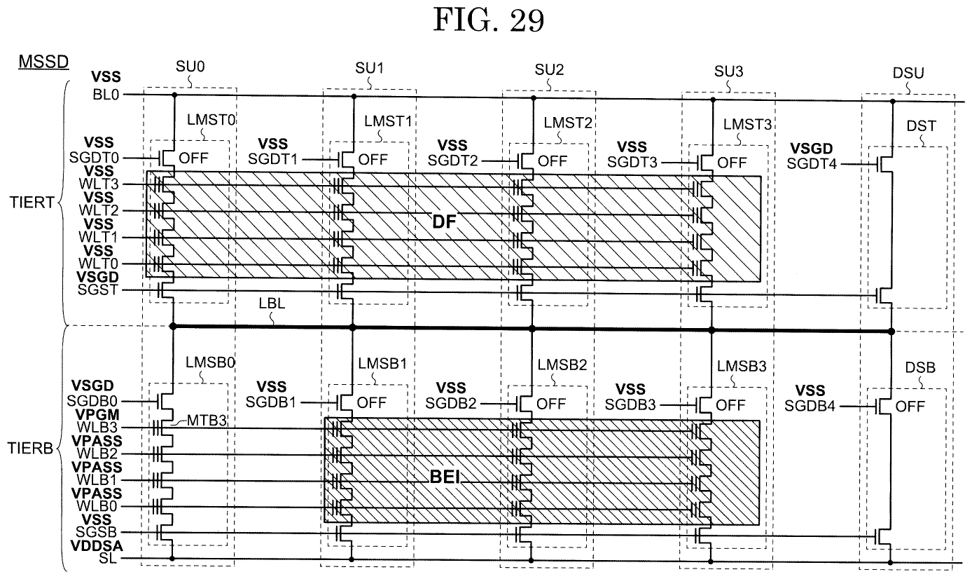

Referring to FIG. 28 and FIG. 29, a program operation in the semiconductor storage device 10B will be described. FIG. 28 is a timing chart showing waveforms of various types of program operations in the semiconductor storage device 10B. FIG. 29 is a schematic diagram showing the memory string set MSSD in the program operation of the semiconductor storage device 10B. In an example of the program operation of the semiconductor storage device 10B, an example is shown in which the tier TIERB is a selected tier, and the selected transistor is the memory cell transistor MTB 3. In the circuit diagram shown in FIG. 29, the sign of the transistor in the circuit diagram shown in FIG. 3 is omitted.

The semiconductor storage device 10B includes the dummy string unit DSU, and a flowchart during the program operation in the semiconductor storage device 10B shown in FIG. 28 differs from a flowchart during a program operation in the semiconductor storage device 10 shown in FIG. 15 in a following configuration 14. (Configuration 14) With the addition of the dummy string unit DSU, the select gate lines SGDT 0, SGDT 4, SGST, SGDB 4, and SGSB are controlled, the select transistor LMST 0 of the local memory string STT 1 is turned into the off state, the select transistors STT 1 and STT 2 of the dummy string DST are turned into the on state, and the select transistors STB 1 and STB 2 of the dummy string DSB are turned into the off state.

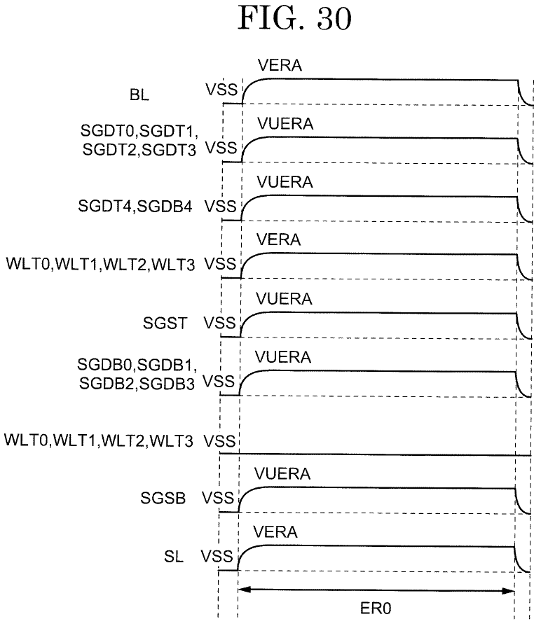

Configurations other than the configuration 14 in the timing chart shown in FIG. 30, as well as configurations other than configurations related to the configuration 14 are the same as the configuration in the timing chart shown in FIG. 15. Therefore, in the description of the timing chart in the section “2-4-2. Example of Program Operation in Semiconductor Storage Device”, the description of the same or similar configuration and function as in the timing chart shown in the section “1-6-2-1. First Example of Program Operation in Semiconductor Storage Device” is omitted and will be described as necessary.

As shown in FIG. 28, the select gate lines SGDT 0, SGDT 4, and SGDB 4 are supplied with the voltage VSS until the period PR 1. Thus, the select transistor STT 1 connected to the select gate line SGDT 0, the select transistor STT 1 connected to the select gate line SGDT 4, and the select transistor STB 1 connected to the select gate line SGDB 4 are in the off state. A signal (voltage) supplied to other signal lines shown in FIG. 28 is the same as the signal (voltage) supplied to the signal lines of the same names shown in FIG. 15, the state of each transistor is the same as the content described with reference to FIG. 15, and the description here is omitted.

In the period PR 1, the select gate line SGDT 0 is supplied with the voltage VSS and the select gate lines SGDT 4 and SGDB 4 are supplied with the voltage VSGD. The select transistor STT 1 connected to the select gate line SGDT 0 and the select transistor STT 1 connected to the select gate line SGDT 4 are in the on state. A signal (voltage) supplied to other signal lines shown in FIG. 28 in the period PR 1 is the same as the signal (voltage) supplied to the signal lines of the same name shown in FIG. 15, the state of each transistor is the same as the content described with reference to FIG. 15, and the description here is omitted.

Consequently, in the period PR 1, only the dummy string DST of the non-selected tier TIERT is conductive and the local memory strings LMST 0 to LMST 3 of the non-selected tier TIERT, the local memory strings LMSTB 0 to LMSTB 3 of the selected tier TIERB, and the dummy string DSB are non-conductive. In the period PR 1, since the respective memory cell transistors MTB 0 to MTB 3 in the local memory strings LMSTB 1 to LMSTB 3 are in the on state and the select transistor STB 1 connected to the select gate lines SGDB 1 to SGDB 3, and the select transistor STB 2 are in the off state, channels of the respective memory cell transistors MTB 0 to MTB 3 in the local memory strings LMSTB 1 to LMSTB 3 are in the floating state and the boosted state.

In the period PR 2, the select gate line SGDT 0 maintains the voltage VSS and the select gate lines SGDT 4 and SGDB 4 maintain the voltage VSGD. The select transistor STT 1 connected to the select gate line SGDT 0 and the select transistor STT 1 connected to the select gate line SGDT 4 remain in the on state. A signal (voltage) supplied to other signal lines shown in FIG. 28 in the period PR 2 is the same as the signal (voltage) supplied to the signal lines of the same name shown in FIG. 15, the state of each transistor is the same as the content described with reference to FIG. 15, and the description here is omitted.

In the period PR 2, as in the period PR 1, only the dummy string DST of the non-selected tier TIERT is conductive, and the local memory strings LMST 0 to LMST 3 of the non-selected tier TIERT, the local memory strings LMSTB 0 to LMSTB 3 of the selected tier TIERB, and the dummy string DSB are non-conductive. Further, in the period PR 2, similar to the period PR 1, the select transistor STB 1 connected to the select gate line SGDB 0 and the memory cell transistors MTB 0 to MTB 3 in the local memory strings LMSTB 1 to LMSTB 3 are in the on state, and the select transistor STB 1 connected to the select gate lines SGDB 1 to SGDB 3 and the select transistor STB 2 are in the off state. Therefore, the memory cell transistor MTB 3 connected to the word line WLB 3 which is the selected word line is selected, and the threshold voltage is increased or the threshold voltage is maintained on the basis of the voltage supplied to the bit line BL 0. Also, the channels of the respective memory cell transistors MTB 0 to MTB 3 in the local memory strings LMSTB 1 to LMSTB 3 maintain the floating state and the boosted state.

In the period PR 3, the select gate line SGDT 0 maintains the voltage VSS and the select gate line SGDT 4 and SGDB 4 maintain the voltage VSGD. The select transistor STT 1 connected to the select gate line SGDT 0 and the select transistor STT 1 connected to the select gate line SGDT 4 remain in an on state. A signal (voltage) supplied to other signal lines shown in FIG. 28 in the period PR 3 is the same as the signal (voltage) supplied to the signal lines of the same name shown in FIG. 15, the state of each transistor is the same as the content described with reference to FIG. 15, and the description here is omitted.

In the period PR 3, as in the period PR 2, only the dummy string DST of the non-selected tier TIERT is conductive, and the local memory strings LMST 0 to LMST 3 of the non-selected tier TIERT, the local memory strings LMSTB 0 to LMSTB 3 of the selected tier TIERB, and the dummy string DSB are non-conductive.

In the period after the period PR 3, the same voltage as the period until the period PR 0 is supplied to each signal line, and each transistor is in the off state.

As described above, the semiconductor storage device 10B executes the program operation. Further, for example, the semiconductor storage device 10B executes a verify operation after the program operation. Description of the verify operation is omitted.

As described above, the semiconductor storage device 10B includes the dummy string unit DSU. The program operation of the semiconductor storage device 10B includes only the dummy string DST of the non-selected tier TIERT being conductive, the local memory strings LMST 0 to LMST 3 of the non-selected tier TIERT, the local memory strings LMSTB 0 to LMSTB 3 of the selected tier TIERB, and the dummy string DSB not being conductive. Therefore, in the program operation of the semiconductor storage device 10B, the voltage supplied to the gates of all the memory cell transistors MTT 0 to MTT 3 of the non-selected tier TIERT can be turned to the voltage VSS. That is, all the memory cell transistors MTT 0 to MTT 3 of the non-selected tier TIERT can be turned into the off state. Consequently, the memory cell transistors MTT 0 to MTT 3 of the non-selective tier TIERT in the semiconductor storage device 10B corresponding to the region DF indicated by the diagonal line in FIG. 29 are not affected by disturbance (disturbance free). Further, in the memory cell transistors MTB 0 to MTB 3 in the non-selected local memory strings LMSB 1 to LMSB 3 of the selected tier TIERB in the semiconductor storage device 10B corresponding to the region BEI indicated by the diagonal lines in FIG. 29, the number of stacked layers is suppressed by the local bit line LBL and the select transistors SGD and SGS. Therefore, in the selected tier TIERB in the semiconductor storage device 10B, it is possible to reduce the number of memory cell transistors for supplying the voltage VPASS more than the semiconductor storage device 10B. Thus, the semiconductor storage 10B can improve the boost efficiency of the memory cell transistors MTB 0 to MTB 3 in the non-selected local memory strings LMSB 1 to LMSB 3. Although an example in which the voltage VSS is supplied to the bit line BL 0 is shown in FIG. 29, in accordance with the write data WDT, in the case where the bit line BL 0 is the write bit line PROG-BL, the voltage VSS is supplied to the bit line BL 0, and in the case where the bit line BL 0 is the non-write bit line Inhibit-BL, the voltage VDDSA is supplied to the bit line BL 0.

In addition, similar to the content described in the section “1-6-2. Example of Write Operation in Semiconductor Storage Device”, for example, in the period PR 0 in the write operation in the semiconductor storage device 10B, the voltage VDDSA may be supplied to the write bit line PROG-BL. Further, for example, in the period PR 0 in the semiconductor storage device 10, the source line SL may be supplied with the voltage VDDSA, the select gate lines SGDT 1 to SGDT 3 may be supplied with the voltage VSS, and the select gate line SGSB may be supplied with the voltage VSGDPCH. In this case, the select transistor STT 1 is in the off state, and the memory cell transistors MTT 0 to MTT 3, the select transistor STT 2, the select transistors SGDB 0 to SGDB 3, the memory cell transistor MTB 3, the memory cell transistors MTB 0 to MTB 2, and the select transistor STB 2 are in the on state. Thus, although the local memory strings LMST 0 to LMST 3 of the non-selected tier TIERT are non-conductive, the local memory strings LMSB 0 to LMSB 3 of the selected tier TIERB are conductive. Consequently, the voltage VDDSA is supplied from the source line SL to the local memory strings LMST 0 to LMST 3 of the non-selected tier TIERT, for example, via the local memory strings LMSB 0 to LMSB 3 of the selected tier TIERB, and the channels of the transistors are precharged to the voltage VDDSA.

Further, for example, in the period PR 1 in the write operation in the semiconductor storage device 10B, the voltage VSGD may be supplied to the select gate lines SGDT 0 to SGDT 3 in the same manner as the select gate line SGDT 4. Thus, the select transistor STT 1 connected to each of the select gate lines SGDT 0 to SGDT 3 is turned into the on state. Since all of the channels of the non-selected tier TIERT can be conductive, the resistance value can be reduced.

Further, for example, in the write operation in the semiconductor storage 10B, for example, the select gate line SGST may be configured to be divided into the local memory strings LMST 0 to LMST 3 and the dummy string DST in the same manner as the select gate lines SGST 0 to SGST 4, and may be electrically connected to the respective select transistors STT 2 in the local memory strings LMST 0 to LMST 3 and the dummy string DST as the select gate lines SGST 0 to SGST 4. Further, in this case, since the voltage of the selected bit line BL 0 (PROG-BL) passes through the dummy, the voltage supplied to the word lines WLT 0 to WLT 3 on the non-selected tier TIERT side may be the voltage VSS rather than the voltage VPASSL. The select gate line SGSB may also be configured to be divided into the local memory strings LMSB 0 to LMSB 3 and the dummy string DST in the same manner as the select gate lines SGSB 0 to SGSB 4, and may be electrically connected to the respective select transistors STB 2 in the local memory strings LMSB 0 to LMSB 3 and the dummy string DST.

### 2-4-3. Example of Erase in Semiconductor Storage Device

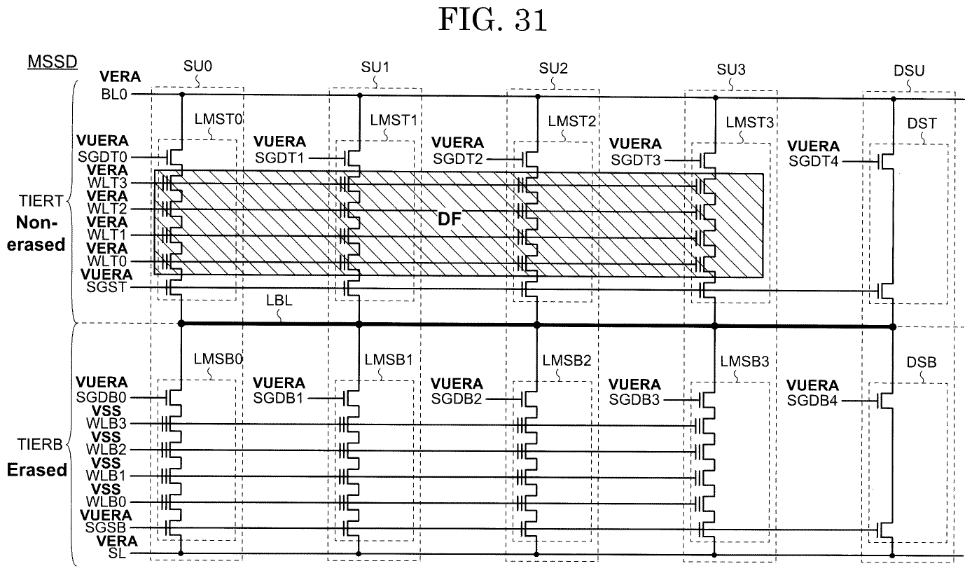

Referring to FIG. 30 and FIG. 31, a data erase operation (erase operation) in the semiconductor storage device 10B will be described. FIG. 30 is a timing chart showing waveforms of various types of erase operations in the semiconductor storage device 10B. FIG. 31 is a circuit diagram for explaining the memory string set MSS in the erase operation in the semiconductor storage device 10B. In the circuit diagram shown in FIG. 31, the reference signs of the transistor in the circuit diagram shown in FIG. 3 are omitted. In an example of the erase operation in the semiconductor storage device 10B, similar to the semiconductor storage device 10 shown in FIG. 21, an example is shown in which data of the respective memory cell transistors MTB 0 to MTB 3 of the local memory strings LMSB 0 to LMSB 3 included in the tier TIERB is erased. That is, the tier TIERB is the selected tier including the memory cell transistor to be erased, the tier TIERB is the selected tier TIERB, the tier TIERT is the tier not to be erased, and is marked as the non-selected tier TIERT.

The semiconductor storage device 10B includes the dummy string unit DSU, and a flowchart during the erase operation in the semiconductor storage device 10B shown in FIG. 30 differs from a flowchart during an erase operation in the semiconductor storage device 10 shown in FIG. 20 in the following configuration 15.
(Configuration 15) With the addition of the dummy string unit DSU, the selected tier is energized via the dummy string (for example, DST) to erase data for memory cell transistors in the selected tier.

Configurations other than the configuration 15 in the timing chart shown in FIG. 30 and configurations other than configurations related to the configuration 15 are the same as the configurations in the timing chart shown in FIG. 20. Therefore, in the description of the timing chart in the section “2-4-2. Example of Program Operation in Semiconductor Storage Device”, the description of the same or similar configuration and function as in the timing chart shown in the section “1-6-3. Example of Erase in Semiconductor Storage Device” is omitted and will be described as necessary.

As shown in FIG. 30, until the period ER 0, the select gate lines SGDT 4 and SGDB 4 are supplied with the voltage VSS and the signal lines are in the standby state. In this case, the transistors of the select transistor STT 1 connected to the select gate line SGDT 4 and the select transistor STB 1 connected to the select gate line SGDB 4 are in the off state. A signal (voltage) supplied to the other signal lines shown in FIG. 30 until the period ER 0 is the same as the signal (voltage) supplied to the signal lines of the same name shown in FIG. 20, and the state of each transistor is the same as that described with reference to FIG. 20, and the description thereof will be omitted here.

In the period ER 0, the select gate lines SGDT 0 to SGDT 3 are supplied with the voltage VUERA. The select gate lines SGDT 4 and SGDB 4 are supplied with the voltage VUERA. The bit line BL and the word lines WLT 0 to WLT 3 are supplied with the voltage VERA. Therefore, there is no potential difference between the gate terminal of each of the select transistors STT 1 connected to the gate lines SGDT 0 to SGDT 3 and the vicinity of the bit line BL, and the select transistors STT 1 connected to the select gate lines SGDT 0 to SGDT 3 are in the off state. Thus, the local memory strings LMST 0 to LMST 3 are non-conductive. On the other hand, the gate terminal of the select transistor STT 1 in the dummy string DST connected to the select gate line SGDT 4 is supplied with the voltage VUERA, and the vicinity of the bit line BL is supplied with the voltage VERA. Also, a gate terminal of the select gate line STT 2 in the dummy string DST is supplied with the voltage VUERA. Therefore, the dummy string DST is conductive. A signal (voltage) supplied to other signal lines shown in FIG. 30 is the same as the signal (voltage) supplied to the signal line of the same name shown in FIG. 20, and since the state of each transistor is the same as the content described with reference to FIG. 20, the description here is omitted.

In the period ER 0, the transistors in the selective tier TIERB include a configuration similar to that described with respect to FIG. 20. Thus, electrons of the respective charge storage layers of the memory cell transistors MTB 0 to MTB 3 in the selected tier TIERB are extracted by the generated holes, and the data of the memory cell transistors MTB 0 to MTB 3 in the selected tier TIERB is erased.

On the other hand, as described above, in the non-selected tier TIERT, although the select transistor STT 1 connected to the select gate lines SGDT 0 to SGDT 3 is in the off state and the local memory strings LMST 0 to LMST 3 are non-conductive, since the dummy string DST is conductive, a current can flow from the bit line BL to the local bit line LBL through the dummy string DST. Each of the memory cell transistors MTT 0 to MTT 3 of the local memory strings LMST 0 to LMST 3 in the non-selected tier TIERT corresponding to the region DF shown by the diagonal line in FIG. 31 has no path through which the current flows. Therefore, the memory cell transistors MTT 0 to MTT 3 in the non-selected tier TIERT are not affected by disturbance (disturbance free). In addition, the data of the memory cell transistors MTT 0 to MTT 3 in the non-selected tier TIERT is not erased (the non-selected tier TIERT is not erased).

In a period after the period ER 0, the same voltage as the period until the period ER 0 is supplied to each signal line, and each transistor is in the off state.

As described above, the semiconductor storage device 10B is capable of making the non-selected tier TIER disturbance free and is capable of executing an erase operation for each selected tier TIER (sub block SUBBLK).

2-4-4. Example of Erase Verify operation in Semiconductor Memory Device

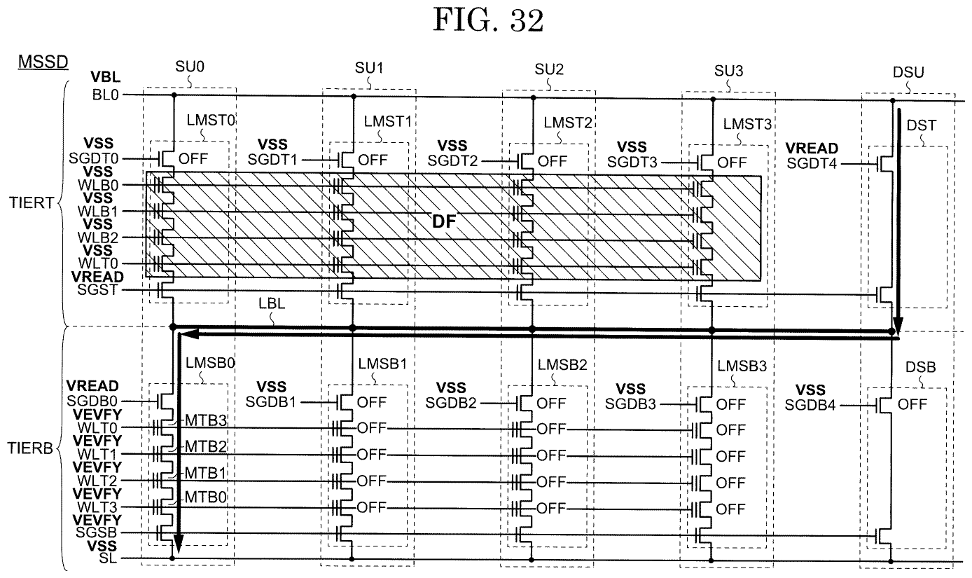

Referring to FIG. 32, an erase verify operation of data (erase verify operation) in the semiconductor storage device 10B will be described. FIG. 32 is a schematic diagram showing the memory string set MSSD in an erase verify operation in the semiconductor storage device 10B. In the circuit diagram shown in FIG. 32, the reference signs of the transistor in the circuit diagram shown in FIG. 3 are omitted. In an example of the erase verify operation in the semiconductor storage device, an example is shown in which the local memory string unit LMSB 0 is subject to the erase verify operation and the selected transistors (memory cell transistors MTB 0 to MTB 3) are verified. That is, the tier TIERB is the selected tier including the memory cell transistor to be the target of the erase verify operation, the tier TIERB is marked as the selected tier TIERB, the tier TIERT is the tier not to be the target of the erase verify operation, and the tier is marked as the non-selected tier TIERT.

The semiconductor storage device 10B includes the dummy string unit DSU, and a flowchart similar to the flowchart during the erase verify operation in the semiconductor storage device 10 shown in FIG. 22 may be used. However, the configurations 16 to 22 shown below are different from the erase verify operation in the semiconductor storage device 10.
(Configuration 16) As shown in FIG. 32, with the addition of the dummy string unit DSU (dummy strings DST and DSB), a current is applied to the local bit line LBL from the bit line BL by supplying the voltage VBL to the select gate lines SGDT 4 and SGDB 4 in the dummy string DST, and making the dummy string DST conductive.
(Configuration 17) As shown in FIG. 32 and FIG. 23, in the semiconductor storage device 10 and the semiconductor storage device 10B, the signals (voltages) supplied to the transistors in the local memory strings LMSB 0 to LMST 3 in the selected tier TIERB are the same.
(Configuration 18) With the addition of the dummy string unit DSU (dummy strings DST and DSB), the dummy string DSB can be non-conductive by supplying the select gate line SGDB 4 in the dummy string DSB in the selected tier TIERB with the voltage VSS.
(Configuration 19) Configurations 17 to 19 allow the dummy string DST, the local bit line LBL, and the local memory string LMSB 0 in the selected tier TIERB to be conductive, a current flows from the bit line BL to the source line SL, and it is possible to perform the erase verify operation to the memory cell transistors MTB 0 to MTB 3 in the local memory string LMSB 0, as shown in FIG. 32.
(Configuration 20) With the configuration 18, as shown in FIG. 32, the voltage VSS is supplied to the select gate lines SGDT 0 to SGDT 3 and the word lines WLT 0 to WLT 3 in the local memory strings LMST 0 to LMST 3 in the unselected tier TIER (for example, TIERT), the select transistor STT 1 and the memory cell transistors MTT 0 to MTT 3 connected to the select gate lines SGDT 0 to SGDT 3 are turned into the off state, and the local memory strings LMST 0 to LMST 3 are made non-conductive.
(Configuration 21) With the configuration 17, each of the memory cell transistors MTT 0 to MTT 3 of the local memory strings LMST 0 to LMST 3 in the non-selected tier TIERT corresponding to the region DF indicated by a diagonal line in FIG. 32 has no path through which current flows. Therefore, the memory cell transistors MTT 0 to MTT 3 in the non-selected tier TIERT are not affected by disturbance (disturbance free).
(Configuration 22) With the addition of the dummy string unit DSU (dummy strings DST and DSB), by making the dummy string DST conductive, the data of the memory cell transistors MTT 0 to MTT 3 in the non-selected tier TIERT is not erased (the non-selected tier TIERT is in a non-erasable state).

Configurations other than configurations 16 to 22 and configurations other than configurations related to configurations 16 to 22 are the same as in the timing chart shown in FIG. 20. Therefore, in the description of “2-4-4. Example of Erase Verify Operation in Semiconductor Storage Device”, the description of the same or similar configuration and function as those shown in the section “1-6-4. Example of Erase Verify Operation in Semiconductor Storage Device” is omitted.

### 2-4-5. Modification of Semiconductor Memory Device 10B

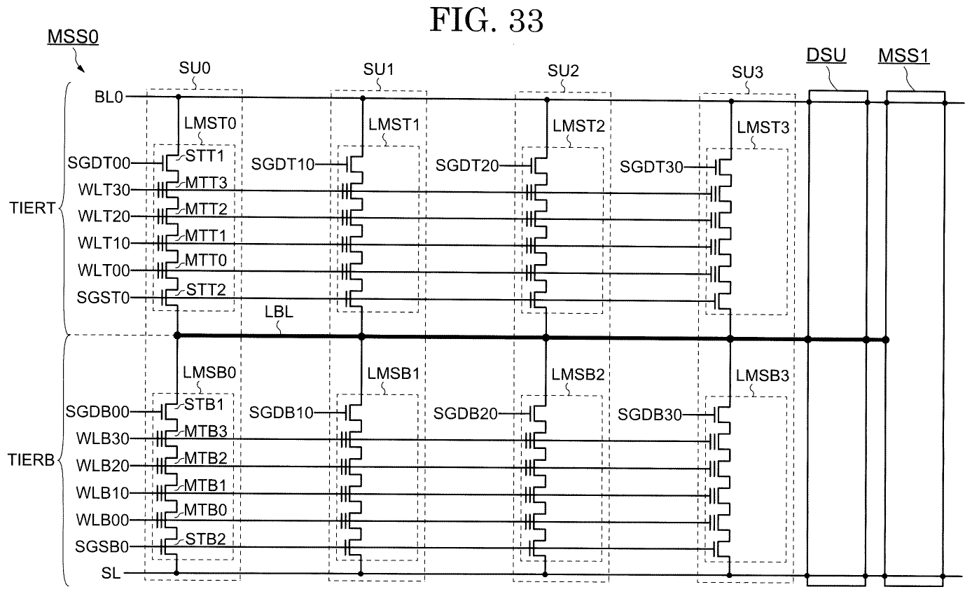

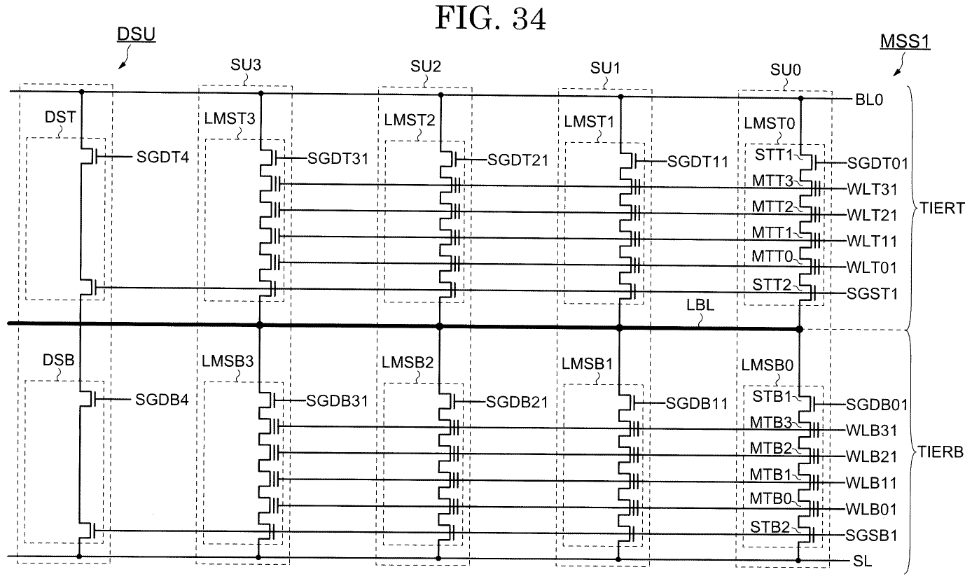

Referring to FIG. 33 and FIG. 34, a modification of the semiconductor storage device 10B (a modified semiconductor storage device 10B) will be described. FIG. 33 and FIG. 34 are circuit diagrams showing a modification of the circuit configuration of the memory string set MSSD of the semiconductor storage device 10B.

For example, as shown in FIG. 33 and FIG. 34, the dummy string unit DSU may be shared by the plurality of memory string sets MSS. The examples shown in FIG. 33 and FIG. 34 show examples in which the dummy string unit DSU is shared by two memory string sets MSS 0 and MSS 1. The number of memory string sets MSS shared by the dummy string unit DSU is not limited to the cases shown in FIG. 33 and FIG. 34. For example, the dummy string unit DSU may share three or more memory string sets MSS.

As shown in FIG. 33 and FIG. 34, the modified semiconductor storage device 10B includes the memory string set MSS 0, the dummy string unit DSU, and the memory string set MSS 1. The memory string set MSS 0 and the memory string set MSS 1 have the same configuration as the memory string set MSS. For example, the dummy string unit DSU is electrically connected between the memory string set MSS 0 and the memory string set MSS 1.

Although not shown, for example, a direction in which the memory string set MSS 0, the dummy string unit DSU, and the memory string set MSS 1 are arranged is the direction in which the bit line BL extends, that is, the memory string set MSS 0, the dummy string unit DSU, and the memory string set MSS 1 are arranged along the direction in which the bit line BL extends.

In addition, in the tier TIERB of the memory string set MSS 0, each signal line is a select gate line SGDB 00 to SGDB 30 and SGSB 0, and a word line WLB 00 to WLB 30, and in the tier TIERT of the memory string set MSS 1, each signal line is a select gate line SGDT 00 to SGDT 30 and SGST 0, and a word line WLT 00 to WLT 30. In addition, in the tier TIERB of the memory string set MSS 1, each signal line is a select gate line SGDB 01 to SGDB 31 and SGSB 1, and a word line WLB 01 to WLB 31, and in the tier TIERT of the memory string set MSS 1, each signal line is a select gate line SGDT 01 to SGDT 31 and SGST 1, and a word line WLT 01 to WLT 31.

### 3. Third Embodiment

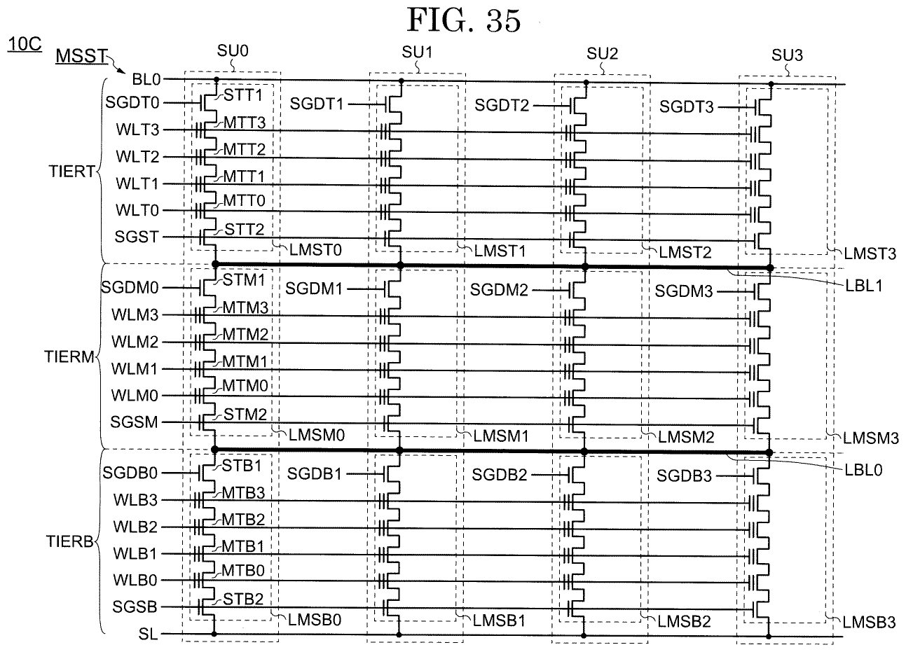

Referring to FIG. 35 to FIG. 39, a semiconductor storage device 10C according to a third embodiment will be described.

### 3-1. Overall Configuration of Semiconductor Memory Device 10C

Referring to FIG. 35, the overall configuration of the semiconductor storage device 10C will be described. FIG. 35 is a circuit diagram showing a circuit configuration of a memory string set MSST of the semiconductor storage device 10C. As shown in FIG. 35, the semiconductor storage device 10C includes at least the following configurations 23 to 25 as compared to the semiconductor storage device 10, 10A or 10B.
(Configuration 23) A configuration containing the memory string set MSST. The memory string set MSST includes a tier TIERM between the tier TIERT and the tier TIERB in the memory string set MSS.
(Configuration 24) The tier TIERM includes a configuration similar to the tier TIERT or the tier TIERB. For example, the tier TIERM has a configuration in which the source line SL, the local bit line LBL, the local memory strings LMSB 0 to LMSB 3, the select gate lines SGDB 0 to SGDB 3 and SGSB electrically connected to the local memory strings LMSB 0 to LMSB 3, the word lines WLB 0 to WLB 3, select transistors STB 1 and STB 2 arranged in each of the local memory strings LMSB 0 to LMSB 3 and electrically connected to the select gate lines SGDB 0 to SGDB 3 and SGSB and the word lines WLB 0 to WLB 3, and the memory cell transistors MTB 0 to MTB 3 in the tier TIERB are replaced with a local bit line LBL 0, a local bit line LBL 1, local memory strings LMSM 0 to LMSM 3, select gate lines SGDM 0 to SGDM 3 and SGSM electrically connected to the local memory strings LMSM 0 to LMSM 3, word lines WLM 0 to WLM 3, select transistors STM1 and STM2 arranged in each of the local memory strings LMSM 0 to LMSM 3 and electrically connected to select gate lines SGDM 0 to SGDM 3 and SGSM and the word lines WLM 0 to WLM 3, and memory cell transistors MTM 0 to MTM 3.
(Configuration 25) For example, the tier TIERM is electrically connected to the tier TIERB via the local bit line LBL 0 and electrically connected to the tier TIERT via the local bit line LBL 1.

Configurations other than the configurations 23 to 25 and configurations related to the configurations 23 to 25 in the semiconductor storage device 10C are the same as the configurations of the semiconductor storage device 10, 10A, or 10B. In the description of the semiconductor storage device 10C, the description of the same or similar content as the semiconductor storage device 10, 10A, or 10B may be omitted, and the same or similar content as the semiconductor storage device 10, 10A, or 10B may be described as required.

The local bit lines LBL 0 and LBL 1 are not electrically connected to the peripheral circuit 20, unlike the bit line BL and the source line SL, and are not driven by the peripheral circuit 20, as is the case with the local bit line LBL. That is, the local bit lines LBL 0 and LBL 1 are closed wirings in the memory string set MSS between the bit line BL and the source line SL. In other words, the local bit lines LBL 0 and LBL 1 are connected to a peripheral circuit 20 via the bit line BL or the source line SL that are connected to corresponding local memory strings. The applied voltage to the local bit line LBL of the selected block BLK is determined based on the bit line BL and the source line SL.

### 3-2. Example of Operation in Semiconductor Storage Device

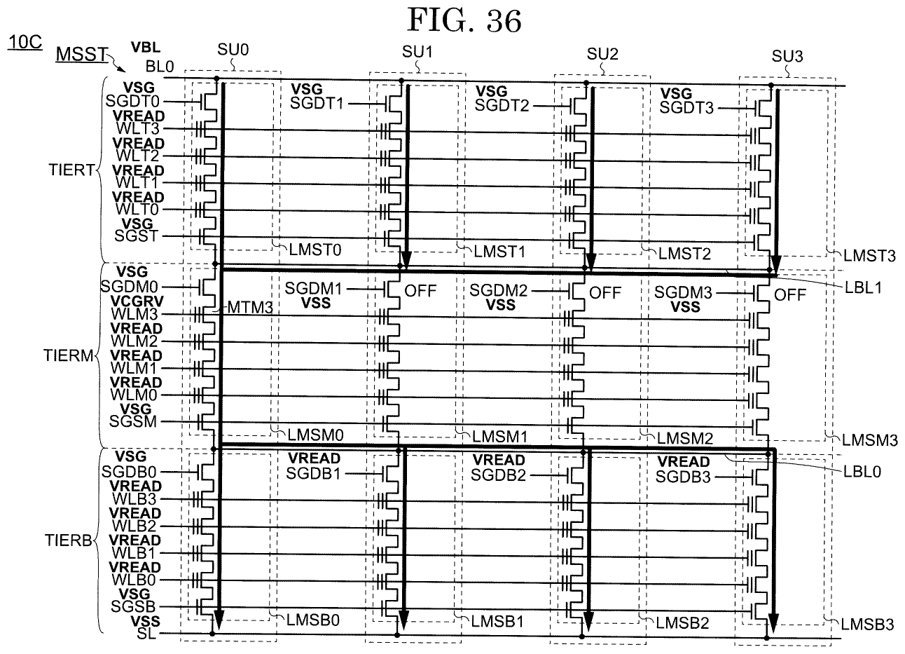

Referring to FIG. 36 to FIG. 39, an operation in the semiconductor storage device 10C will be described.

### 3-2-1. Example of Read Operation in Semiconductor Storage Device

Referring to FIG. 36, a read operation of data in the semiconductor storage device 10C will be described. FIG. 36 is a circuit diagram for showing the memory string set MSST in the read operation in the semiconductor storage device 10C. In the circuit diagram shown in FIG. 36, the reference signs of the transistor in the circuit diagram shown in FIG. 35 and the like are omitted. In one example of the read operation in the semiconductor storage device, an example is shown in which the selected transistor is a memory cell transistor MTM 3.

For example, the read operation of data in the semiconductor storage device 10C may use a timing chart similar to the timing chart in the semiconductor storage device 10 shown in FIG. 13.

For example, the tier TIERT in the semiconductor storage device 10C has the same configuration as each signal line of the tier TIERT in the semiconductor storage device 10, and is supplied with the signal (voltage) supplied to each signal line of the tier TIERT in the semiconductor storage device 10 in the timing chart shown in FIG. 13.

For example, the tier TIERB in the semiconductor storage device 10C has the same configuration as the signal lines of the tier TIERT in the semiconductor storage device 10, and in the timing chart shown in FIG. 13, the signal (voltage) supplied to the word lines SGDT 0 to SGDT 3 and SGST and the word lines WLT 0 to WLT 3 of the tier TIERT in the semiconductor storage device 10 are supplied to the select gate lines SGDB 0 to SGDB 3 and SGSB and the word lines WLB 0 to WLB 3 of the tier TIERB in the semiconductor storage device 10C.

For example, the tier TIERM in the semiconductor storage device 10C has the same configuration as the signal lines of the tier TIERB in the semiconductor storage device 10, and in the timing chart shown in FIG. 13, the signal (voltage) supplied to the select gate lines SGDB 0 to SGDB 3 and SGSB and the word lines WLB 0 to WLB 3 of the tier TIERB in the semiconductor storage device 10 are supplied to the select gate lines SGDM 0 to SGDM 3 and SGSM and the word lines WLM 0 to WLM 3 of the tier TIERM in the semiconductor storage device 10C.

Further, a signal (voltage) supplied to the source line SL and the bit line BL (for example, BL 0, BL 1) in the semiconductor storage device 10 is the same as the signal (voltage) supplied to the source line SL and bit line BL (BL 0, BL 1) in the semiconductor storage device 10 in the timing chart shown in FIG. 13.

For example, in the read operation of data in the semiconductor storage device 10C, the signal (voltage) described above is supplied to the respective signal lines. For example, in the period RE 1, the local memory strings LMST 0 to LMST 3 of the non-selected tier TIERT are all conductive and electrically connected between the bit line BL 0 and the local bit line LBL 1 to carry current from the bit line BL 0 to the local bit line LBL 1. Also, the local memory string LMSM 0 of the selective tier TIERM is conductive, the local memory strings LMSM 1 to LMSM 3 are non-conductive, and the local memory string LMSM 0 is electrically connected between the local bit line LBL 1 and the local bit line LBL 0 to carry current from the local bit line LBL 1 to the local bit line LBL 0. Also, the local memory strings LMSB 0 to LMSB 3 of the non-selected tier TIERB are all conductive and electrically connected between the local bit line LBL0 and the source line SL to carry current from the local bit line LBL0 to the source line SL.

Consequently, as indicated by the thick solid line shown in FIG. 36, current flows from the bit line BL 0 (SEL-BL) to the source line SL via the local memory strings LMST 0 to LMST 3 of the non-selected tier TIERT, the local bit line LBL 1, the local memory string LMSM 0 of the selected tier TIERM, and the local memory strings LMSB 0 to LMSB 3 of the selected tier TIERB. The current is a current in which a selected transistor is based on data (threshold voltage) of the memory cell transistor MTM 3, the sense amplifier module 23 electrically connected to the bit line BL0 senses the current, and the semiconductor storage device 10C can read the data.

### 3-2-2. Example of Program Operation in Semiconductor Storage Device

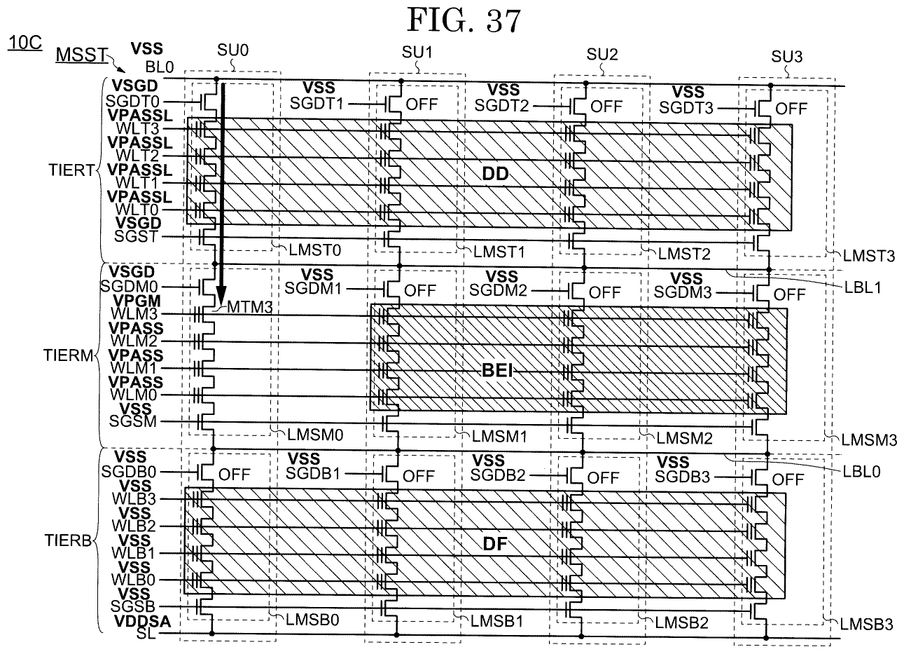

Referring to FIG. 37, a program operation in the semiconductor storage device 10C will be described. FIG. 37 is a schematic diagram showing the memory string set MSST in the program operation in the semiconductor storage device 10C. In an example of the program operation in the semiconductor storage device 10C, an example is shown in which the tier TIERM is the selected tier and the selected transistor is a memory cell transistor MTM 3. In the circuit diagram shown in FIG. 37, the reference signs of the transistors in the circuit diagram shown in FIG. 35 are omitted.

For example, the program operation of the data in the semiconductor storage device 10C may use a timing chart similar to the timing chart in the semiconductor storage device 10 shown in FIG. 15 or FIG. 18.

For example, the tier TIERT in the semiconductor storage device 10C has the same configuration as each signal line of the tier TIERT in the semiconductor storage device 10, and in the timing chart shown in FIG. 15, a signal (voltage) supplied to each signal line of the tier TIERT in the semiconductor storage device 10 is supplied.

For example, the tier TIERB in the semiconductor storage device 10C has the same configuration as each signal line of the tier TIERB in the semiconductor storage device 10, and in the timing chart shown in FIG. 18, a signal (voltage) supplied to each signal line of the tier TIERB in the semiconductor storage device 10 is supplied.

For example, the tier TIERM in the semiconductor storage device 10C has the same configuration as the signal lines of the tier TIERB in the semiconductor storage device 10, and in the timing chart shown in FIG. 15, the signal (voltage) supplied to the select gate lines SGDB 0 to SGDB 3 and SGSB and the word lines WLB 0 to WLB 3 of the tier TIERB in the semiconductor storage device 10 are supplied to the select gate lines SGDM 0 to SGDM 3 and SGSM and the word lines WLM 0 to WLM 3 of the tier TIERM in the semiconductor storage device 10C.

Further, the signal (voltage) supplied to the source line SL, the bit line BL 0 (PROG-BL), and the bit line BL 1 (Inhibit-BL) in the semiconductor storage device 10C is the same as the signal (voltage) supplied to the source line SL, the bit line BL 0 (PROG-BL), and the bit line BL 1 (Inhibit-BL) in the semiconductor storage device 10 in the timing chart shown in FIG. 15.

For example, in the program operation of the data in the semiconductor storage device 10C, the signal (voltage) described above is supplied to the respective signal lines. For example, in the period PR 2, the local memory string LMST 0 of the non-selected tier TIERT is conductive, the local memory strings LMST 1 to LMST 3 are non-conductive, and the local memory string LMST 0 is electrically connected between the bit line BL 0 and the local bit line LBL 1 to carry current from the bit line BL 0 to the local bit line LBL 1. Furthermore, the local memory string LMSM 0 of the selective tier TIERM is conductive, the local memory strings LMSM 1 to LMSM 3 are non-conductive, and the local memory string LMSM 0 is electrically connected between the local bit line LBL 1 and the local bit line LBL 0 to carry current from the local bit line LBL 1 to the local bit line LBL 0. In addition, the local memory strings LMSB 0 to LMSB 3 of the non-selective tier TIERB are all non-conductive, and are electrically connected between the local bit line LBL 0 and the source line SL, and the local bit line LBL 0 and the source line SL are electrically isolated from each other.

Consequently, the data (threshold voltage) can be programmed into the memory cell transistor MTM 3, which is the select transistor, via the local memory string LMST 0 of the non-selected tier TIERT, the local bit line LBL 1, and the local memory string LMSM 0 of the selected tier TIERM as shown by the thick solid line in FIG. 37.

Further, in the memory cell transistors MTM 0 to MTM 3 in the non-selected local memory strings LMSM 1 to LMSM 3 of the selected tier TIERM in the semiconductor storage device 10C corresponding to the region BEI indicated by diagonal lines in FIG. 37, the number of stacked layers is suppressed by the local bit lines LBL 1 and LBL 0 and the select transistors SGD and SGS. Therefore, in the selective tier TIERM in the semiconductor storage device 10C, it is possible to reduce the number of memory cell transistors for supplying the voltage VPASS more than in the semiconductor storage device 10C. Thus, the semiconductor storage 10C can improve the boost efficiency of the memory cell transistors MTM 0 to MTM 3 in the non-selected local memory strings LMSM 1 to LMSM 3.

Further, the memory cell transistors MTT 0 to MTT 3 of the non-selected tier TIERT in the semiconductor storage device 10C corresponding to the region DD indicated by diagonal lines in FIG. 37 are less susceptible to disturbance than the memory cell transistor supplied with the voltage VPASS in the semiconductor storage device 10P.

Further, since VSS is supplied to the gates, the local bit line LBL, and the source line SL of all the transistors in the non-selected tier TIERB in the semiconductor storage device 10C corresponding to the region DF indicated by hatched line in FIG. 37, there is no path through which current flows in all the transistors, and all the transistors are in the off state. Therefore, the memory cell transistors MTB 0 to MTB 3 in the non-selective tier TIERB are not affected by disturbance (disturbance free).

### 3-2-3. Example of Erase in Semiconductor Storage Device

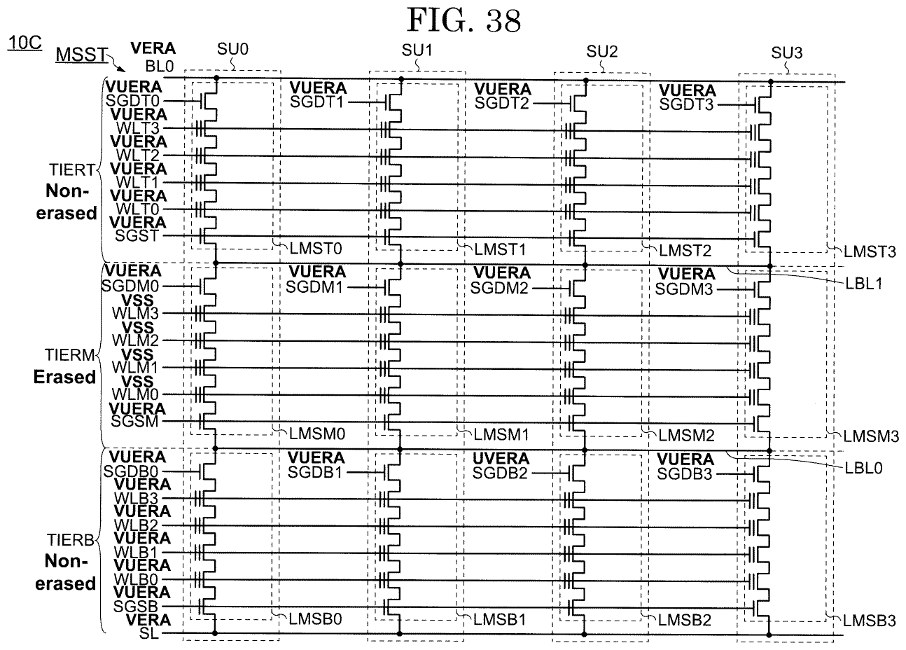

Referring to FIG. 38, a data erase operation in the semiconductor storage device 10C will be described. FIG. 38 is a schematic diagram showing the memory string set MSST in the erase operation in the semiconductor storage device 10C. In the circuit diagram shown in FIG. 38, the reference signs of the transistors in the circuit diagram shown in FIG. 35 are omitted. In one example of the erase operation in the semiconductor storage device 10C, an example is shown in which the local memory cell transistors MTB 0 to MTB 3 of the local memory strings LMSB 0 to LMSB 3 included in the tier TIERB of the semiconductor storage device 10 shown in FIG. 21 erases data of respective memory cell transistors MTM 0 to MTM 3 of the local memory strings LMSM 0 to LMSM 3 included in the tier TIERM in the semiconductor storage device 10C. That is, the tier TIERM is a selected tier including memory cell transistors to be erased, the tier TIERM is a selected tier TIERM, the tiers TIERT and TIERB are tiers not to be erased, and the tiers TIERT and TIERB are marked as non-selected tiers.

For example, the erase operation of data in the semiconductor storage device 10C may use a timing chart similar to the timing chart in the semiconductor storage device 10 shown in FIG. 20.

For example, the tier TIERT in the semiconductor storage device 10C has the same configuration as each signal line of the tier TIERT in the semiconductor storage device 10, and in the timing chart shown in FIG. 20, a signal (voltage) supplied to each signal line of the tier TIERT in the semiconductor storage device 10 is supplied to each signal line of the tier TIERT in the semiconductor storage device 10C.

For example, the tier TIERB in the semiconductor storage device 10C has the same configuration as each of the signal lines of the tier TIERT in the semiconductor storage device 10, and in the timing chart shown in FIG. 20, the signal (voltage) supplied to the select gate lines SGDT 0 to SGDT 3 and SGST and the word lines WLT 0 to WLT 3 of the tier TIERT in the semiconductor storage device 10 are supplied to the select gate lines SGDB 0 to SGDB 3 and SGSB and the word lines WLB 0 to WLB 3 of the tier TIERB in the semiconductor storage device 10C.

For example, the tier TIERM in the semiconductor storage device 10C has the same configuration as the signal lines of the tier TIERB in the semiconductor storage device 10, and in the timing chart shown in FIG. 20, the signal (voltage) supplied to the select gate lines SGDB 0 to SGDB 3 and SGSB and the word lines WLB 0 to WLB 3 of the tier TIERB in the semiconductor storage device 10 are supplied to the select gate lines SGDM 0 to SGDM 3 and SGSM and the word lines WLM 0 to WLM 3 of the tier TIERM in the semiconductor storage device 10C.

Further, the signal (voltage) supplied to the source line SL and the bit line BL (fo example, BL 0, BL 1) in the semiconductor storage device 10C is the same as the signal (voltage) supplied to the source line SL, the bit line BL (for example, BL 0, BL 1) in the semiconductor storage device 10 in the timing chart shown in FIG. 20.

For example, in the erase operation of the data in the semiconductor storage device 10C, the signal (voltage) described above is supplied to the respective signal lines. Consequently, the electrons of the respective charge storage layers of the memory cell transistors MTM 0 to MTM 3 in the selected tier TIERM are withdrawn and the data of the memory cell transistors MTM 0 to MTM 3 in the selected tier TIERM is erased.

Further, in the non-selective tier TIERT, the voltage supplied to the channel rises due to coupling between the gate terminals and channels of the memory cell transistors MTT 0 to MTT 3 in the tier TIERT, and electrons are not extracted from the respective charge storage layers. In the non-selected tier TIERB, similar to the deselecting tier TIERT, the voltage supplied to the channel rises and electrons are not extracted from the respective charge storage layers. Therefore, data of the memory cell transistors MTT 0 to MTT 3 and MTB 0 to MTB 3 in the non-selected tiers TIERT and TIERB is not erased (the non-selected tier TIERT is in a non-erased state).

### 3-2-4. Example of Erase Verify Operation in Semiconductor Storage Device

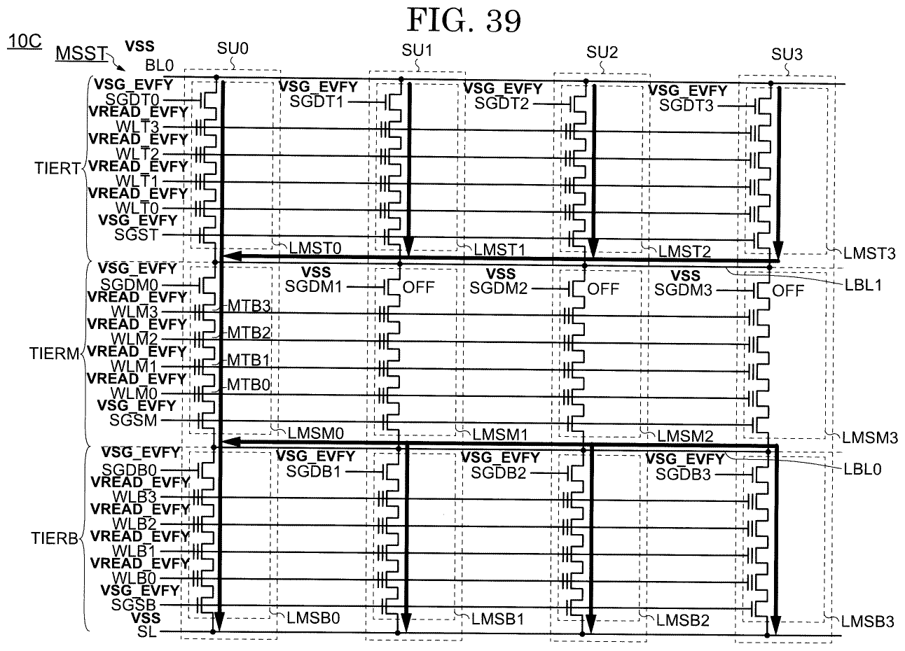

Referring to FIG. 39, an erase verify operation of data (erase verify operation) in the semiconductor storage device 10C will be described. In the circuit diagram shown in FIG. 39, the reference signs of the transistors in the circuit diagram shown in FIG. 35 are omitted. In an example of an erase verify operation in a semiconductor storage device, an example is shown in which the local memory string unit LMSM 0 is subject to an erase verify operation and the selected transistors (memory cell transistors MTM 0 to MTM 3) are verified. That is, the tier TIERM is a selected tier including the memory cell transistor that is a target of the erase verify operation, the tier TIERM is referred to as the selected tier TIERM, the tiers TIERT and TIERB are tiers that are not targets of the erase verify operation, and the tiers are referred to as non-selected tiers TIERT and TIERB.

For example, the erase verify operation of data in the semiconductor storage device 10C may use a timing chart similar to the timing chart in the semiconductor storage device 10 shown in FIG. 22.

For example, the tier TIERT in the semiconductor storage device 10C has the same configuration as each signal line of the tier TIERT in the semiconductor storage device 10, and in the timing chart shown in FIG. 22, a signal (voltage) supplied to each signal line of the tier TIERT in the semiconductor storage device 10 is supplied to each signal line of the tier TIERT in the semiconductor storage device 10C.

For example, the tier TIERB in the semiconductor storage device 10C has the same configuration as the signal lines of the tier TIERT in the semiconductor storage device 10, and in the timing chart shown in FIG. 22, the signal (voltage) supplied to the select gate lines SGDT 0 to SGDT 3 and SGST and the word lines WLT 0 to WLT 3 of the tier TIERT in the semiconductor storage device 10 is supplied to the select gate lines SGDB 0 to SGDB 3 and SGSB and the word lines WLB 0 to WLB 3 of the tier TIERB in the semiconductor storage device 10C.

For example, the tier TIERM in the semiconductor storage device 10C has the same configuration as the signal lines of the tier TIERB in the semiconductor storage device 10, and in the timing chart shown in FIG. 22, the signal (voltage) supplied to the select gate lines SGDB 0 to SGDB 3 and SGSB and the word lines WLB 0 to WLB 3 of the tier TIERB in the semiconductor storage device 10 is supplied to the select gate lines SGDM 0 to SGDM 3 and SGSM and the word lines WLM 0 to WLM 3 of the tier TIERM in the semiconductor storage device 10C.

Further, the signal (voltage) supplied to the source line SL, the bit line BL 0 (PROG-BL), and the bit line BL 1 (Inhibit-BL) in the semiconductor storage device 10C is the same as the signal (voltage) supplied to the source line SL, the bit line BL 0 (PROG-BL), and the bit line BL 1 (Inhibit-BL) in the semiconductor storage device 10 in the timing chart shown in FIG. 22.

For example, the erase verify operation of the data in the semiconductor storage device 10C is such that the signal (voltage) described above is supplied to the respective signal lines. Consequently, the electrons of the respective charge storage layers of the memory cell transistors MTM 0 to MTM 3 in the selected tier TIERM are withdrawn and the data of the memory cell transistors MTM 0 to MTM 3 in the selected tier TIERM is erased.

For example, in the period VE 0, the local memory strings LMST 0 to LMST 3 of the non-selected tier TIERT are all conductive and electrically connected between the bit line BL 0 and the local bit line LBL 1 to carry current from the bit line BL 0 to the local bit line LBL 1. Also, the local memory string LMSM 0 of the selective tier TIERM is conductive, the local memory strings LMSM 1 to LMSM 3 are non-conductive, and the local memory string LMSM0 is electrically connected between the local bit line LBL 1 and the local bit line LBL 0 to carry current from the local bit line LBL 1 to the local bit line LBL 0. Also, the local memory strings LMSB 0 to LMSB 3 of the non-selected tier TIERB are all conductive and electrically connected between the local bit line LBL 0 and the source line SL to carry current from the local bit line LBL 0 to the source line SL.

Consequently, as indicated by the thick solid line shown in FIG. 38, current flows from the bit line BL 0 (PROG-BL) to the source line SL via the local memory strings LMST 0 to LMST 3 of the non-selected tier TIERT, the local bit line LBL 1, the local memory string LMSM 0 of the selected tier TIERM, and the local memory strings LMSB 0 to LMSB 3 of the selected tier TIERB. For example, the sense amplifier module 23 electrically connected to the bit line BL 0 senses the current, and the semiconductor storage 10C may verify that the data of the memory cell transistors MTM 0 to MTM 3 in the local memory string LMSM 0 of the selected tier TIERM has been erased.

### 3-3. Sectional Structure of End of Semiconductor Storage Device 10C

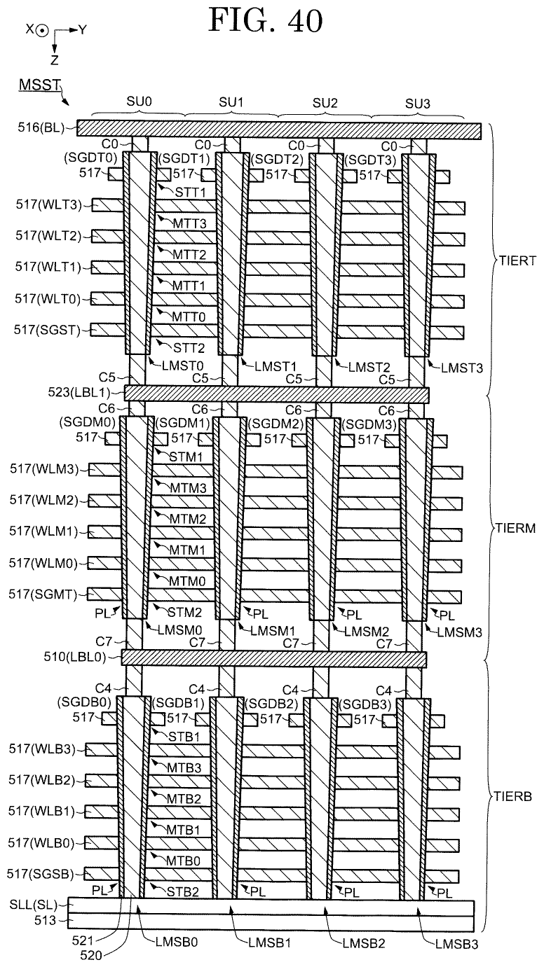

Referring to FIG. 40, a schematic end cross-sectional structure of the semiconductor storage device 10C will be described. FIG. 40 is an end view showing an end cross-sectional view of the memory string set MSST of the semiconductor storage device 10C.

The end cross-sectional structure of the semiconductor storage device 10C (the end cross-sectional structure of the memory string set MSST) is a structure in which a tier TIERM is arranged between the tier TIERB and the tier TIERT in FIG. 8. Configurations other than the tier TIERM are the same as the semiconductor storage device 10 or the semiconductor storage device 10A. Further, the configurations of layers, pillars, and the like constituting the tier TIERM are the same as layers, pillars or the like in the tier TIERB or the tier TIERT. Therefore, the description of the same structure as that of the semiconductor storage device 10 or the semiconductor storage device 10A is omitted here.

The tier tierm contains the local memory strings LMSM 0 to LMSM 3. Each of the local memory strings LMSM 0 to LMSM 3 includes the wiring 510 corresponding to the local bit line LBL 0, a plurality of vias C 7, the plurality of wirings 517, a via C 6, and a wiring 523 corresponding to the local bit line LBL 1. The wiring 510, the plurality of vias C 7, the plurality of wirings 517, the via C 6, and the wiring 523 are laminated in this order from top to bottom along the direction Z. In addition, the wiring 510 corresponding to the local bit line LBL 0 is shared by the tier TIERB and tier TIERM, and are commonly provided. The wiring 523 corresponding to the local bit line LBL 1 is shared by the tier TIERM and tier TIERT, and are commonly provided.

As described above, the wirings 510 serve as the local bit line LBL 0. The local bit line LBL 0 also electrically connects the tier TIERB and the tier TIERM. The plurality of wirings 517 functions as the select gate line SGSM, word lines WLM 0 to WLM 3, and a select gate line SGDM in order from the local bit line LBL 0 to the wiring 523 along the direction Z. As described above, the wiring 523 functions as a local bit line LBL 1. The wiring 516 functions as a bit line BL. Further, the local bit line LBL 1 electrically connects the tier TIERM and the tier TIERT.

For example, the plurality of wirings 517 that functions as the select gate line SGSM and the word lines WLM 0 to WLM 3 is formed in a plate shape that extends along parallel planes along the direction X and the direction Y, and are commonly arranged in the local memory strings LMSM 0 to LMSM 3. Further, for example, the wirings 510 and 523 extend along the direction Y and are divided along the direction X in the same units as the bit line BL and are commonly arranged in the local memory strings LMSM 0 to LMSM 3. For example, the plurality of wirings 517 functioning as the select gate line SGDM functions as the select gate lines SGDM 0 to SGDM 3 corresponding to each of the local memory strings LMSM 0 to LMSM 3. The plurality of wirings 517 functioning as the select gate lines SGDM 0 to SGDM 3 extends along the direction X and are spaced apart from each other along the direction Y and arranged independently. That is, the plurality of wirings 517 functioning as respective wiring of the select gate lines SGDM 0 to SGDM 3 are arranged in the same layer and correspond to respective wiring of the local memory strings LMSM 0 to LMSM 3.

The memory pillar PL is arranged between the wiring 510 and the wiring 523. The memory pillar PL between the wiring 510 and the wiring 523 is included in the local memory string LMST. The memory pillar PL is arranged to extend along the axis Z. The memory pillar PL extends through the plurality of wirings 517. The bottoms of the wirings 510 side of the memory pillar PL along the direction Z contact the wirings 510. The memory pillar PL between the wiring 510 and the wiring 523 includes a configuration similar to the memory pillar PL between the source layer SLL and the wiring 510.

Upper ends of the semiconductor layer 520 and the charge storage layer 521 (the wiring 516 side along the direction Z) are located above the wiring 517, which functions as the select gate line SGDM, and lower ends of the semiconductor layer 520 and the charge storage layer 521 (the line 510 side along the direction Z) contacts the via C 7. The charge storage layer 521 surrounds and covers the side surface of the semiconductor layer 520.

In the memory pillar PL included in the local memory string LMSD, a portion intersecting the plurality of wirings 517 functions as the select transistor STM 1, the memory cell transistors MTM 3 to MTM 0, and the select transistor STM 2, in order from the wiring 523 to the wiring 510 along the direction Z.

The columnar via C 6 is arranged on the upper surface (the wirings 523 side along the direction Z) of the semiconductor layer 520 in the memory pillar PL included in the local memory string LMSM. For example, a diameter of the via C 6 is less than the diameter of the semiconductor layer 520, and an upper end of the via C 6 contacts a corresponding wiring 523 (local bit line LBL 1). The columnar via C 7 is arranged on the lower surface (the wirings 510 side along the direction Z) of the semiconductor layer 520 in the memory pillar PL included in the local memory string LMSM. For example, a diameter of the via C 7 is less than the diameter of the semiconductor layer 520, and a lower end of the via C 7 contacts the corresponding wiring 510 (local bit line LBL 0). Therefore, the wiring 510 and the wiring 523 are connected to each other through the semiconductor layer 520 in the memory pillar PL.

In addition, the wiring 510 in the tier TIERT shown in FIG. 8 (local bit line LBL) is replaced with the wiring 523 in the tiers TIERT and TIERM shown in FIG. 40 (local bit line LBL 1).

### 4. Fourth Embodiment

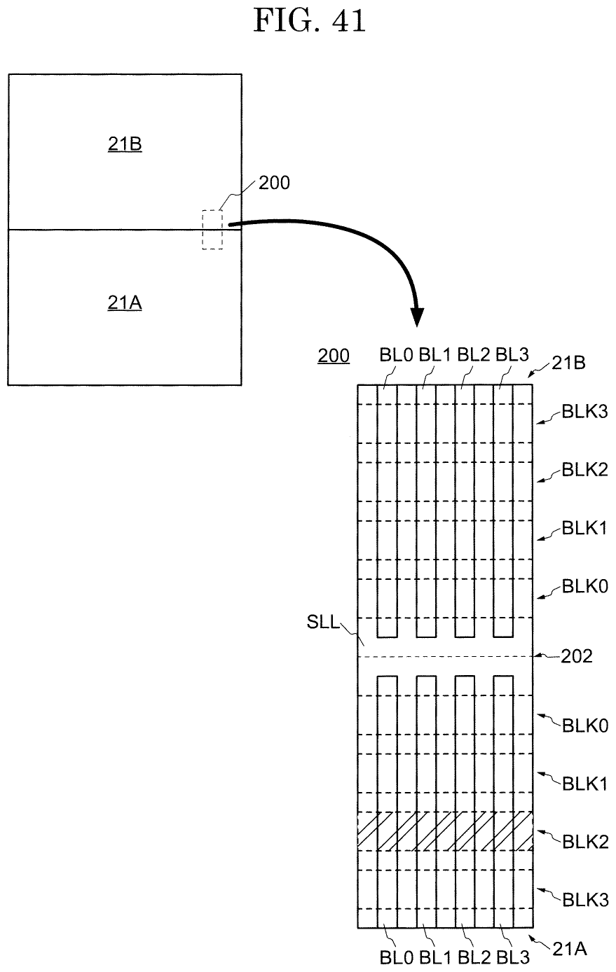

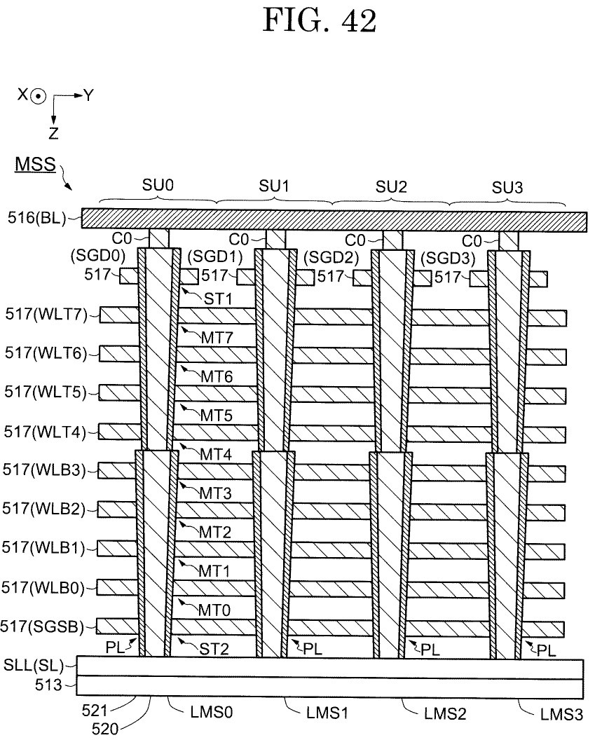

Referring to FIG. 5, FIG. 6, FIG. 41, and FIG. 42, a semiconductor storage device according to a fourth embodiment will be described. The semiconductor storage device 10 shown in FIG. 5 is effective in reducing a chip size of the semiconductor storage device 10P of the comparative example shown in FIG. 6 by (1) using the local bit line LBL to reduce the current flowing through the memory string and (2) connecting a plurality of memory cell arrays. Here, the semiconductor storage device 10 shown in FIG. 5 can implement (1) and (2) independently of each other. Further, with regard to (2), as will be described below with reference to FIG. 5, FIG. 6, and FIG. 41, in the case where the source layer SSL (source line SL) is common, since the voltage VERA is supplied to the source layer SSL of the memory cell array that is not erased among the plurality of memory cell arrays 21 during the erase operation in the semiconductor storage device 10, the same operation as the non-selected block BLK is performed.

FIG. 41 is an enlarged view showing layouts of the memory cell arrays 21A and 21B of the semiconductor storage device 10 shown in FIG. 5 that are paired with each other, and a partially enlarged view showing the layouts of the memory cell arrays 21A and 21B that are paired with each other. In an enlarged view of part of the layouts of the memory cell arrays 21A and 21B that are paired with each other in FIG. 41, for ease of visibility of the drawings, respective bit lines BL 0 to BL 3 of the memory cell arrays 21A and 21B, the source layer SSL commonly arranged in the memory cell arrays 21A and 21B, and the plurality of blocks BLK (blocks BLK 0 to BLK 3) are shown, and other elements constituting the memory cell arrays are omitted. Further, in FIG. 41, the bit lines BL 0 to BL 3 of each of the memory cell arrays 21A and 21B and the source layer SSL are indicated by solid lines, and a region in which the plurality of blocks BLK (block BLK 0 to BLK 3) is arranged is indicated by a broken line as a virtual region. Further, FIG. 42 is an end view showing an example of an end section structure obtained by removing the local bit line LBL or the like in the cross-sectional structure shown in FIG. 8. FIG. 42 shows an example in which the corresponding pillars PL in the tier TIRET and the tier TIERB are connected without the local bit line LBL.

With respect to the memory cell array 21P of the semiconductor storage device 10P of the comparative example shown in FIG. 6, in the plurality of memory cell arrays of the semiconductor storage device 10 shown in FIG. 5, two memory cell arrays 21A and 21B are connected as a pair. As shown in FIG. 5, in the case where the source layers SSL of the memory cell arrays 21A and 21B are common (that is, in the case where the source layers SSL are connected), even if only one block BLK in one memory cell array 21A (for example, BLK 1 indicated by the diagonal line) is operated to erase, the voltage VERA is also applied to the source layer SSL of the other memory cell array 21B. For example, in this case, the same voltages as the select gate lines SGD and SGS of the non-selected block of the selected memory cell array 21A are applied to the select gate lines SGD and SGS of the non-selected memory cell array 21. Thus, since the voltage applied to the non-selected memory cell array 21B becomes the same as the voltage applied to the non-selected block BLK (for example, BLK 0, BLK 2, BLK 3) of the selected memory cell array 21A, the data of the respective memory cells of the non-selected memory cell array 21B is not erased.

Here, as shown in FIG. 41, the bit line BL (BL 0 to BL 3) of each of the memory cell arrays 21A and 21B that are paired with each other is conventionally separated (isolated) in a first region 200 corresponding to a vicinity of a boundary 202 of the memory cell arrays 21A and 21B. For this reason, the read and program operations can be executed in the same manner as in the related art. Further, since the bit lines BL of the memory cell arrays 21A and 21B that are paired with each other are spaced apart from each other, a dummy block may be added to one block or several blocks.

In addition, in the case where only one memory cell array 21A of the memory cell arrays 21A and 21B that are paired with each other is erased, the other memory cell array 21B is also erased in the non-selected manner, and stress is applied during the erase operation. However, in recent years, due to the increasing size of blocks and the increasing number of memory cell arrays, the number of blocks per memory cell array has been reduced and stress in the erase operation is acceptable.

Further, without limiting to the embodiments using the local bit line LBL, it can also be applied to a configuration that does not use the local bit line LBL shown in the comparative example (for example, including a configuration that does not include the local bit line LBL as shown in FIG. 42).

In each of the embodiments described above, although an example of connecting two memory cell arrays has been shown, in addition, three or more memory cell arrays may be connected.

Further, in the embodiments described above, although the number of word lines WL is four, and the number of string units SU is four, the number of word lines WL and the number of string units SU can be independently any number (for example, the number of word lines may be 100 layers or more, and the number of string units SU may be 5 or more). In addition, in each of the embodiments described above, as an example, although the number of tiers TIER is 2 or 3, the number of tiers TIER may be 4 or more.

In the embodiments described above, although the select gate lines SGDT 0 to SGDT 3 and the select gate lines SGDB 0 to SGDB 3 are physically separated, selection can be made by changing the thresholds of the memory cell MC (electric disconnection). Further, in a modified embodiment, although the select gate lines SGST 0 to SGST 3 and the select gate lines STSB 0 to STSB 3 are physically separated, selection can also be made by changing the thresholds of the memory cells (electric disconnection). In addition, the electric disconnection of the select gate line SGD and the select gate line SGS is described in Japanese Laid-Open Patent Publication No. 2019-79885 (U.S. Pat. No. 11,176,999).

Although the present invention has been described above with reference to the drawings, the present invention is not limited to the embodiments described above and can be modified as appropriate within the scope of the invention. For example, any semiconductor memory device in which a person skilled in the art appropriately adds or deletes components or modifies the design based on the semiconductor memory device of this embodiment is included within the scope of the present invention as long as it includes the gist of the present invention. Furthermore, the embodiments described above can be appropriately combined as long as they do not contradict each other, and the technical matters common to each embodiment are included in each embodiment without explicit description.

Even if there are other effects and advantages different from those brought about by the aspects of each of the embodiments described above, those that are clear from the description in this specification or that can be easily predicted by a person skilled in the art are naturally understood to be brought about by the present invention.

1. A semiconductor memory device comprising:
a first source line extending in a first direction and a second direction intersecting the first direction;
a local bit line extending in the second direction;
a first bit line extending in the second direction and overlapping the local bit line when viewed from a third direction intersecting the first and second directions;
a first-tier memory cell array including a plurality of first local strings arranged in the third direction, each of the plurality of first local strings including a first selection transistor, a plurality of first memory cells, and a second selection transistor arranged between the first source line and the local bit line and electrically connected in series;
a second-tier memory cell array including a plurality of second local strings arranged in the third direction, each of the plurality of second local strings including a third selection transistor, a plurality of second memory cells, and a fourth selection transistor arranged between the local bit line and the first bit line and electrically connected in series; and
a control circuit electrically connected to the first bit line and configured to control the first-tier memory cell array and the second-tier memory cell array.

2. The semiconductor memory device according to claim 1, further comprising a first chip,
wherein
the first chip includes the first bit line, the local bit line, the first source line, the first-tier memory cell array, and the second-tier memory cell array.

3. The semiconductor memory device according to claim 1, further comprising:
a first chip; and
a second chip,
wherein
the first chip includes the first source line, a second bit line, a first adhesive electrode electrically connected to the second bit line, and the first-tier memory cell array arranged between and electrically connected to the first source line and the second bit line,
the second chip includes a second source line, a second adhesive electrode electrically connected to the second source line, the first bit line, and the second-tier memory cell array arranged between and electrically connected to the second source line and the first bit line, and
the local bit line includes the second bit line, the first adhesive electrode, the second adhesive electrode electrically connected to the first adhesive electrode, and the second source line.

4. The semiconductor memory device according to claim 1, further comprising:
a first dummy string arranged parallel to the plurality of first local strings along the third direction, and including a fifth select transistor and a sixth select transistor arranged between the first source line and the local bit line and electrically connected in series; and
a second dummy string arranged parallel to the plurality of second local strings along the third direction, and including a seventh select transistor and an eighth select transistor arranged between the local bit line and the first bit line and electrically connected in series.

5. The semiconductor memory device according to claim 4,
wherein
the first dummy string includes a third memory cell electrically connected between the fifth select transistor and the sixth select transistor and having a threshold voltage programmed therein in advance, and
the second dummy string includes a fourth memory cell electrically connected between the seventh select transistor and the eighth select transistor and having a threshold voltage programmed therein in advance.

6. The semiconductor memory device according to claim 1, further comprising:
a plurality of blocks extending along the third direction and arranged along the second direction,
wherein
each of the plurality of blocks includes the plurality of first local strings, the local bit line, and the plurality of second local strings.

7. The semiconductor memory device according to claim 6, further comprising
a third bit line arranged opposite the first bit line in the second direction,
wherein
the plurality of blocks includes at least a first block and a second block,
the first block is arranged between the first bit line and the first source line, and
the second block is arranged between the second bit line and the first source line.

8. The semiconductor memory device according to claim 1,
wherein
the control circuit controls a read operation, a write operation, or an erase operation to the first-tier memory cell array and the second-tier memory cell array, and
on executing the read operation, the write operation, or the erase operation to the first-tier memory cell array or the second-tier memory cell array, the control circuit turns on either the first select transistor and the second select transistor of the first-tier memory cell array or the third select transistor and the fourth select transistor of the second-tier memory cell array.

9. The semiconductor memory device according to claim 4,
wherein
the control circuit controls a read operation, a write operation, or an erase operation to the first-tier memory cell array and the second-tier memory cell array, and
on executing the read operation, the write operation, or the erase operation to the first-tier memory cell array or the second-tier memory cell array, the control circuit turns on either the fifth select transistor and the sixth select transistor in the first dummy string or the seventh select transistor and the eighth select transistor in the second dummy string.

10. The semiconductor memory device according to claim 1,
wherein
the control circuit controls a read operation, a write operation, or an erase operation on the first-tier memory cell array and the second-tier memory cell array, and
on executing the write operation on the first-tier memory cell array or the second-tier memory cell array, the control circuit supplies a first voltage to either the first memory cell in the first local string or the second memory cell in the second local string, and supplies a second voltage lower than the first voltage to the remaining local string.

11. The semiconductor memory device according to claim 4,
wherein
the control circuit controls a read operation, a write operation, or an erase operation on the first-tier memory cell array and the second-tier memory cell array, and
on executing the erase operation on the first-level memory cell array or the second-level memory cell array, the control circuit supplies a third voltage that turns on either the fifth select transistor and the sixth select transistor in the first dummy string or the seventh select transistor and the eighth select transistor in the second dummy string, and supplies a fourth voltage greater than the third voltage to either the first memory cell in the first local string or the second memory cell in the second local string.

12. A semiconductor memory device comprising:
a plurality of memory cells each holding data;
a plurality of word lines connected to the plurality of memory cells;
a page including the plurality of memory cells connected to the same word line;
a plurality of blocks having a plurality of pages; and
first and second memory cell arrays including the plurality of blocks;
wherein
the first memory cell array and the second memory cell array are arranged adjacent to each other, and
the blocks of the first memory cell array and the blocks of the second memory cell array are arranged adjacent to each other or with dummy blocks having the same shape as the memory cells adjacent to each other.

13. The semiconductor memory device according to claim 12,
wherein
a source line connected to memory cells of the first memory cell array is common to a source line connected to memory cells of the second memory cell array.

14. The semiconductor memory device according to claim 12,
wherein
during an erase operation of a block on a selected memory cell among a plurality of memory cell arrays including the first memory cell array or the second memory cell array,
an erase voltage is applied to memory cells of a selected block of the selected memory cell array,
an erase inhibit voltage is applied to memory cells of unselected blocks of the selected memory cell array, and
the erase inhibit voltage is applied to memory cells of blocks of unselected memory cell arrays.

15. The semiconductor memory device according to claim 12,
wherein
the plurality of memory cells is connected to a plurality of bit lines, and,
during an erase operation of a block on a selected memory cell among a plurality of memory cell arrays including the first memory cell array or the second memory cell array,
an erase voltage is applied to bit lines of the selected memory cell array, and
the erase voltage is also applied to bit lines of unselected memory cell arrays.

16. The semiconductor memory device according to claim 4,
wherein
the control circuit controls a read operation, a write operation, or an erase operation on the first-tier memory cell array and the second-tier memory cell array, and
on executing the write operation on the first-tier memory cell array or the second-tier memory cell array, the control circuit supplies a first voltage to either the first memory cell in the first local string or the second memory cell in the second local string, and supplies a second voltage lower than the first voltage to the remaining local string.

17. The semiconductor memory device according to claim 5,
wherein
the control circuit controls a read operation, a write operation, or an erase operation on the first-tier memory cell array and the second-tier memory cell array, and
on executing the write operation on the first-tier memory cell array or the second-tier memory cell array, the control circuit supplies a first voltage to either the first memory cell in the first local string or the second memory cell in the second local string, and supplies a second voltage lower than the first voltage to the remaining local string.

18. The semiconductor memory device according to claim 5,
wherein
the control circuit controls a read operation, a write operation, or an erase operation on the first-level memory cell array and the second-level memory cell array, and
on executing the erase operation on the first-level memory cell array or the second-level memory cell array, the control circuit supplies a third voltage that turns on either the fifth select transistor and the sixth select transistor in the first dummy string or the seventh select transistor and the eighth select transistor in the second dummy string, and supplies a fourth voltage greater than the third voltage to either the first memory cell in the first local string or the second memory cell in the second local string.
